(19) United States
(12) Patent Application Publication
(10) Pub. No.: US 2025/0294956 A1
(43) Pub. Date: Sep. 18, 2025

(54) ORGANIC ELECTROLUMINESCENT DEVICE AND DISPLAY APPARATUS

(71) Applicant: BEIJING SUMMER SPROUT TECHNOLOGY CO., LTD., Beijing (CN)

(72) Inventors: Chunliang ZHAO, Beijing (CN); Ming SANG, Beijing (CN); Xuechao TIAN, Beijing (CN); Liuhuan CAI, Beijing (CN); Chi Yuen Raymond KWONG, Beijing (CN); Chuanjun XIA, Beijing (CN)

(21) Appl. No.: 19/076,860

(22) Filed: Mar. 11, 2025

(30) Foreign Application Priority Data
Mar. 13, 2024 (CN) 202410287628.8

(51) Int. Cl. H10K 50/11; C09K 11/06; H10K 85/30; H10K 85/60

(52) U.S. Cl. CPC H10K 50/11; C09K 11/06; H10K 85/346; H10K 85/657; H10K 85/658; C09K 2211/1014

(57) ABSTRACT

Provided are an organic electroluminescent device and a display apparatus. The organic electroluminescent device includes an anode, a cathode, and an emissive layer disposed between the anode and the cathode, wherein the emissive layer includes a fluorescent emissive material represented by the structure of Formula 1, a metal complex, a first host compound, and a second host compound. The organic electroluminescent device of the present disclosure exhibits excellent overall device performance and can achieve, for example, a narrow full width at half maximum, high current efficiency, and very excellent device lifetime. Further provided are a display apparatus including the organic electroluminescent device and a composition including the fluorescent emissive material, the metal complex, the first host compound, and the second host compound.

### CROSS-REFERENCE TO RELATED APPLICATION(S)

This present disclosure claims priority to Chinese Patent Application No. CN 202410287628.8 filed on Mar. 13, 2024, the disclosure of which is incorporated herein by reference in its entirety.

### TECHNICAL FIELD

The present disclosure relates to organic electronic devices, for example, organic electroluminescent devices. More particularly, the present disclosure relates to an organic electroluminescent device including a specific combination of four materials and a display apparatus including the organic electroluminescent device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation (VTE method). Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

US20230200206A1 discloses a condensed cyclic compound represented by Formula 1:

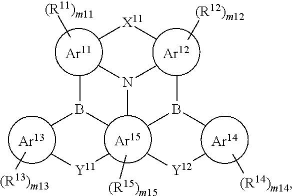

wherein X¹¹ is —O—, —S—, —Se—, —Te—, —NR^{X11}— or a single bond, and Y¹¹ and Y¹² are each independently selected from —O—, —S—, —Se—, —Te—, —NR^{Y11}—, —CR^{Y12}R^{Y13}— or —SiR^{Y14}R^{Y15}—. This application discloses compounds such as

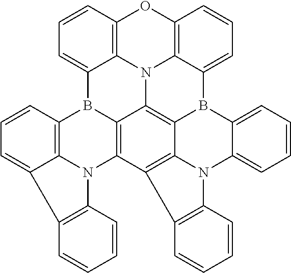 [SMILES: c1ccc2c(c1)B1c3cccc4c3N3c5c(cccc5B5c6c3c1c1c(c6-n3c6ccccc6c6cccc5c63)c3ccccc3n1-2)O4]

in specific structures,

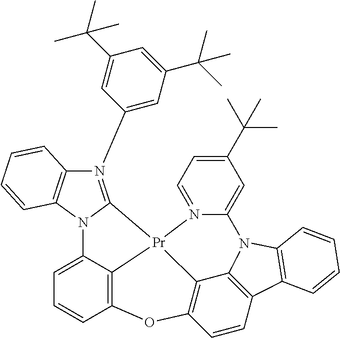

uses as a phosphorescent sensitizer in specific device application examples, and uses

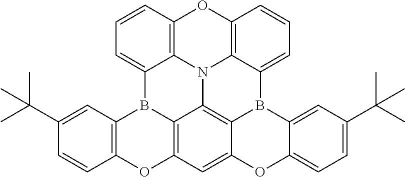 [SMILES: CC(C)(C)c1ccc2c(c1)B1c3cccc4c3N3c5c(cccc5B5c6cc(C(C)(C)C)ccc6Oc6cc(c1c3c65)O2)O4]

as an emissive material. As can be seen, this application discloses a compound having a specific condensed cyclic structure of general formula 1 and the use thereof in organic electroluminescent devices and does not disclose nor teach compounds with other backbone structures and the use thereof in organic electroluminescent devices.

The related art discloses devices in an emissive layer of which a metal complex is used as a phosphorescent sensitizer to sensitize a fluorescent emissive material, and since the high roll-off phenomenon of a delayed fluorescent material is well suppressed due to the presence of the phosphorescent sensitizer, the device performance is improved under the condition of high brightness. However, the performance of such devices still needs to be improved, such as higher device efficiency and longer lifetime.

### SUMMARY

The present disclosure aims to provide a new organic electroluminescent device to solve at least part of the above problems. The emissive layer of the organic electroluminescent device includes a fluorescent emissive material represented by the structure of Formula 1, a metal complex, a first host compound, and a second host compound. The new organic electroluminescent device can exhibit excellent overall device performance and can achieve, for example, a narrow full width at half maximum, high current efficiency, and very excellent device lifetime.

According to an embodiment of the present disclosure, an organic electroluminescent device is disclosed, which includes:
an anode,
a cathode, and
an emissive layer disposed between the anode and the cathode, wherein the emissive layer includes a fluorescent emissive material, a metal complex, a first host compound, and a second host compound;
wherein the fluorescent emissive material has a structure represented by Formula 1:

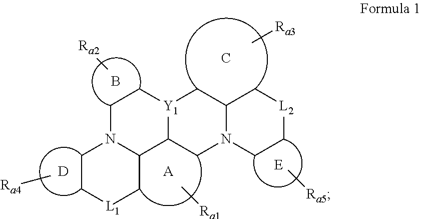

wherein in Formula 1,
the ring A is selected from an unsaturated carbocyclic ring having 5 to 30 carbon atoms or an unsaturated heterocyclic ring having 4 to 30 carbon atoms;
the ring B, the ring C, the ring D, and the ring E are each independently selected from an unsaturated carbocyclic ring having 5 to 30 carbon atoms or an unsaturated heterocyclic ring having 3 to 30 carbon atoms;
Y₁ is selected from B, P═O, P═S, As, As═O, As═S, SiR′ or GeR′;
Rₐ₁, Rₐ₂, Rₐ₃, Rₐ₄, and Rₐ₅ represent, at each occurrence identically or differently, mono-substitution, multiple substitutions or non-substitution;
R′, Rₐ₁, Rₐ₂, Rₐ₃, Rₐ₄, and Rₐ₅ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ and L₂ are each independently selected from the group consisting of: a single bond, O, S, Se, SiR_{L1}R_{L1}, PR_{L1}, R_{L1}C═CR_{L1}, substituted or unsubstituted arylene having 6 to 30 carbon atoms, substituted or unsubstituted heteroarylene having 3 to 30 carbon atoms, and combinations thereof;
R_{L1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof;
adjacent substituents Rₐ₁ can be optionally joined to form a ring;
adjacent substituents Rₐ₂ can be optionally joined to form a ring;
adjacent substituents Rₐ₃ can be optionally joined to form a ring;
adjacent substituents Rₐ₄ can be optionally joined to form a ring;
adjacent substituents Rₐ₅ can be optionally joined to form a ring; and
adjacent substituents R_{L1} can be optionally joined to form a ring.

According to an embodiment of the present disclosure, a display apparatus is disclosed, which includes the organic electroluminescent device described in the above-mentioned embodiment.

According to an embodiment of the present disclosure, a composition is disclosed, the composition includes a fluorescent emissive material, a metal complex, a first host compound, and a second host compound;
wherein the fluorescent emissive material has a structure represented by Formula 1:

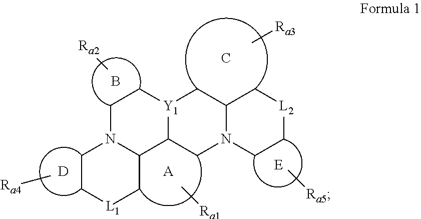

wherein in Formula 1,
the ring A is selected from an unsaturated carbocyclic ring having 5 to 30 carbon atoms or an unsaturated heterocyclic ring having 4 to 30 carbon atoms;
the ring B, the ring C, the ring D, and the ring E are each independently selected from an unsaturated carbocyclic ring having 5 to 30 carbon atoms or an unsaturated heterocyclic ring having 3 to 30 carbon atoms;
Y₁ is selected from B, P═O, P═S, As, As═O, As═S, SiR′ or GeR′;
Rₐ₁, Rₐ₂, Rₐ₃, Rₐ₄, and Rₐ₅ represent, at each occurrence identically or differently, mono-substitution, multiple substitutions or non-substitution;
R′, Rₐ₁, Rₐ₂, Rₐ₃, Rₐ₄, and Rₐ₅ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ and L₂ are each independently selected from the group consisting of: a single bond, O, S, Se, SiR_{L1}R_{L1}, PR_{L1}, R_{L1}C═CR_{L1}, substituted or unsubstituted arylene having 6 to 30 carbon atoms, substituted or unsubstituted heteroarylene having 3 to 30 carbon atoms, and combinations thereof;
R_{L1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof,
adjacent substituents Rₐ₁ can be optionally joined to form a ring;
adjacent substituents Rₐ₂ can be optionally joined to form a ring;
adjacent substituents Rₐ₃ can be optionally joined to form a ring;
adjacent substituents Rₐ₄ can be optionally joined to form a ring;
adjacent substituents Rₐ₅ can be optionally joined to form a ring; and
adjacent substituents R_{L1} can be optionally joined to form a ring.

The present disclosure aims to provide a new organic electroluminescent device. The emissive layer of the organic electroluminescent device includes a fluorescent emissive material represented by the structure of Formula 1, a metal complex, a first host compound, and a second host compound. The new organic electroluminescent device can exhibit excellent overall device performance and can achieve, for example, a narrow full width at half maximum, high current efficiency, and very excellent device lifetime.

### BRIEF DESCRIPTION OF DRAWINGS

FIG. 1 is a schematic diagram of an organic light-emitting device that may include an organic electroluminescent device disclosed herein.

FIG. 2 is a schematic diagram of another organic light-emitting device that may include an organic electroluminescent device disclosed herein.

### DETAILED DESCRIPTION

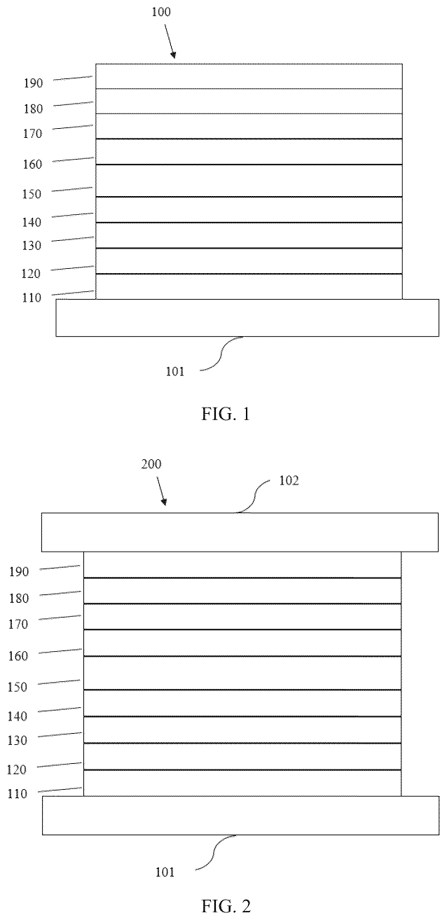

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device includes a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AEs-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylisopropylgermanylmethyl, tert-dimethylethylgermanylmethyl, butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, O-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions, etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

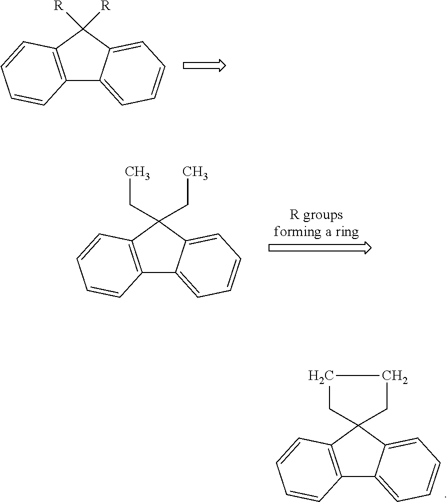

The expression that adjacent substituents can be optionally joined to form a ring is also intended to mean that two substituents bonded to carbon atoms which are directly bonded to each other are joined to each other via a chemical bond to form a ring, which can be exemplified by the following formula:

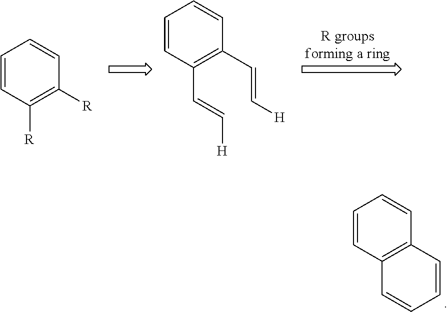

The expression that adjacent substituents can be optionally joined to form a ring is also intended to mean that two substituents bonded to further distant carbon atoms are joined to each other via a chemical bond to form a ring, which can be exemplified by the following formula:

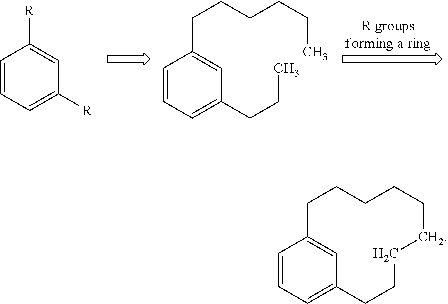

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

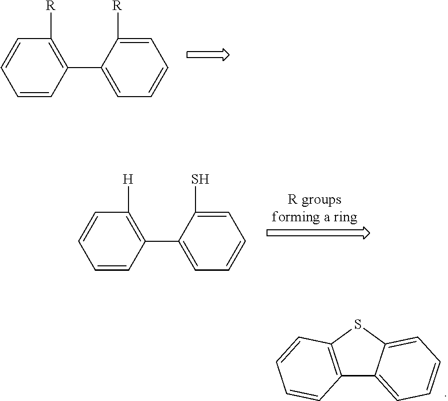

According to an embodiment of the present disclosure, an organic electroluminescent device is disclosed, which includes:
an anode,
a cathode, and
an emissive layer disposed between the anode and the cathode, wherein the emissive layer includes a fluorescent emissive material, a metal complex, a first host compound, and a second host compound;
wherein the fluorescent emissive material has a structure represented by Formula 1:

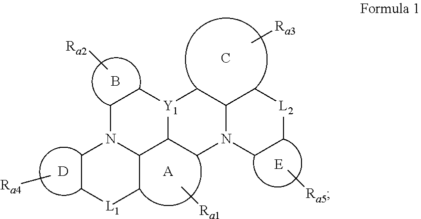

wherein in Formula 1,
the ring A is selected from an unsaturated carbocyclic ring having 5 to 30 carbon atoms or an unsaturated heterocyclic ring having 4 to 30 carbon atoms;
the ring B, the ring C, the ring D, and the ring E are each independently selected from an unsaturated carbocyclic ring having 5 to 30 carbon atoms or an unsaturated heterocyclic ring having 3 to 30 carbon atoms;
Y₁ is selected from B, P═O, P═S, As, As═O, As═S, SiR′ or GeR′;
Rₐ₁, Rₐ₂, Rₐ₃, Rₐ₄, and Rₐ₅ represent, at each occurrence identically or differently, mono-substitution, multiple substitutions or non-substitution;
R′, Rₐ₁, Rₐ₂, Rₐ₃, Rₐ₄, and Rₐ₅ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ and L₂ are each independently selected from the group consisting of: a single bond, O, S, Se, SiR_{L1}R_{L1}, PR_{L1}, R_{L1}C═CR_{L1}, substituted or unsubstituted arylene having 6 to 30 carbon atoms, substituted or unsubstituted heteroarylene having 3 to 30 carbon atoms, and combinations thereof;
R_{L1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof;
adjacent substituents Rₐ₁ can be optionally joined to form a ring;
adjacent substituents Rₐ₂ can be optionally joined to form a ring;
adjacent substituents Rₐ₃ can be optionally joined to form a ring;
adjacent substituents Rₐ₄ can be optionally joined to form a ring;
adjacent substituents Rₐ₅ can be optionally joined to form a ring; and
adjacent substituents R_{L1} can be optionally joined to form a ring.

Herein, the expression that adjacent substituents Rₐ₁ can be optionally joined to form a ring is intended to mean that two adjacent substituents Rₐ₁ can be joined to form a ring. Obviously, it is also possible that two adjacent substituents Rₐ₁ are not joined to form a ring.

Herein, the expression that adjacent substituents Rₐ₂ can be optionally joined to form a ring is intended to mean that two adjacent substituents Rₐ₂ can be joined to form a ring. Obviously, it is also possible that two adjacent substituents Rₐ₂ are not joined to form a ring.

Herein, the expression that adjacent substituents Rₐ₃ can be optionally joined to form a ring is intended to mean that two adjacent substituents Rₐ₃ can be joined to form a ring. Obviously, it is also possible that two adjacent substituents Rₐ₃ are not joined to form a ring.

Herein, the expression that adjacent substituents Rₐ₄ can be optionally joined to form a ring is intended to mean that two adjacent substituents Rₐ₄ can be joined to form a ring. Obviously, it is also possible that two adjacent substituents Rₐ₄ are not joined to form a ring.

Herein, the expression that adjacent substituents Rₐ₅ can be optionally joined to form a ring is intended to mean that two adjacent substituents Rₐ₅ can be joined to form a ring. Obviously, it is also possible that two adjacent substituents Rₐ₅ are not joined to form a ring.

Herein, the expression that adjacent substituents R_{L1} can be optionally joined to form a ring is intended to mean that two adjacent substituents R_{L1} can be joined to form a ring. Obviously, it is also possible that two adjacent substituents R_{L1} are not joined to form a ring.

Herein, an unsaturated carbocyclic ring includes an aromatic unsaturated carbocyclic ring (aromatic ring) and a non-aromatic unsaturated carbocyclic ring, and an unsaturated heterocyclic ring includes an aromatic unsaturated heterocyclic ring (heteroaromatic ring) and a non-aromatic unsaturated heterocyclic ring.

According to an embodiment of the present disclosure, the emissive layer in the device is formed by co-evaporating four materials, that is, a fluorescent emissive material, a metal complex, a first host compound and a second host compound, which are loaded in four evaporation sources, respectively.

According to an embodiment of the present disclosure, the emissive layer in the device is not formed by co-evaporating a pre-mixture of a fluorescent emissive material, a first host compound and a second host compound placed in one evaporation source with a metal complex placed in another evaporation source.

According to an embodiment of the present disclosure, the ring A, the ring B, the ring C, the ring D, and the ring E are each independently selected from a five-membered unsaturated carbocyclic ring, an aromatic ring having 6 to 30 carbon atoms or a heteroaromatic ring having 4 to 30 carbon atoms.

According to an embodiment of the present disclosure, the ring A, the ring B, the ring C, the ring D, and the ring E are, at each occurrence identically or differently, selected from a five-membered unsaturated carbocyclic ring, an aromatic ring having 6 to 18 carbon atoms or a heteroaromatic ring having 4 to 18 carbon atoms.

According to an embodiment of the present disclosure, the ring A, the ring B, the ring C, the ring D, and the ring E are, at each occurrence identically or differently, selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring or a combination thereof.

According to an embodiment of the present disclosure, the ring A, the ring B, the ring C, the ring D, and the ring E are selected from a benzene ring.

According to an embodiment of the present disclosure, Y₁ is each independently selected from B, P═O or P═S.

According to an embodiment of the present disclosure, Y₁ is selected from B.

According to an embodiment of the present disclosure, the fluorescent emissive material includes only one atom B.

According to an embodiment of the present disclosure, the compound of Formula 1 includes only one atom B.

According to an embodiment of the present disclosure, the compound of Formula 1-1 includes only one atom B.

According to an embodiment of the present disclosure, the fluorescent emissive material has a structure represented by Formula 1-1:

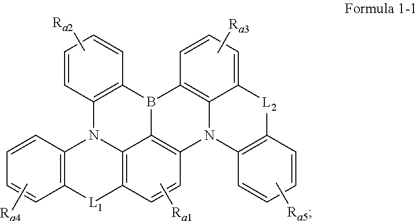

wherein,
Rₐ₁, Rₐ₂, Rₐ₃, Rₐ₄, and Rₐ₅ represent, at each occurrence identically or differently, mono-substitution, multiple substitutions or non-substitution;
Rₐ₁, Rₐ₂, Rₐ₃, Rₐ₄, and Rₐ₅ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ and L₂ are each independently selected from the group consisting of: a single bond, O, S, Se, SiR_{L1}R_{L1}, PR_{L1}, R_{L1}C═CR_{L1}, substituted or unsubstituted arylene having 6 to 30 carbon atoms, substituted or unsubstituted heteroarylene having 3 to 30 carbon atoms, and combinations thereof;
R_{L1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof;
adjacent substituents Rₐ₁ can be optionally joined to form a ring;
adjacent substituents Rₐ₂ can be optionally joined to form a ring;
adjacent substituents Rₐ₃ can be optionally joined to form a ring;
adjacent substituents Rₐ₄ can be optionally joined to form a ring;
adjacent substituents Rₐ₅ can be optionally joined to form a ring; and
adjacent substituents R_{L1} can be optionally joined to form a ring.

According to an embodiment of the present disclosure, L₁ and L₂ are each independently selected from a single bond, O or S.

According to an embodiment of the present disclosure, at least one of L₁ and L₂ is a single bond.

According to an embodiment of the present disclosure, L₁ and L₂ are each a single bond.

According to an embodiment of the present disclosure, Rₐ₁, Rₐ₂, Rₐ₃, Rₐ₄, and Rₐ₅ are, at each occurrence identically or differently, selected from the group consisting of: hydrogen, deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, and combinations thereof.

According to an embodiment of the present disclosure, Rₐ₁, Rₐ₂, Rₐ₃, Rₐ₄, and Rₐ₅ are, at each occurrence identically or differently, selected from the group consisting of: hydrogen, deuterium, halogen, cyano, hydroxyl, sulfanyl, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted heterocyclic group having 3 to 6 ring atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof.

According to an embodiment of the present disclosure, Rₐ₁, Rₐ₂, Rₐ₃, Rₐ₄, and Rₐ₅ are, at each occurrence identically or differently, selected from the group consisting of: hydrogen, deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, quarterphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, diphenylamino, dibenzofurylphenylamino, and combinations thereof.

According to an embodiment of the present disclosure, at least one of Rₐ₁, Rₐ₂, Rₐ₃, Rₐ₄, and Rₐ₅ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least one of Rₐ₁, Rₐ₂, Rₐ₃, Rₐ₄, and Rₐ₅ is, at each occurrence identically or differently, selected from the group consisting of: deuterium, halogen, cyano, hydroxyl, sulfanyl, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof.

According to an embodiment of the present disclosure, at least one of Rₐ₁, Rₐ₂, Rₐ₃, Rₐ₄, and Rₐ₅ is, at each occurrence identically or differently, selected from the group consisting of: deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, quarterphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, diphenylamino, dibenzofurylphenylamino, and combinations thereof.

According to an embodiment of the present disclosure, the fluorescent emissive material is selected from the group consisting of Compound BD-1-1 to Compound BD-1-31, Compound BD-2-1 to Compound BD-2-28, Compound BD-3-1 to Compound BD-3-22, Compound BD-4-1 to Compound BD-4-36, Compound BD-5-1 to Compound BD-5-36, and Compound BD-6-1 to Compound BD-6-42, wherein the specific structures of Compound BD-1-1 to Compound BD-1-31, Compound BD-2-1 to Compound BD-2-28, Compound BD-3-1 to Compound BD-3-22, Compound BD-4-1 to Compound BD-4-36, Compound BD-5-1 to Compound BD-5-36, and Compound BD-6-1 to Compound BD-6-42 are referred to claim 8.

According to an embodiment of the present disclosure, hydrogens in Compound BD-1-1 to Compound BD-1-31, Compound BD-2-1 to Compound BD-2-28, Compound BD-3-1 to Compound BD-3-22, Compound BD-4-1 to Compound BD-4-36, Compound BD-5-1 to Compound BD-5-36, and Compound BD-6-1 to Compound BD-6-42 can be partially or fully substituted with deuterium.

According to an embodiment of the present disclosure, the maximum emission wavelength λ_{max-PL} in the photoluminescence spectrum of the fluorescent emissive material is 450 nm to 500 nm.

According to an embodiment of the present disclosure, the maximum emission wavelength λ_{max-PL} in the photoluminescence spectrum of the fluorescent emissive material is 450 nm to 470 nm.

According to an embodiment of the present disclosure, the maximum emission wavelength λ_{max-PL} in the photoluminescence spectrum of the fluorescent emissive material is 455 nm to 465 nm.

According to an embodiment of the present disclosure, the full width at half maximum FWHM-_{PL} in the photoluminescence spectrum of the fluorescent emissive material is less than or equal to 45 nm.

According to an embodiment of the present disclosure, the full width at half maximum FWHM-_{PL} in the photoluminescence spectrum of the fluorescent emissive material is less than or equal to 35 nm.

According to an embodiment of the present disclosure, the full width at half maximum FWHM-_{PL} in the photoluminescence spectrum of the fluorescent emissive material is less than or equal to 30 nm.

According to an embodiment of the present disclosure, the full width at half maximum FWHM-_{PL} in the photoluminescence spectrum of the fluorescent emissive material is less than or equal to 25 nm.

According to an embodiment of the present disclosure, the full width at half maximum FWHM-_{PL} in the photoluminescence spectrum of the fluorescent emissive material is less than or equal to 20 nm.

In the present disclosure, the maximum emission wavelength Δ_{max-PL} and the full width at half maximum FWHM-_{PL} of the photoluminescence spectrum are measured in the following manner.

The photoluminescence (PL) spectrum data of a compound to be measured were measured using a fluorescence spectrophotometer F98 produced by SHANGHAI LENGGUANG TECHNOLOGY CO., LTD. The compound to be measured was dissolved in a toluene solvent to prepare a solution with a concentration of 1×10⁻⁶ mol/L, nitrogen was purged into the prepared solution to be measured for 5 min to remove oxygen, and the solution to be measured was added to a quartz sample tube and excited at room temperature (298 K) by light with a wavelength of 350 nm to measure the emission spectrum. The emission spectrum has a maximum emission wavelength λ_{max-PL} and a full width at half maximum FWHM-_{PL} (which is the peak width at half the maximum emission peak height, that is, the distance between two points where a straight line parallel to the horizontal axis through the middle point of the peak height intersects both sides of the peak).

For example, the maximum emission wavelength Δ_{max-PL} and the full width at half maximum FWHM-_{PL} of the photoluminescence spectrum of each of the following compounds were measured by using the above manner, and the specific results are shown in Table 1.

TABLE 1
λ_{max-PL} and FWHM-_{PL} of the photoluminescence
spectra of compounds

| Compound No. | λ_{max-PL} (nm) | FWHM-_{PL} (nm) |
|---|---|---|
| BD-1-1 | 460 | 27.4 |
| BD-1-24 | 460 | 28.9 |
| BD | 453 | 25.8 |

The specific structures of Compound BD-1-1, Compound BD-1-24, and Compound BD are shown below:

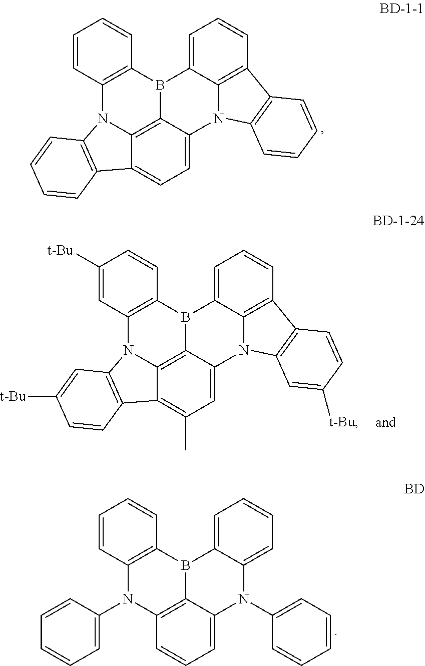 [SMILES: c1ccc2c(c1)B1c3cccc4c5ccccc5n(c34)-c3ccc4c5ccccc5n-2c4c31 ; Cc1cc2c3c4c1c1ccc(C(C)(C)C)cc1n4-c1cc(C(C)(C)C)ccc1B3c1cccc3c4ccc(C(C)(C)C)cc4n-2c13 ; "and" ; c1ccc(N2c3ccccc3B3c4ccccc4N(c4ccccc4)c4cccc2c43)cc1]

According to an embodiment of the present disclosure, the metal complex has a general formula of M(Lₐ)ₘ(L_{b})ₙ (L_{c})_{q};
wherein the M is selected from a metal with a relative atomic mass greater than 40;
the ligands Lₐ, L_{b}, and L_{c} are a first ligand, a second ligand, and a third ligand coordinated to the metal M, respectively, and the ligands Lₐ, L_{b}, and L_{c} may be the same or different;
the ligands Lₐ, L_{b}, and L_{c} can be optionally joined to form a multidentate ligand; for example, any two of Lₐ, L_{b}, and L_{c} may be joined to form a tetradentate ligand; in another example, Lₐ, L_{b}, and L_{c} may be joined to each other to form a hexadentate ligand; in yet another example, none of Lₐ, L_{b}, and Le are joined so that no multidentate ligand is formed;
m is 1, 2 or 3; n is 0, 1 or 2; q is 0, 1 or 2; the sum of m, n, and q is equal to an oxidation state of the metal M; when m is greater than or equal to 2, multiple Lₐ may be the same or different; when n is 2, two L_{b} may be the same or different; when q is 2, two L_{c} may be the same or different;
the ligand Lₐ has a structure represented by Formula 2:

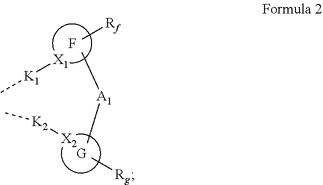

wherein the ring F and the ring G are, at each occurrence identically or differently, selected from an unsaturated carbocyclic ring having 5 to 30 carbon atoms, an unsaturated heterocyclic ring having 1 to 30 carbon atoms or a combination thereof;
X₁ and X₂ are, at each occurrence identically or differently, selected from C or N;
K₁ and K₂ are each independently selected from a single bond, O or S;
A₁ is selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2, 3, 4 or 5;
R_{f} and R_{g} represent, at each occurrence identically or differently, mono-substitution, multiple substitutions or non-substitution;
R_{f} and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
adjacent substituents R_{f} and R_{g} can be optionally joined to form a ring; and
the ligands L_{b} and L_{c} are, at each occurrence identically or differently, selected from a monoanionic bidentate ligand.

In this embodiment, the expression that adjacent substituents R_{f} and R_{g} can be optionally joined to form a ring is intended to mean that any one or more of groups of adjacent substituents, such as two substituents R_{f}, two substituents R_{g}, and R_{f} and R_{g}, may be joined to form a ring. Obviously, it is also possible that none of these substituents are joined to form a ring.

According to an embodiment of the present disclosure, the ligands L_{b} and L_{c} are, at each occurrence identically or differently, selected from the group consisting of the following structures:

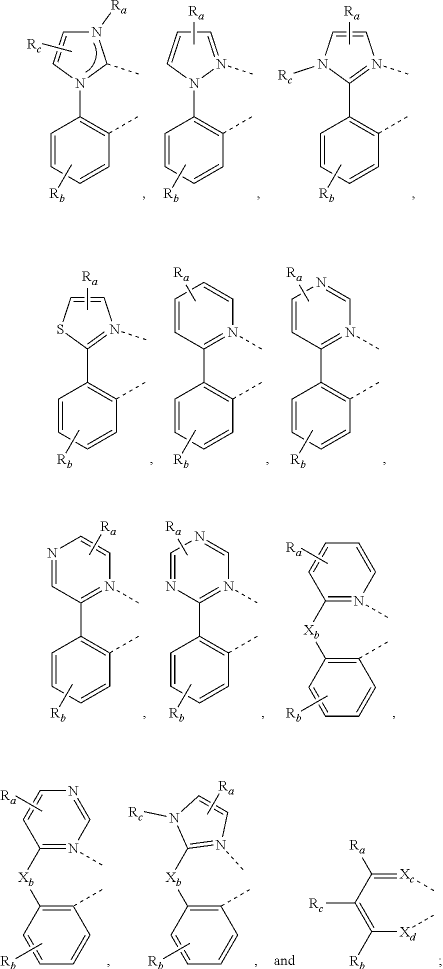

wherein,
Rₐ and R_{b} represent, at each occurrence identically or differently, mono-substitution, multiple substitutions or non-substitution;
X_{b} is, at each occurrence identically or differently, selected from the group consisting of O, S, Se, NR_{N1}, and CR_{C1}R_{C2};
X_{c} and X_{d} are, at each occurrence identically or differently, selected from the group consisting of O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ, R_{b}, R_{c}, R_{N1}, R_{N2}, R_{C1}, and R_{C2} can be optionally joined to form a ring.

In this embodiment, the expression that adjacent substituents Rₐ, R_{b}, R_{c}, R_{N1}, R_{N2}, R_{C1}, and R_{C2} can be optionally joined to form a ring is intended to mean that any one or more of groups of adjacent substituents, such as two substituents Rₐ, two substituents R_{b}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, R_{C1} and R_{C2}, substituents Rₐ and R_{N2}, and substituents R_{b} and R_{N2}, may be joined to form a ring. Obviously, it is also possible that none of these substituents are joined to form a ring.

According to an embodiment of the present disclosure, the metal M is selected from the group consisting of Cu, Ag, Au, Zn, Ru, Rh, Pd, Os, Ir, and Pt.

According to an embodiment of the present disclosure, the metal M is selected from Ir or Pt.

According to an embodiment of the present disclosure, the metal complex has a structure represented by Formula 3:

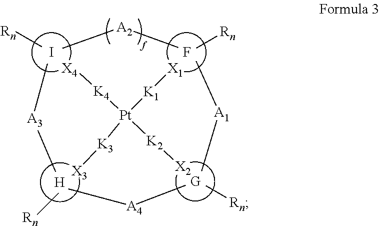

wherein in Formula 3,
the ring F, the ring G, the ring H, and the ring I are each independently selected from an unsaturated carbocyclic ring having 5 to 30 carbon atoms, an unsaturated heterocyclic ring having 1 to 30 carbon atoms or a combination thereof;
f is selected from 0 or 1;
A₁ to A₄ are, at each occurrence identically or differently, selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof;
y is, at each occurrence identically or differently, selected from 1, 2, 3, 4 or 5;
X₁ to X₄ are each independently selected from C or N;
K₁ to K₄ are each independently selected from a single bond, O or S;
Rₙ represents, at each occurrence identically or differently, mono-substitution, multiple substitutions or non-substitution;
R_{q} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{q} and Rₙ can be optionally joined to form a ring.

In this embodiment, the expression that adjacent substituents R_{q} and Rₙ can be optionally joined to form a ring is intended to mean that any one or more of groups of adjacent substituents, such as two substituents R_{q}, two substituents Rₙ, and substituents R_{q} and Rₙ, may be joined to form a ring. Obviously, it is also possible that none of these groups of adjacent substituents are joined to form a ring.

According to an embodiment of the present disclosure, the metal complex has a structure represented by Formula 3-A:

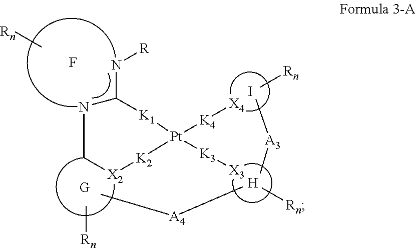

wherein in Formula 3-A,
the ring F is selected from an unsaturated heterocyclic ring having 1 to 30 carbon atoms; the ring G, the ring H, and the ring I are each independently selected from an unsaturated carbocyclic ring having 5 to 30 carbon atoms, an unsaturated heterocyclic ring having 3 to 30 carbon atoms or a combination thereof;
A₃ and A₄ are each independently selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2, 3, 4 or 5;
K₁ to K₄ are each independently selected from a single bond, O or S;
X₂ to X₄ are each independently selected from C or N;
Rₙ represents, at each occurrence identically or differently, mono-substitution, multiple substitutions or non-substitution;
R, R_{q}, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, R_{q}, and Rₙ can be optionally joined to form a ring.

In this embodiment, the expression that adjacent substituents R, R_{q}, and Rₙ can be optionally joined to form a ring is intended to mean that any one or more of groups of adjacent substituents, such as two substituents R_{q}, two substituents Rₙ, substituents R_{q} and Rₙ, and substituents R and Rₙ, may be joined to form a ring. Obviously, it is also possible that none of these groups of adjacent substituents are joined to form a ring.

According to an embodiment of the present disclosure, in Formula 3 or Formula 3-A, the ring F is selected from an unsaturated heterocyclic ring having 3 to 30 carbon atoms; the ring G, the ring H, and the ring I are each independently selected from a five-membered unsaturated carbocyclic ring, an aromatic ring having 6 to 30 carbon atoms or a heteroaromatic ring having 3 to 30 carbon atoms.

According to an embodiment of the present disclosure, in Formula 3 or Formula 3-A, the ring F is selected from an unsaturated heterocyclic ring having 3 to 18 carbon atoms; the ring G, the ring H, and the ring I are each independently selected from a five-membered unsaturated carbocyclic ring, an aromatic ring having 6 to 18 carbon atoms or a heteroaromatic ring having 3 to 18 carbon atoms.

According to an embodiment of the present disclosure, in Formula 3 or Formula 3-A, the ring F is selected from an imidazole-carbene ring or a benzimidazole-carbene ring; the ring G, the ring H, and the ring I are each independently selected from a benzene ring, a pyridine ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring or a silole ring.

According to an embodiment of the present disclosure, K₁ to K₄ are selected from a single bond.

According to an embodiment of the present disclosure, the metal complex has a structure represented by one of Formula 3-1 to Formula 3-20:

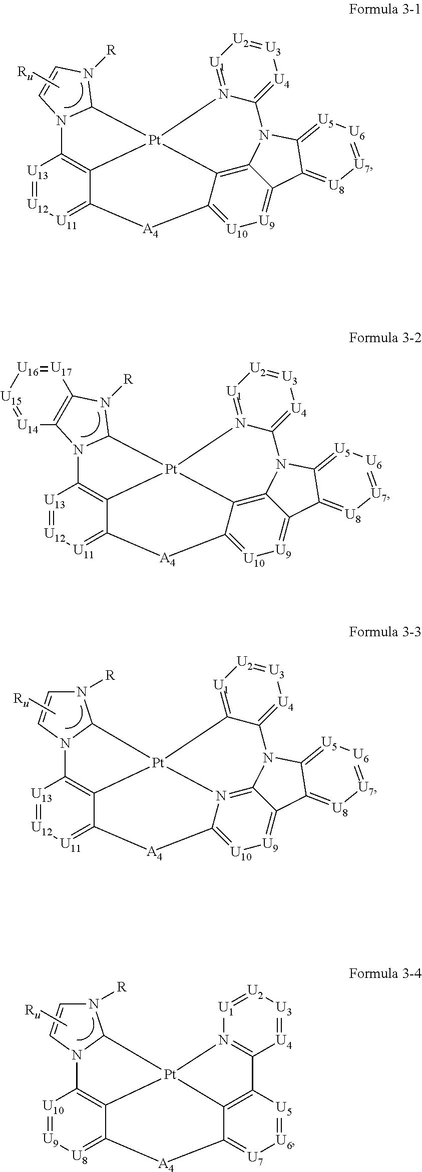

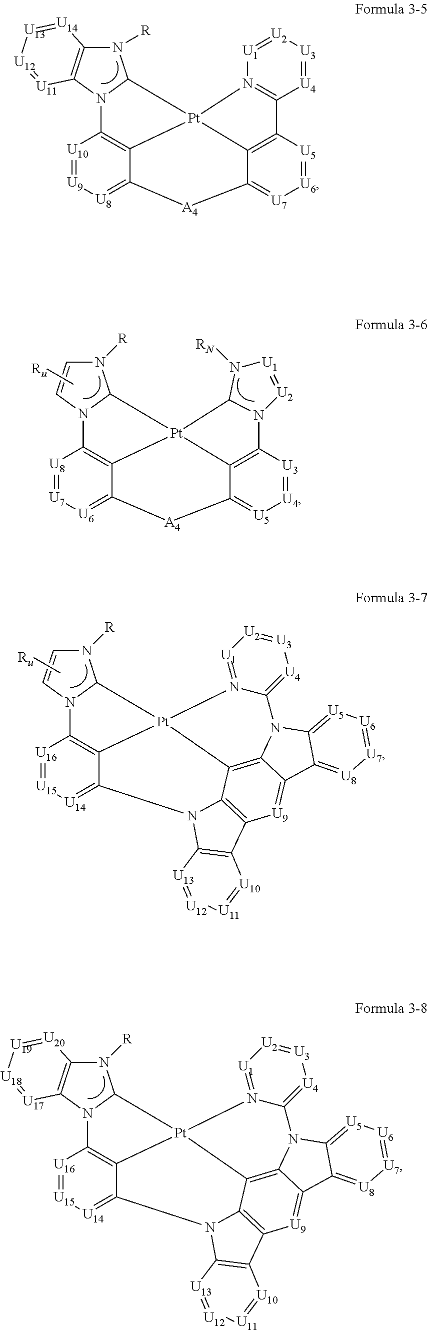

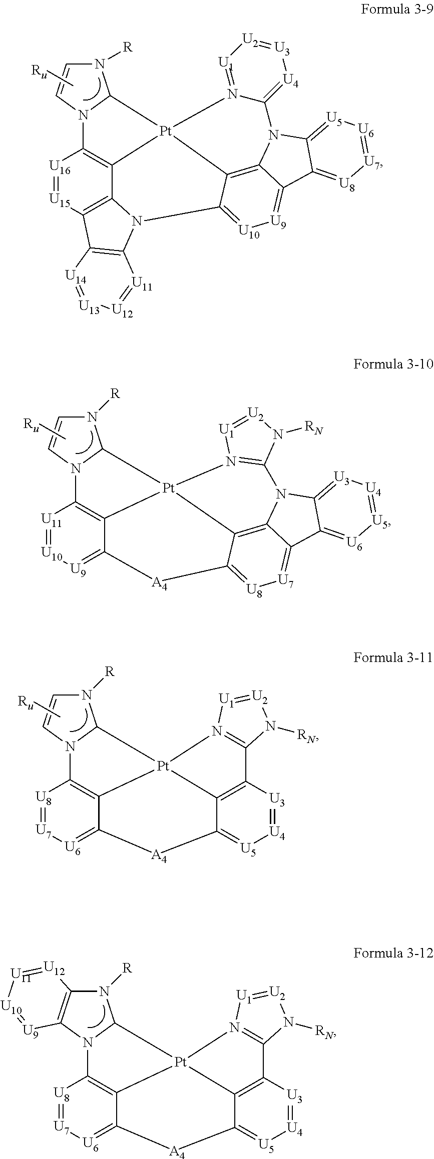

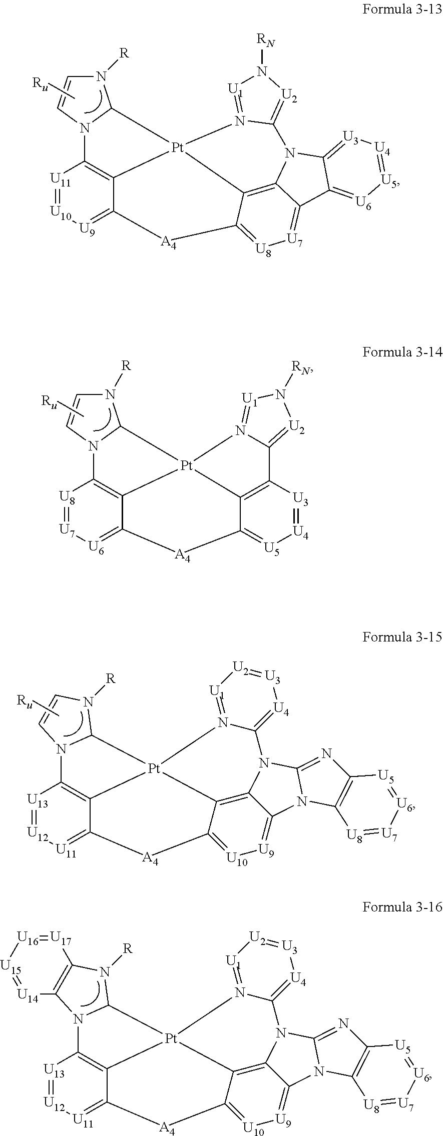

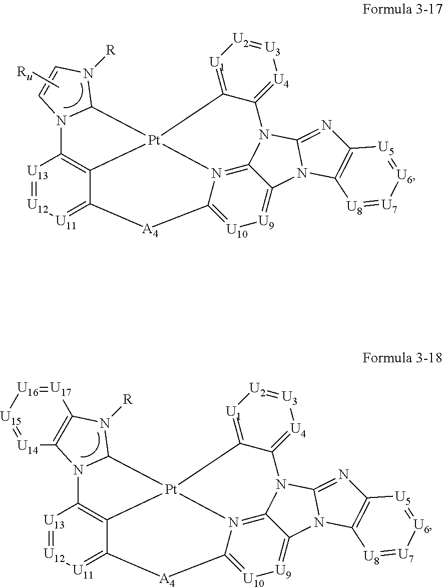

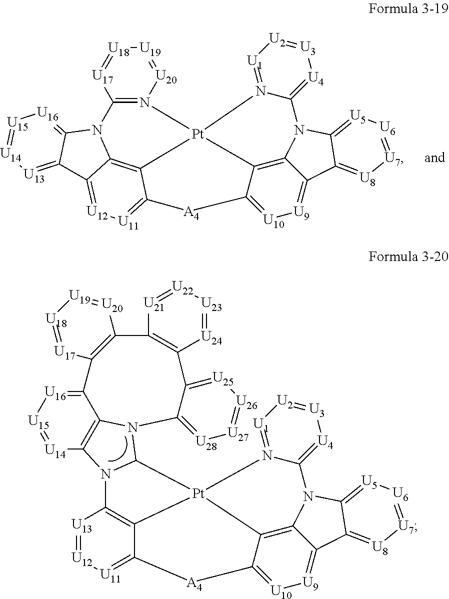

wherein,
A₄ is, at each occurrence identically or differently, selected from a single bond, O, S, Se, (SiR_{q}R_{q})_{y}, PR_{q}, NR_{q}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2 or 3;
U₁ to U₂₈ are, at each occurrence identically or differently, selected from CRₙ or N;
Rᵤ represents, at each occurrence identically or differently, mono-substitution, multiple substitutions or non-substitution;
R, R_{N}, R_{q}, Rᵤ, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, R_{N}, R_{q}, Rᵤ, and Rₙ can be optionally joined to form a ring.

In this embodiment, the expression that adjacent substituents R, R_{N}, R_{q}, Rᵤ, and Rₙ can be optionally joined to form a ring is intended to mean that any one or more of groups of adjacent substituents, such as two substituents R_{q}, two substituents Rᵤ, two substituents Rₙ, substituents R and Rᵤ, substituents R and Rₙ, substituents R_{N} and Rₙ, and substituents R_{q} and Rₙ, may be joined to form a ring. Obviously, it is also possible that none of these groups of adjacent substituents are joined to form a ring.

According to an embodiment of the present disclosure, the metal complex has a structure represented by Formula 3-1 or Formula 3-2.

According to an embodiment of the present disclosure, A₄ is selected from a single bond, O or S.

According to an embodiment of the present disclosure, A₄ is selected from O.

According to an embodiment of the present disclosure, U₁ to U₂₈ are, at each occurrence identically or differently, selected from CRₙ, and Rₙ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, Rₙ is, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuryl, dibenzofuryl, benzosilolyl, dibenzosilolyl, benzothienyl, dibenzothienyl, dibenzoselenophenyl, and combinations thereof.

According to an embodiment of the present disclosure, the substituent R has a structure represented by Formula 4:

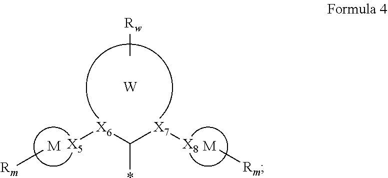

wherein in Formula 4,
the ring M and the ring W are, at each occurrence identically or differently, selected from an unsaturated carbocyclic ring having 5 to 30 carbon atoms, an unsaturated heterocyclic ring having 3 to 30 carbon atoms or a combination thereof;
X₅ to X₈ are, at each occurrence identically or differently, selected from C or N;
“*” represents a position where Formula 4 is joined;
Rₘ and R_{w} represent, at each occurrence identically or differently, mono-substitution, multiple substitutions or non-substitution;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₘ and R_{w} can be optionally joined to form a ring.

Herein, the expression that adjacent substituents Rₘ and R_{w} can be optionally joined to form a ring is intended to mean that any one or more of groups of adjacent substituents, such as two substituents Rₘ, two substituents R_{w}, and substituents Rₘ and R_{w}, may be joined to form a ring. Obviously, it is also possible that none of these groups of adjacent substituents are joined to form a ring.

According to an embodiment of the present disclosure, the substituent R has a structure represented by Formula 4-1:

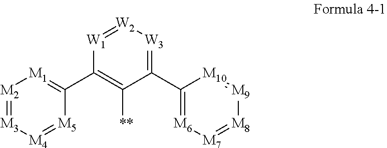

wherein in Formula 4-1,
M₁ to M₁₀ are each independently selected from CRₘ or N;
W₁ to W₃ are each independently selected from CR_{w} or N;
“* *” represents a position where Formula 4-1 is joined;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₘ and R_{w} can be optionally joined to form a ring.

According to an embodiment of the present disclosure, the substituent R or at least one R_{w} in Formula 4 or Formula 4-1 is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, the substituent R or at least one R_{w} in Formula 4 or Formula 4-1 is selected from the group consisting of: deuterium, halogen, substituted or unsubstituted alkyl having 2 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, M₁ to M₁₀ are each independently selected from CRₘ.

According to an embodiment of the present disclosure, W₁ to W₃ are each independently selected from CR_{w}.

According to an embodiment of the present disclosure, Rₘ and R_{w} are, at each occurrence identically or differently, selected from the group consisting of: hydrogen, deuterium, halogen, a cyano group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, M₁ to M₁₀ are selected from CH or CD.

According to an embodiment of the present disclosure, W₂ is selected from CR_{w}, and R_{w} is selected from the group consisting of: deuterium, halogen, a cyano group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, W₂ is selected from CR_{w}, and R_{w} is selected from the group consisting of: deuterium, halogen, a cyano group, a hydroxyl group, a sulfanyl group, substituted or unsubstituted alkyl having 2 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, the metal complex has a structure represented by general formula Pt(Lₐ)(L_{b}), wherein Lₐ and L_{b} are a first ligand and a second ligand coordinated to metal Pt, respectively. For example, for

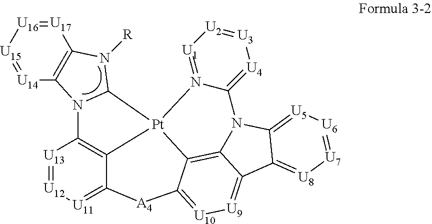

Lₐ has a structure represented by Formula A:

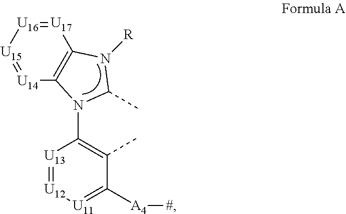

wherein “#” in Formula A represents a position where L_{b} is joined; and L_{b} has a structure represented by Formula B:

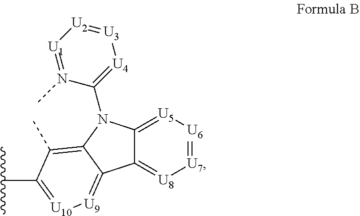

wherein

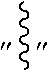

in Formula B represents a position where Lₐ is joined.

According to an embodiment of the present disclosure, the metal complex is selected from the group consisting of BD1 to BD18, wherein the specific structures of BD1 to BD18 are referred to claim 16.

According to an embodiment of the present disclosure, the metal complex has a structure represented by Pt(Lₐ)(L_{b}), wherein Lₐ and L_{b} are a first ligand and a second ligand coordinated to metal Pt, respectively, Lₐ is selected from the group consisting of Lₐ1-1 to Lₐ1-25 and Lₐ2-1 to Lₐ2-6, and L_{b} is selected from the group consisting of L_{b}1-1 to L_{b}1-8 and L_{b}2-1 to L_{b}2-22, wherein the specific structures of Lₐ1-1 to Lₐ1-25, Lₐ2-1 to Lₐ2-6, L_{b}1-1 to L_{b}1-8, and L_{b}2-1 to L_{b}2-22 are referred to claim 16.

According to an embodiment of the present disclosure, the metal complex is selected from the group consisting of Pt1 to Pt81, and Pt1 to Pt81 each have a structure represented by Pt(Lₐ)(L_{b}), wherein the specific structures of Pt1 to Pt81 are referred to claim 16.

According to an embodiment of the present disclosure, the metal complex is a phosphorescent sensitizer.

According to an embodiment of the present disclosure, the first host compound and the second host compound are each independently selected from the group consisting of compounds containing at least one of the following chemical groups: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, the first host compound has a structure represented by one of Formula 5 to Formula 7:

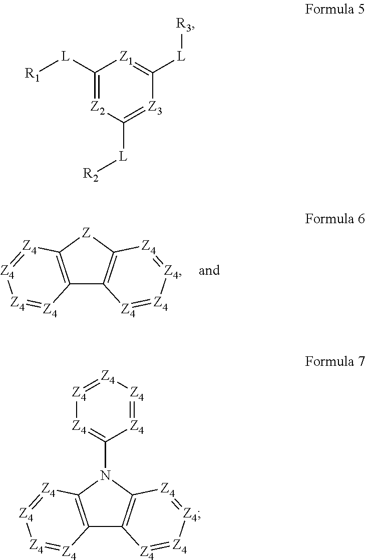

wherein in Formula 5, Z₁ to Z₃ are, at each occurrence identically or differently, selected from CR₄ or N, and at least one of Z₁ to Z₃ is N;
L is, at each occurrence identically or differently, selected from the group consisting of: a single bond, substituted or unsubstituted arylene having 6 to 30 carbon atoms, substituted or unsubstituted heteroarylene having 3 to 30 carbon atoms and combinations thereof;
in Formula 6 and Formula 7, Z₄ is, at each occurrence identically or differently, selected from CR₄ or N, and at least one Z₄ is N;
Z is, at each occurrence identically or differently, selected from O or S;
R₁ to R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₄ can be optionally joined to form a ring.

Herein, the expression that adjacent substituents R₄ can be optionally joined to form a ring is intended to mean that adjacent two substituents R₄ may be joined to form a ring. Obviously, it is also possible that two adjacent substituents R₄ are not joined to form a ring.

According to an embodiment of the present disclosure, the first host compound has a structure represented by Formula 5-1 or Formula 6-1:

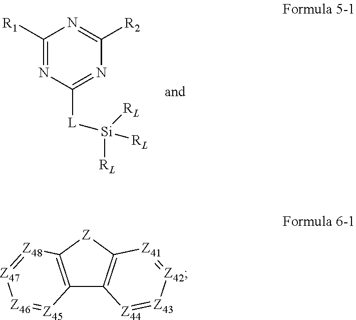

wherein in Formula 5-1,
R¹ and R₂ are each independently selected from substituted or unsubstituted heteroaryl having 3 to 30 carbon atoms;
L is selected from a single bond, substituted or unsubstituted arylene having 6 to 30 carbon atoms, substituted or unsubstituted heteroarylene having 3 to 30 carbon atoms or a combination thereof;
in Formula 6-1,
Z is selected from O or S;
Z₄₁ to Z₄₈ are, at each occurrence identically or differently, selected from CR₄, CR₄′ or N, at least one of Z₄₁ to Z₄₈ is selected from N, and at least one of Z₄₁ to Z₄₈ is selected from CR₄′;
R₄′ is, at each occurrence identically or differently, selected from substituted or unsubstituted aryl having 6 to 30 carbon atoms, substituted or unsubstituted heteroaryl having 3 to 30 carbon atoms or a combination thereof;
R_{L} and R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₄ can be optionally joined to form a ring.

According to an embodiment of the present disclosure, L is, at each occurrence identically or differently, selected from the group consisting of: a single bond, substituted or unsubstituted arylene having 6 to 18 carbon atoms, substituted or unsubstituted heteroarylene having 3 to 18 carbon atoms, and combinations thereof.

According to an embodiment of the present disclosure, L is, at each occurrence identically or differently, selected from the group consisting of: a single bond, phenylene, biphenylene, fluorenylene, triphenylenylene, furylene, thienylene, dibenzofurylene, dibenzothienylene, and combinations thereof.

According to an embodiment of the present disclosure, R_{L} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, R_{L} is, at each occurrence identically or differently, selected from substituted or unsubstituted aryl having 6 to 30 carbon atoms.

According to an embodiment of the present disclosure, R_{L} is, at each occurrence identically or differently, selected from the group consisting of: phenyl, biphenyl, triphenylene, indenyl, fluorenyl, indolyl, carbazolyl, benzofuranyl, dibenzofuranyl, benzosilolyl, dibenzosilolyl, benzothienyl, dibenzothienyl, dibenzoselenophenyl, and combinations thereof.

According to an embodiment of the present disclosure, R₁ to R₄ are, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, R₁ to R₄ are, at each occurrence identically or differently, selected from the group consisting of: hydrogen, deuterium, halogen, a cyano group, substituted or unsubstituted aryl having 6 to 18 carbon atoms, substituted or unsubstituted heteroaryl having 3 to 18 carbon atoms, and combinations thereof.

According to an embodiment of the present disclosure, R₁ to R₄ are, at each occurrence identically or differently, selected from the group consisting of: hydrogen, deuterium, fluorine, a cyano group, phenyl, biphenyl, triphenylene, indenyl, fluorenyl, indolyl, carbazolyl, benzofuranyl, dibenzofuranyl, benzosilolyl, dibenzosilolyl, benzothienyl, dibenzothienyl, dibenzoselenophenyl, triazinyl, and combinations thereof.

According to an embodiment of the present disclosure, in Formula 6-1, at least one of Z₄₁ to Z₄₈ is selected from N, and at least two of Z₄₁ to Z₄₈ are selected from CR₄′.

According to an embodiment of the present disclosure, in Formula 6-1, only one of Z₄₁ to Z₄₈ is selected from N, and only two of Z₄₁ to Z₄₈ are selected from CR₄′.

According to an embodiment of the present disclosure, in Formula 6-1, Z₄₂ is selected from N, and Z₄₁ and Z₄₆ are selected from CR₄′.

According to an embodiment of the present disclosure, the first host compound is selected from the group consisting of Compound N-1-1 to Compound N-1-60, Compound N-2-1 to Compound N-2-35, and Compound N-3-1 to Compound N-3-9, wherein the specific structures of Compound N-1-1 to Compound N-1-60, Compound N-2-1 to Compound N-2-35, and Compound N-3-1 to Compound N-3-9 are referred to claim 19.

According to an embodiment of the present disclosure, hydrogens in the structures of Compound N-1-1 to Compound N-1-53, Compound N-1-58, Compound N-2-1 to Compound N-2-32, and Compound N-3-1 to Compound N-3-7 can be partially or fully substituted with deuterium.

According to an embodiment of the present disclosure, the second host compound has a structure represented by Formula 8:

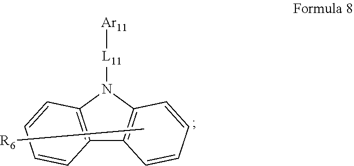

wherein in Formula 8,
L₁₁ is selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₆ can be optionally joined to form a ring.

Herein, the expression that adjacent substituents R₆ can be optionally joined to form a ring is intended to mean that adjacent two substituents R₆ may be joined to form a ring. Obviously, it is also possible that two adjacent substituents R₆ are not joined to form a ring.

According to an embodiment of the present disclosure, the second host compound has a structure represented by Formula 8-1 or Formula 8-2:

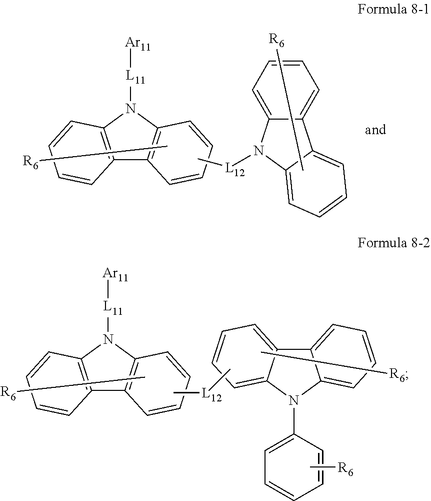

wherein L₁₁ and L₁₂ are selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₆ can be optionally joined to form a ring.

According to an embodiment of the present disclosure, the second host compound has a structure represented by Formula 8-3 or Formula 8-4:

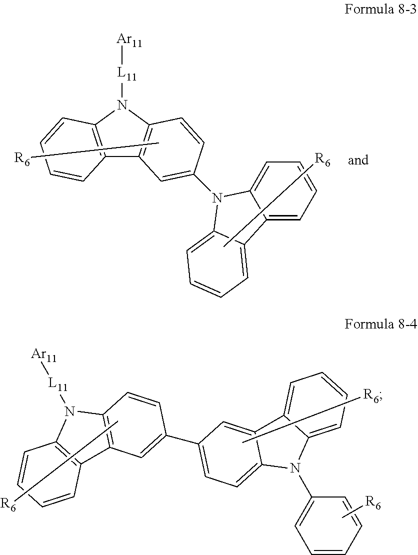

Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
L₁₁ is selected from a single bond, substituted or unsubstituted arylene having 6 to 30 carbon atoms, substituted or unsubstituted heteroarylene having 3 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₆ can be optionally joined to form a ring.

According to an embodiment of the present disclosure, R₆ is, at each occurrence identically or differently, selected from the group consisting of: hydrogen, deuterium, halogen, a cyano group, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, R₆ is, at each occurrence identically or differently, selected from the group consisting of: hydrogen, deuterium, halogen, a cyano group, substituted or unsubstituted aryl having 6 to 18 carbon atoms, substituted or unsubstituted heteroaryl having 3 to 18 carbon atoms, and combinations thereof.

According to an embodiment of the present disclosure, R₆ is, at each occurrence identically or differently, selected from the group consisting of: hydrogen, deuterium, fluorine, cyano, phenyl, biphenyl, triphenylene, indenyl, fluorenyl, indolyl, carbazolyl, benzofuranyl, dibenzofuranyl, benzosilolyl, dibenzosilolyl, benzothienyl, dibenzothienyl, dibenzoselenophenyl, and combinations thereof.

According to an embodiment of the present disclosure, the second host compound is selected from the group consisting of Compound P-1 to Compound P-38, wherein the specific structures of Compound P-1 to Compound P-38 are referred to claim 20.

According to an embodiment of the present disclosure, hydrogens in the structures of Compound P-1 to Compound P-23 and Compound P-27 to Compound P-38 can be partially or fully substituted with deuterium.

According to an embodiment of the present disclosure, the weight of the first host compound and the second host compound accounts for 65% to 98.9% of the total weight of materials in an emissive layer, the weight of the metal complex accounts for 1% to 30% of the total weight of materials in the emissive layer, and the weight of the fluorescent emissive material accounts for 0.1% to 5% of the total weight of materials in the emissive layer.

According to an embodiment of the present disclosure, the weight of the first host compound and the second host compound accounts for 82% to 94.5% of the total weight of materials in the emissive layer, the weight of the metal complex accounts for 5% to 15% of the total weight of materials in the emissive layer, and the weight of the fluorescent emissive material accounts for 0.5% to 3% of the total weight of materials in the emissive layer.

According to an embodiment of the present disclosure, the weight of the first host compound and the second host compound accounts for 86.5% to 91.5% of the total weight of materials in the emissive layer, the weight of the metal complex accounts for 8% to 12% of the total weight of materials in the emissive layer, and the weight of the fluorescent emissive material accounts for 0.5% to 1.5% of the total weight of materials in the emissive layer.

According to an embodiment of the present disclosure, the device emits blue light.

According to an embodiment of the present disclosure, the device emits deep blue light.

According to an embodiment of the present disclosure, the device emits white light.

According to an embodiment of the present disclosure, the maximum emission wavelength of the device is 460 nm to 470 nm.

According to an embodiment of the present disclosure, a display apparatus is disclosed. The display apparatus includes the organic electroluminescent device described in any one of the preceding embodiments.

According to an embodiment of the present disclosure, a composition is disclosed. The composition includes a fluorescent emissive material, a metal complex, a first host compound, and a second host compound;
wherein the fluorescent emissive material has a structure represented by Formula 1:

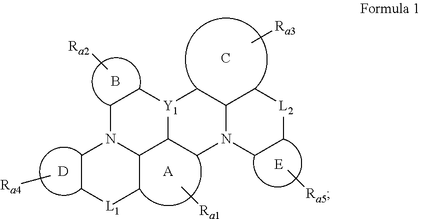

wherein in Formula 1,
the ring A is selected from an unsaturated carbocyclic ring having 5 to 30 carbon atoms or an unsaturated heterocyclic ring having 4 to 30 carbon atoms;
the ring B, the ring C, the ring D, and the ring E are each independently selected from an unsaturated carbocyclic ring having 5 to 30 carbon atoms or an unsaturated heterocyclic ring having 3 to 30 carbon atoms;
Y₁ is selected from B, P═O, P═S, As, As═O, As═S, SiR′ or GeR′;
Rₐ₁, Rₐ₂, Rₐ₃, Rₐ₄, and Rₐ₅ represent, at each occurrence identically or differently, mono-substitution, multiple substitutions or non-substitution;
R′, Rₐ₁, Rₐ₂, Rₐ₃, Rₐ₄, and Rₐ₅ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ and L₂ are each independently selected from the group consisting of: a single bond, O, S, Se, SiR_{L1}R_{L1}, PR_{L1}, R_{L1}C═CR_{L1}, substituted or unsubstituted arylene having 6 to 30 carbon atoms, substituted or unsubstituted heteroarylene having 3 to 30 carbon atoms, and combinations thereof;
R_{L1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof;
adjacent substituents Rₐ₁ can be optionally joined to form a ring;
adjacent substituents Rₐ₂ can be optionally joined to form a ring;
adjacent substituents Rₐ₃ can be optionally joined to form a ring;
adjacent substituents Rₐ₄ can be optionally joined to form a ring;
adjacent substituents Rₐ₅ can be optionally joined to form a ring; and
adjacent substituents R_{L1} can be optionally joined to form a ring.
   Combination with Other Materials

The materials described in the present disclosure for a particular layer in an organic light emitting device can be used in combination with various other materials present in the device. The combinations of these materials are described in more detail in U.S. patent application No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. patent application No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The emissive material and the metal complex used in the present disclosure can be easily obtained with reference to the preparation methods in the related art, and the preparation methods thereof are not repeated here.

The method for preparing an organic electroluminescent device is not limited. The preparation methods in the following device examples are merely examples and are not to be construed as limitations. Based on the related art, those skilled in the art can make reasonable improvements on the preparation methods in the following examples. For example, the proportions of materials in an emissive layer are not particularly limited. Those skilled in the art can reasonably select the proportions of materials within a certain range based on the related art. For example, taking the total weight of the materials in the emissive layer as a reference, two host compounds may account for 65% to 98.9%, the metal complex may account for 1% to 30%, and the emissive material may account for 0.1% to 5%; two host compounds may account for 82% to 94.5%, the metal complex may account for 5% to 15%, and the emissive material may account for 0.5% to 3%; or two host compounds may account for 86.5% to 91.5%, the metal complex may account for 8% to 12%, and the emissive material may account for 0.5% to 1.5%. Further, the ratio of the two host compounds may range from 99:1 to 1:99; the ratio may range from 80:20 to 20:80; or the ratio may range from 70:30 to 30:70. In the examples of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to those skilled in the art.

### DEVICE EXAMPLE

### Device Example 1

First, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially evaporated through vacuum thermal evaporation on the ITO anode at a rate of 0.2 to 2 Angstroms (Å) per second at a vacuum level of about 10⁻⁷ torr. Compound HT and Compound HI were co-evaporated (at a weight ratio of 97:3) as a hole injection layer (HIL) with a thickness of 100 Å. Compound HT was evaporated as a hole transport layer (HTL) with a thickness of 250 Å. Compound P-21 was evaporated as an electron blocking layer (EBL) with a thickness of 50 Å. Then, a first host compound Compound N-1-15, a second host compound Compound P-22, a metal complex Pt27, and a fluorescent emissive material Compound BD-1-1 were co-evaporated (at a weight ratio of 34.9:52.1:12:1) as an emissive layer (EML) with a thickness of 350 Å. Compound N-3-2 was evaporated as a hole blocking layer (HBL) with a thickness of 50 Å. On the hole blocking layer, Compound ET and 8-hydroxyquinolinolato-lithium (Liq) were co-evaporated (at a weight ratio of 40:60) as an electron transport layer (ETL) with a thickness of 310 Å. Finally, LiF was evaporated as an electron injection layer with a thickness of 15 Å, and Al was evaporated as a cathode with a thickness of 1200 Å. The device was then transferred back to the glovebox and encapsulated with a glass lid and a moisture getter to complete the device.

### Device Example 2

The implementation mode of Device Example 2 was the same as the implementation mode of Device Example 1 except that in the emissive layer (EML), Compound N-1-15 was replaced with Compound N-3-2.

### Device Example 3

The implementation mode of Device Example 3 was the same as the implementation mode of Device Example 1 except that in the emissive layer (EML), Compound BD-1-1 was replaced with Compound BD-1-24.

### Device Example 4

The implementation mode of Device Example 4 was the same as the implementation mode of Device Example 2 except that in the emissive layer (EML), Compound BD-1-1 was replaced with Compound BD-1-24.

### Device Comparative Example 1

The implementation mode of Device Comparative Example 1 was the same as the implementation mode of Device Example 1 except that the first host compound Compound N-1-15, the second host compound Compound P-22, and the fluorescent emissive material Compound BD-1-1 were co-evaporated (at a weight ratio of 39.6:59.4:1) as an emissive layer (EML).

### Device Comparative Example 2

The implementation mode of Device Comparative Example 2 was the same as the implementation mode of Device Comparative Example 1 except that in the emissive layer (EML), Compound N-1-15 was replaced with Compound N-3-2.

### Device Comparative Example 3

The implementation mode of Device Comparative Example 3 was the same as the implementation mode of Device Example 1 except that in the emissive layer (EML), Compound BD-1-1 was replaced with Compound BD.

Detailed structures and thicknesses of layers of the devices are shown in the following table. A layer using more than one material is obtained by doping different compounds at their weight ratio as recorded.

TABLE 2
Part of device structures in Device Examples and Device Comparative Examples

| Device ID | HIL | HTL | EBL | EML | HBL | ETL |
|---|---|---|---|---|---|---|
| Example 1 | Compound | Compound | Compound | Compound P- | Compound | Compound |
| | HT:Compound | HT | P-21 | 22:Compound | N-3-2 | ET:Liq |
| | HI (97:3) | (250 Å) | (50 Å) | N-1-15:Metal | (50 Å) | (40:60) |
| | (100 Å) | | | Complex | | (310 Å) |
| | | | | Pt27:Compound | | |
| | | | | BD-1-1 | | |
| | | | | (52.1:34.9:12:1) | | |
| | | | | (350 Å) | | |
| Example 2 | Compound | Compound | Compound | Compound P- | Compound | Compound |
| | HT:Compound | HT | P-21 | 22:Compound | N-3-2 | ET:Liq |
| | HI (97:3) | (250 Å) | (50 Å) | N-3-2:Metal | (50 Å) | (40:60) |
| | (100 Å) | | | Complex | | (310 Å) |
| | | | | Pt27:Compound | | |
| | | | | BD-1-1 | | |
| | | | | (52.1:34.9:12:1) | | |
| | | | | (350 Å) | | |
| Example 3 | Compound | Compound | Compound | Compound P- | Compound | Compound |
| | HT:Compound | HT | P-21 | 22:Compound | N-3-2 | ET:Liq |
| | HI (97:3) | (250 Å) | (50 Å) | N-1-15:Metal | (50 Å) | (40:60) |
| | (100 Å) | | | Complex | | (310 Å) |
| | | | | Pt27:Compound | | |
| | | | | BD-1-24 | | |
| | | | | (52.1:34.9:12:1) | | |
| | | | | (350 Å) | | |
| Example 4 | Compound | Compound | Compound | Compound P- | Compound | Compound |
| | HT:Compound | HT | P-21 | 22:Compound | N-3-2 | ET:Liq |
| | HI (97:3) | (250 Å) | (50 Å) | N-3-2:Metal | (50 Å) | (40:60) |
| | (100 Å) | | | Complex | | (310 Å) |
| | | | | Pt27:Compound | | |
| | | | | BD-1-24 | | |
| | | | | (52.1:34.9:12:1) | | |
| | | | | (350 Å) | | |
| Comparative | Compound | Compound | Compound | Compound P- | Compound | Compound |
| Example 1 | HT:Compound | HT | P-21 | 22:Compound | N-3-2 | ET:Liq |
| | HI (97:3) | (250 Å) | (50 Å) | N-1- | (50 Å) | (40:60) |
| | (100 Å) | | | 15:Compound | | (310 Å) |
| | | | | BD-1-1 | | |
| | | | | (59.4:39.6:1) | | |
| | | | | (350 Å) | | |
| Comparative | Compound | Compound | Compound | Compound P- | Compound | Compound |
| Example 2 | HT:Compound | HT | P-21 | 22:Compound | N-3-2 | ET:Liq |
| | HI (97:3) | (250 Å) | (50 Å) | N-3- | (50 Å) | (40:60) |
| | (100 Å) | | | 2:Compound | | (310 Å) |
| | | | | BD-1-1 | | |
| | | | | (59.4:39.6:1) | | |
| | | | | (350 Å) | | |
| Comparative | Compound | Compound | Compound | Compound P- | Compound | Compound |
| Example 3 | HT:Compound | HT | P-21 | 22:Compound | N-3-2 | ET:Liq |
| | HI (97:3) | (250 Å) | (50 Å) | N-1-15:Metal | (50 Å) | (40:60) |
| | (100 Å) | | | Complex | | (310 Å) |
| | | | | Pt27:Compound | | |
| | | | | BD | | |
| | | | | (52.1:34.9:12:1) | | |
| | | | | (350 Å) | | |

The structures of the materials used in the devices are as follows:

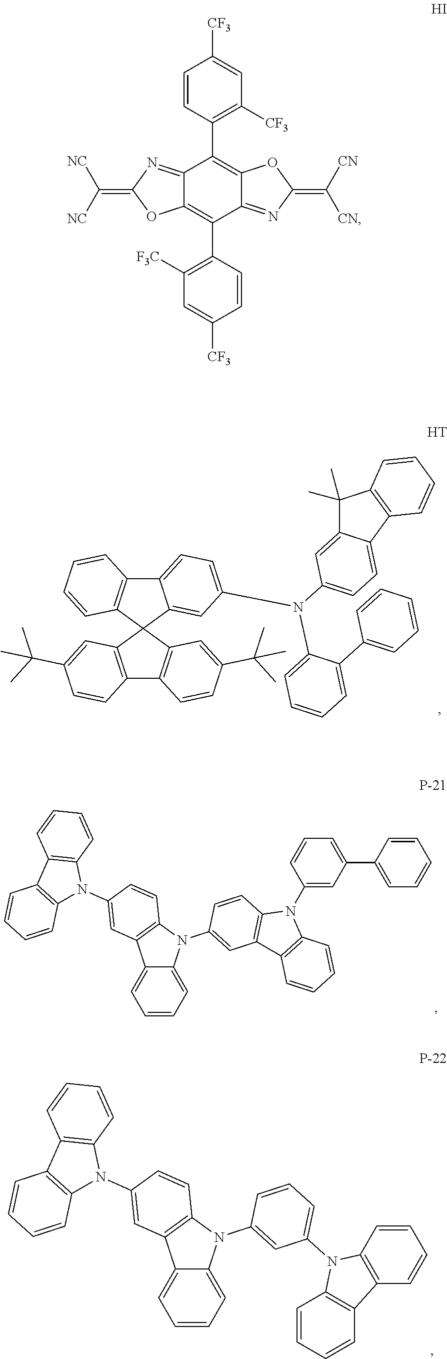 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; c1ccc(-c2cccc(-n3c4ccccc4c4cc(-n5c6ccccc6c6cc(-n7c8ccccc8c8ccccc87)ccc65)ccc43)c2)cc1 ; c1cc(-n2c3ccccc3c3ccccc32)cc(-n2c3ccccc3c3cc(-n4c5ccccc5c5ccccc54)ccc32)c1]

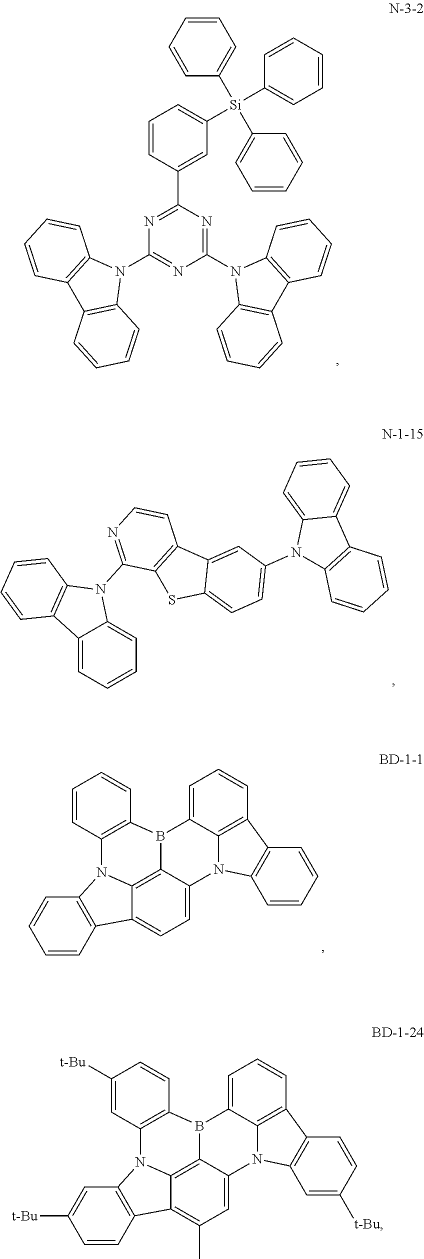 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc2c(c1)c1ccccc1n2-c1ccc2sc3c(-n4c5ccccc5c5ccccc54)nccc3c2c1 ; c1ccc2c(c1)B1c3cccc4c5ccccc5n(c34)-c3ccc4c5ccccc5n-2c4c31 ; Cc1cc2c3c4c1c1ccc(C(C)(C)C)cc1n4-c1cc(C(C)(C)C)ccc1B3c1cccc3c4ccc(C(C)(C)C)cc4n-2c13]

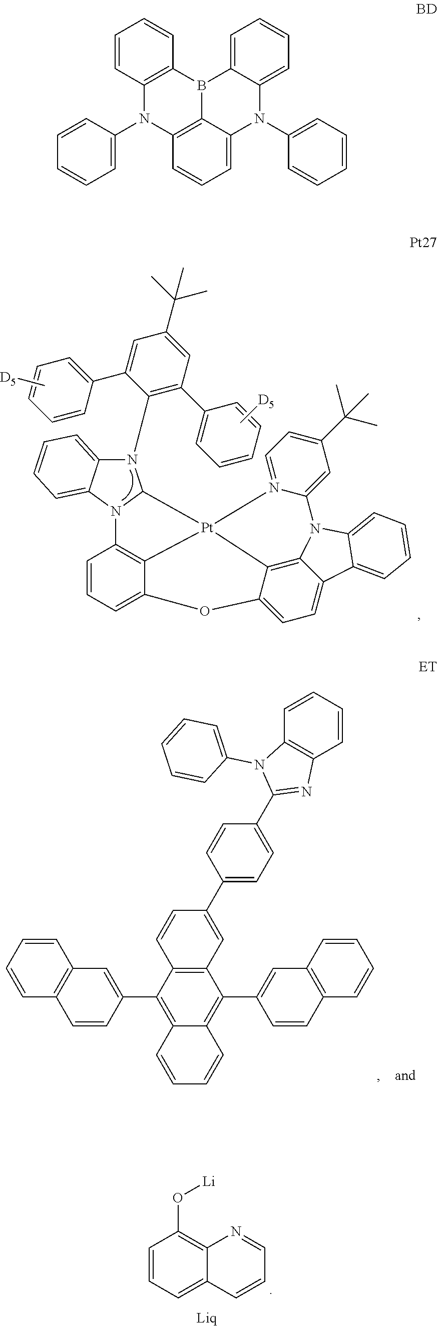

The CIE values, maximum emission wavelengths (λₘₐₓ), full widths at half maximum (FWHM), current efficiency (CE), and lifetime (LT97) of Examples 1 to 4 and Comparative Examples 1 to 3 were measured at 10 mA/cm², wherein LT97 refers to the time for a device's brightness to decay to 97% of its initial brightness. The related data are shown in Table 3.

TABLE 3
Device data

| | | λₘₐₓ | FWHM | CE | LT97 |
|---|---|---|---|---|---|
| Device ID | CIE (x, y) | [nm] | [nm] | [cd/A] | [h] |
| Example 1 | 0.121, 0.176 | 470 | 36.4 | 16.38 | 9.01 |
| Example 2 | 0.123, 0.152 | 468 | 31.8 | 15.99 | 12.51 |
| Example 3 | 0.123, 0.146 | 467 | 34.0 | 20.05 | 5.02 |
| Example 4 | 0.126, 0.142 | 467 | 31.7 | 19.57 | 9.69 |
| Comparative | 0.124, 0.176 | 471 | 35.5 | 4.51 | 2.17 |
| Example 1 | | | | | |
| Comparative | 0.127, 0.145 | 468 | 30.7 | 4.62 | 2.83 |
| Example 2 | | | | | |
| Comparative | 0.132, 0.104 | 461 | 27.0 | 14.74 | 1.17 |
| Example 3 | | | | | |

As can be seen from the data in Table 3, compared to the common fluorescent device of Comparative Example 1, the device of Example 1 maintains a narrow full width at half maximum substantially equivalent to the full width at half maximum of the device of Comparative Example 1; but more importantly, the current efficiency increases by as much as 263%, and the lifetime increases by as much as 315%. Similarly, compared to the common fluorescent device of Comparative Example 2, the device of Example 2 also maintains a narrow full width at half maximum substantially equivalent to the full width at half maximum of the device of Comparative Example 2; but more importantly, the current efficiency increases by as much as 246%, and the lifetime increases by as much as 342%. Meanwhile, the devices of Example 3 and Example 4, in which Compound BD-1-24 is used as a fluorescent emissive material in the emissive layer, can also achieve good device performance with a narrow full width at half maximum and long device lifetime, and in particular, achieve very excellent current efficiency. The above data show that by using a metal complex as the phosphorescent sensitizer in the emissive layer and with the combination of a fluorescent emissive material having a specific structure of Formula 1, a first host compound, and a second host compound, the device of the present disclosure can achieve very excellent device performance. The device not only can maintain a narrow full width at half maximum which is on a par with the full width at half maximum of a common fluorescent device, but also can achieve a substantial increase in current efficiency and lifetime, and thus the device is able to make up for the deficiency in efficiency and lifetime of a common fluorescent device.

Compound BD having a structure different from the structure of Formula 1 is used as the fluorescent emissive material in the emissive layer of the device of Comparative Example 3. As can be seen from the device data, although the device of Comparative Example 3 is at a high level in terms of full width at half maximum and current efficiency, it has a very large deficiency in terms of lifetime. Compared to the device of Comparative Example 3, although the full widths at half maximum of the devices of Examples 1 to 4 increase, they are still at the level of narrow full widths at half maximum; the increase in current efficiency of the devices of Examples 1 to 4 is in the range of 8.48% to 36.0%, and especially, the increase in lifetime is as high as 329% to 969%. The above data prove that the device of the present disclosure can achieve very excellent device performance by using a fluorescent emissive material having a structure represented by a specific formula 1 in the emissive layer.

In summary, by containing a fluorescent emissive material having a structure represented by a specific formula 1, a metal complex, a first host compound, and a second host compound in an emissive layer, the device of the present disclosure can achieve very excellent device performance and has a narrow full width at half maximum, high current efficiency, and very excellent device lifetime, which proves that the device of the present disclosure has excellent performance and broad application prospects.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. An organic electroluminescent device, comprising:
an anode,
a cathode, and
an emissive layer disposed between the anode and the cathode, wherein the emissive layer comprises a fluorescent emissive material, a metal complex, a first host compound, and a second host compound;
wherein the fluorescent emissive material has a structure represented by Formula 1: 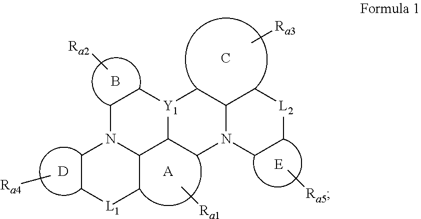
wherein in Formula 1,
the ring A is selected from an unsaturated carbocyclic ring having 5 to 30 carbon atoms or an unsaturated heterocyclic ring having 4 to 30 carbon atoms;
the ring B, the ring C, the ring D, and the ring E are each independently selected from an unsaturated carbocyclic ring having 5 to 30 carbon atoms or an unsaturated heterocyclic ring having 3 to 30 carbon atoms;
Y₁ is selected from B, P═O, P═S, As, As═O, As═S, SiR′ or GeR′;
Rₐ₁, Rₐ₂, Rₐ₃, Rₐ₄, and Rₐ₅ represent, at each occurrence identically or differently, mono-substitution, multiple substitutions or non-substitution;
R′, Rₐ₁, Rₐ₂, Rₐ₃, Rₐ₄, and Rₐ₅ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ and L₂ are each independently selected from the group consisting of: a single bond, O, S, Se, SiR_{L1}R_{L1}, PR_{L1}, R_{L1}C═CR_{L1}, substituted or unsubstituted arylene having 6 to 30 carbon atoms, substituted or unsubstituted heteroarylene having 3 to 30 carbon atoms, and combinations thereof;
R_{L1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof;
adjacent substituents Rₐ₁ can be optionally joined to form a ring;
adjacent substituents Rₐ₂ can be optionally joined to form a ring;
adjacent substituents Rₐ₃ can be optionally joined to form a ring;
adjacent substituents Rₐ₄ can be optionally joined to form a ring;
adjacent substituents Rₐ₅ can be optionally joined to form a ring; and
adjacent substituents R_{L1} can be optionally joined to form a ring.

2. The organic electroluminescent device according to claim 1, wherein the ring A, the ring B, the ring C, the ring D, and the ring E are each independently selected from a five-membered unsaturated carbocyclic ring, an aromatic ring having 6 to 30 carbon atoms or a heteroaromatic ring having 4 to 30 carbon atoms;
preferably, the ring A, the ring B, the ring C, the ring D, and the ring E are, at each occurrence identically or differently, selected from a five-membered unsaturated carbocyclic ring, an aromatic ring having 6 to 18 carbon atoms or a heteroaromatic ring having 4 to 18 carbon atoms;
more preferably, the ring A, the ring B, the ring C, the ring D, and the ring E are, at each occurrence identically or differently, selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring or a combination thereof.

3. The organic electroluminescent device according to claim 1, wherein Y₁ is selected from B, P═O or P═S; preferably, Y is selected from B.

4. The organic electroluminescent device according to claim 1, wherein the fluorescent emissive material has a structure represented by Formula 1-1: 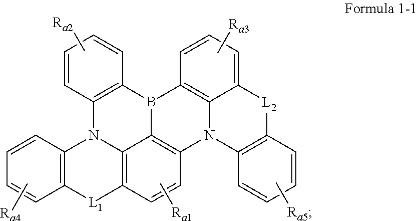
wherein,
Rₐ₁, Rₐ₂, Rₐ₃, Rₐ₄, and Rₐ₅ represent, at each occurrence identically or differently, mono-substitution, multiple substitutions or non-substitution;
Rₐ₁, Rₐ₂, Rₐ₃, Rₐ₄, and Rₐ₅ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ and L₂ are each independently selected from the group consisting of: a single bond, O, S, Se, SiR_{L1}R_{L1}, PR_{L1}, R_{L1}C═CR_{L1}, substituted or unsubstituted arylene having 6 to 30 carbon atoms, substituted or unsubstituted heteroarylene having 3 to 30 carbon atoms, and combinations thereof;
R_{L1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof;
adjacent substituents Rₐ₁ can be optionally joined to form a ring;
adjacent substituents Rₐ₂ can be optionally joined to form a ring;
adjacent substituents Rₐ₃ can be optionally joined to form a ring;
adjacent substituents Rₐ₄ can be optionally joined to form a ring;
adjacent substituents Rₐ₅ can be optionally joined to form a ring; and
adjacent substituents R_{L1} can be optionally joined to form a ring.

5. The organic electroluminescent device according to claim 1, wherein the L₁ and L₂ are each independently selected from a single bond, O or S; preferably, the L₁ and L₂ are each a single bond.

6. The organic electroluminescent device according to claim 1, wherein the Rₐ₁, Rₐ₂, Rₐ₃, Rₐ₄, and Rₐ₅ are, at each occurrence identically or differently, selected from the group consisting of: hydrogen, deuterium, halogen, a cyano group, a hydroxyl group, a sulfanyl group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, and combinations thereof;
preferably, the Rₐ₁, Rₐ₂, Rₐ₃, Rₐ₄, and Rₐ₅ are, at each occurrence identically or differently, selected from the group consisting of: hydrogen, deuterium, halogen, a cyano group, a hydroxyl group, a sulfanyl group, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted heterocyclic group having 3 to 6 ring atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof;
more preferably, the Rₐ₁, Rₐ₂, Rₐ₃, Rₐ₄, and Rₐ₅ are, at each occurrence identically or differently, selected from the group consisting of: hydrogen, deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, quarterphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, diphenylamino, dibenzofurylphenylamino, and combinations thereof.

7. The organic electroluminescent device according to claim 1, wherein at least one of the Rₐ₁, Rₐ₂, Rₐ₃, Rₐ₄, and Rₐ₅ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least one of the Rₐ₁, Rₐ₂, Rₐ₃, Rₐ₄, and Rₐ₅ is, at each occurrence identically or differently, selected from the group consisting of: deuterium, halogen, a cyano group, a hydroxyl group, a sulfanyl group, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof;
more preferably, at least one of the Rₐ₁, Rₐ₂, Rₐ₃, Rₐ₄, and Rₐ₅ is, at each occurrence identically or differently, selected from the group consisting of: deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, quarterphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, diphenylamino, dibenzofurylphenylamino, and combinations thereof.

8. The organic electroluminescent device according to claim 1, wherein the fluorescent emissive material is selected from the group consisting of Compound BD-1-1 to Compound BD-1-31, Compound BD-2-1 to Compound BD-2-28, Compound BD-3-1 to Compound BD-3-22, Compound BD-4-1 to Compound BD-4-36, Compound BD-5-1 to Compound BD-5-36, and Compound BD-6-1 to Compound BD-6-42: 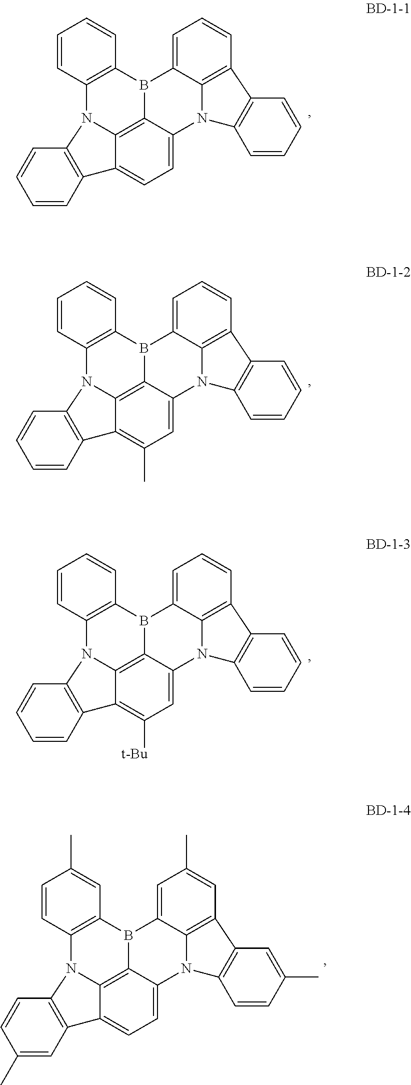 [SMILES: c1ccc2c(c1)B1c3cccc4c5ccccc5n(c34)-c3ccc4c5ccccc5n-2c4c31 ; Cc1cc2c3c4c1c1ccccc1n4-c1ccccc1B3c1cccc3c4ccccc4n-2c13 ; CC(C)(C)c1cc2c3c4c1c1ccccc1n4-c1ccccc1B3c1cccc3c4ccccc4n-2c13 ; Cc1ccc2c(c1)B1c3cc(C)cc4c5cc(C)ccc5n(c34)-c3ccc4c5cc(C)ccc5n-2c4c31] 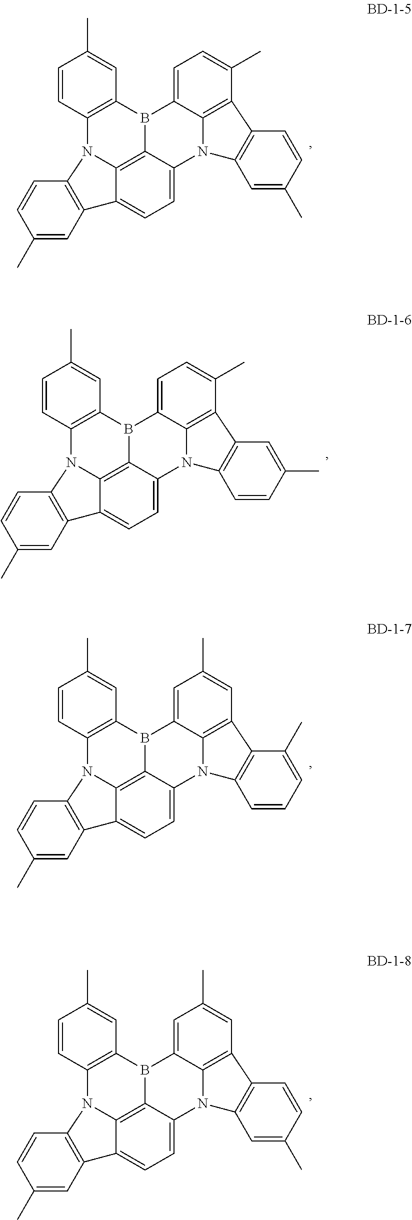 [SMILES: Cc1ccc2c(c1)B1c3c(ccc4c5cc(C)ccc5n-2c34)-n2c3cc(C)ccc3c3c(C)ccc1c32 ; Cc1ccc2c(c1)B1c3c(ccc4c5cc(C)ccc5n-2c34)-n2c3ccc(C)cc3c3c(C)ccc1c32 ; Cc1ccc2c(c1)B1c3c(ccc4c5cc(C)ccc5n-2c34)-n2c3cccc(C)c3c3cc(C)cc1c32 ; Cc1ccc2c(c1)B1c3cc(C)cc4c5ccc(C)cc5n(c34)-c3ccc4c5cc(C)ccc5n-2c4c31] 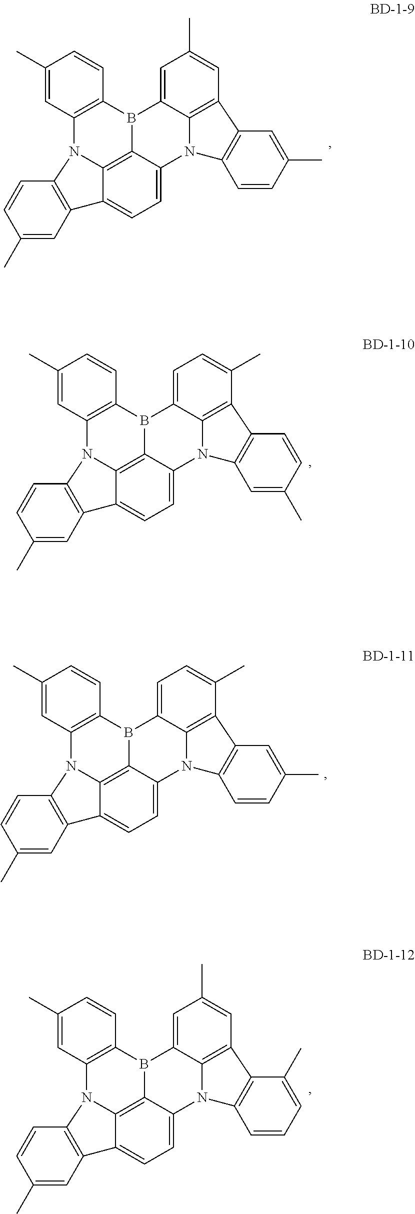 [SMILES: Cc1ccc2c(c1)-n1c3ccc(C)cc3c3ccc4c(c31)B2c1cc(C)cc2c3cc(C)ccc3n-4c12 ; Cc1ccc2c(c1)-n1c3ccc(C)cc3c3ccc4c(c31)B2c1ccc(C)c2c3ccc(C)cc3n-4c12 ; Cc1ccc2c(c1)-n1c3ccc(C)cc3c3ccc4c(c31)B2c1ccc(C)c2c3cc(C)ccc3n-4c12 ; Cc1ccc2c(c1)-n1c3ccc(C)cc3c3ccc4c(c31)B2c1cc(C)cc2c3c(C)cccc3n-4c12] 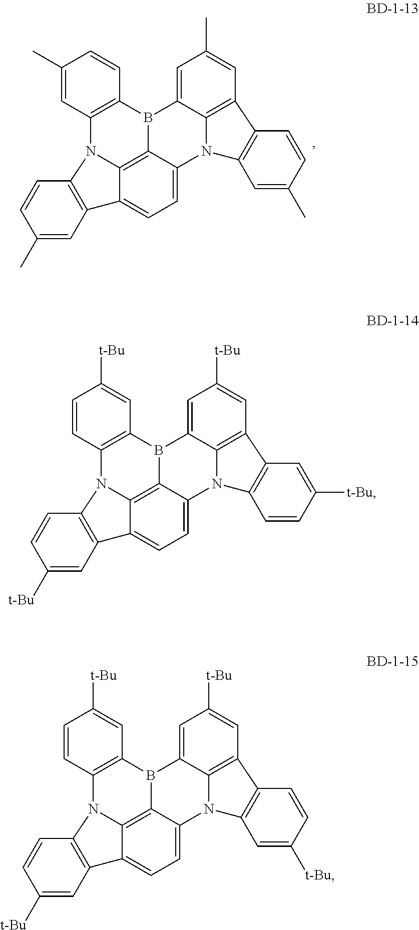 [SMILES: Cc1ccc2c(c1)-n1c3ccc(C)cc3c3ccc4c(c31)B2c1cc(C)cc2c3ccc(C)cc3n-4c12 ; CC(C)(C)c1ccc2c(c1)B1c3cc(C(C)(C)C)cc4c5cc(C(C)(C)C)ccc5n(c34)-c3ccc4c5cc(C(C)(C)C)ccc5n-2c4c31 ; CC(C)(C)c1ccc2c(c1)B1c3cc(C(C)(C)C)cc4c5ccc(C(C)(C)C)cc5n(c34)-c3ccc4c5cc(C(C)(C)C)ccc5n-2c4c31] 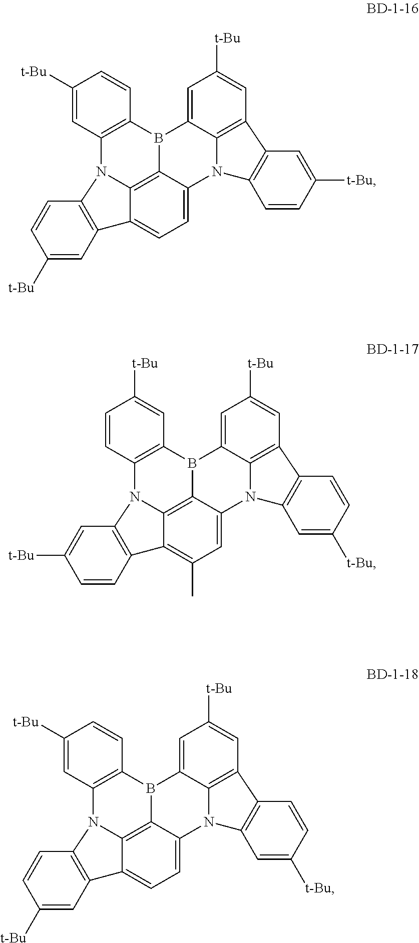 [SMILES: CC(C)(C)c1ccc2c(c1)-n1c3ccc(C(C)(C)C)cc3c3ccc4c(c31)B2c1cc(C(C)(C)C)cc2c3cc(C(C)(C)C)ccc3n-4c12 ; Cc1cc2c3c4c1c1ccc(C(C)(C)C)cc1n4-c1ccc(C(C)(C)C)cc1B3c1cc(C(C)(C)C)cc3c4ccc(C(C)(C)C)cc4n-2c13 ; CC(C)(C)c1ccc2c(c1)-n1c3ccc(C(C)(C)C)cc3c3ccc4c(c31)B2c1cc(C(C)(C)C)cc2c3ccc(C(C)(C)C)cc3n-4c12] 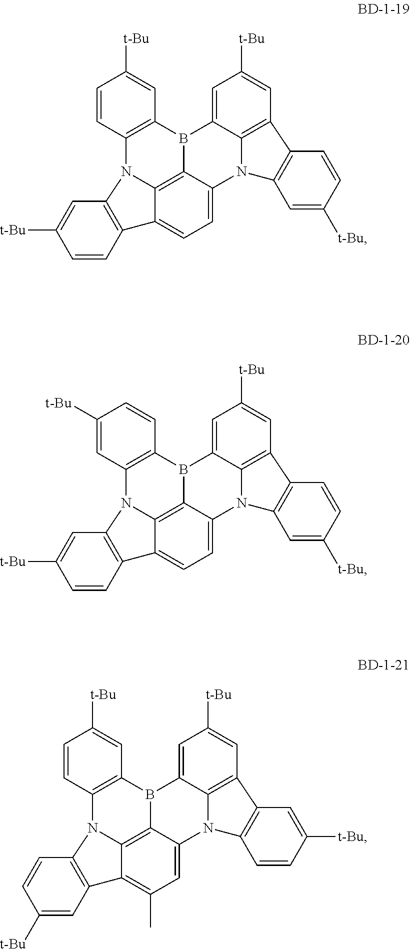 [SMILES: CC(C)(C)c1ccc2c(c1)B1c3cc(C(C)(C)C)cc4c5ccc(C(C)(C)C)cc5n(c34)-c3ccc4c5ccc(C(C)(C)C)cc5n-2c4c31 ; CC(C)(C)c1ccc2c(c1)-n1c3cc(C(C)(C)C)ccc3c3ccc4c(c31)B2c1cc(C(C)(C)C)cc2c3ccc(C(C)(C)C)cc3n-4c12 ; Cc1cc2c3c4c1c1cc(C(C)(C)C)ccc1n4-c1ccc(C(C)(C)C)cc1B3c1cc(C(C)(C)C)cc3c4cc(C(C)(C)C)ccc4n-2c13] 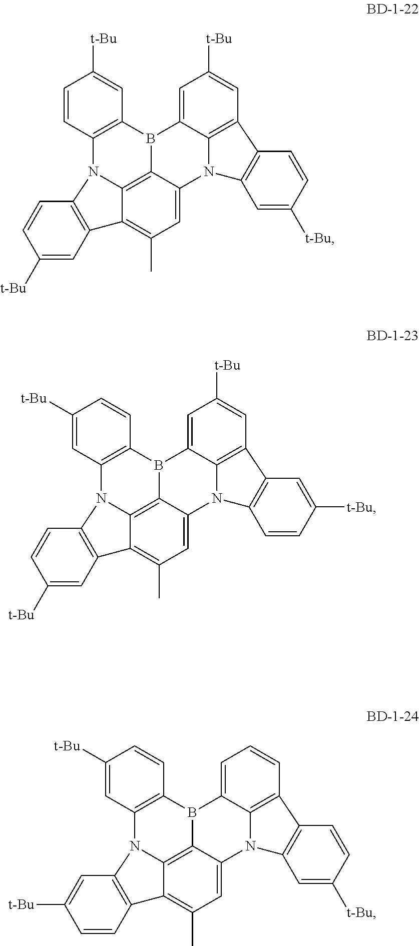 [SMILES: Cc1cc2c3c4c1c1cc(C(C)(C)C)ccc1n4-c1ccc(C(C)(C)C)cc1B3c1cc(C(C)(C)C)cc3c4ccc(C(C)(C)C)cc4n-2c13 ; Cc1cc2c3c4c1c1cc(C(C)(C)C)ccc1n4-c1cc(C(C)(C)C)ccc1B3c1cc(C(C)(C)C)cc3c4cc(C(C)(C)C)ccc4n-2c13 ; Cc1cc2c3c4c1c1ccc(C(C)(C)C)cc1n4-c1cc(C(C)(C)C)ccc1B3c1cccc3c4ccc(C(C)(C)C)cc4n-2c13] 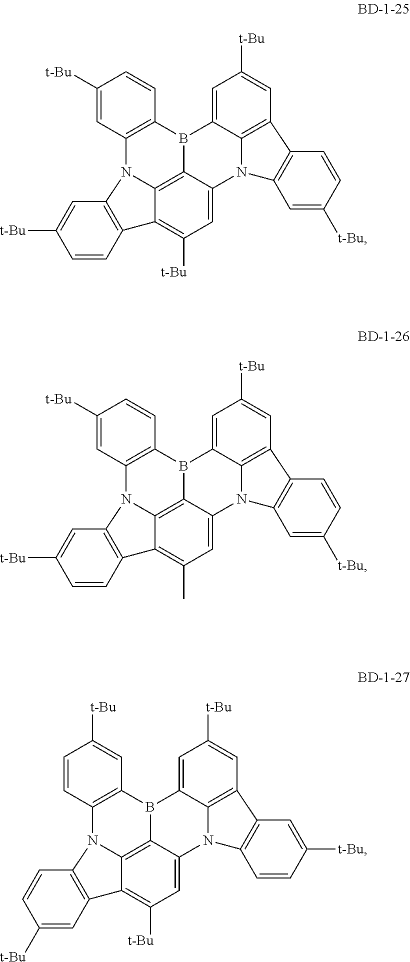 [SMILES: CC(C)(C)c1ccc2c(c1)-n1c3cc(C(C)(C)C)ccc3c3c(C(C)(C)C)cc4c(c31)B2c1cc(C(C)(C)C)cc2c3ccc(C(C)(C)C)cc3n-4c12 ; Cc1cc2c3c4c1c1ccc(C(C)(C)C)cc1n4-c1cc(C(C)(C)C)ccc1B3c1cc(C(C)(C)C)cc3c4ccc(C(C)(C)C)cc4n-2c13 ; CC(C)(C)c1ccc2c(c1)B1c3cc(C(C)(C)C)cc4c5cc(C(C)(C)C)ccc5n(c34)-c3cc(C(C)(C)C)c4c5cc(C(C)(C)C)ccc5n-2c4c31] 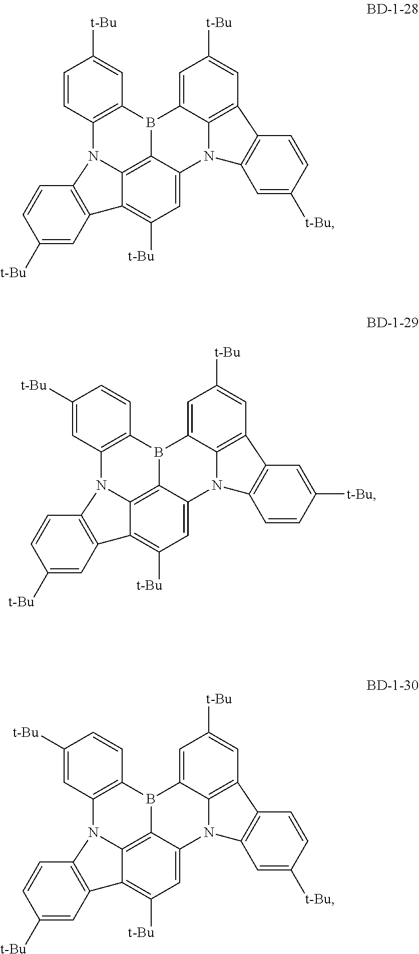 [SMILES: CC(C)(C)c1ccc2c(c1)B1c3cc(C(C)(C)C)cc4c5ccc(C(C)(C)C)cc5n(c34)-c3cc(C(C)(C)C)c4c5cc(C(C)(C)C)ccc5n-2c4c31 ; CC(C)(C)c1ccc2c(c1)-n1c3ccc(C(C)(C)C)cc3c3c(C(C)(C)C)cc4c(c31)B2c1cc(C(C)(C)C)cc2c3cc(C(C)(C)C)ccc3n-4c12 ; CC(C)(C)c1ccc2c(c1)-n1c3ccc(C(C)(C)C)cc3c3c(C(C)(C)C)cc4c(c31)B2c1cc(C(C)(C)C)cc2c3ccc(C(C)(C)C)cc3n-4c12] 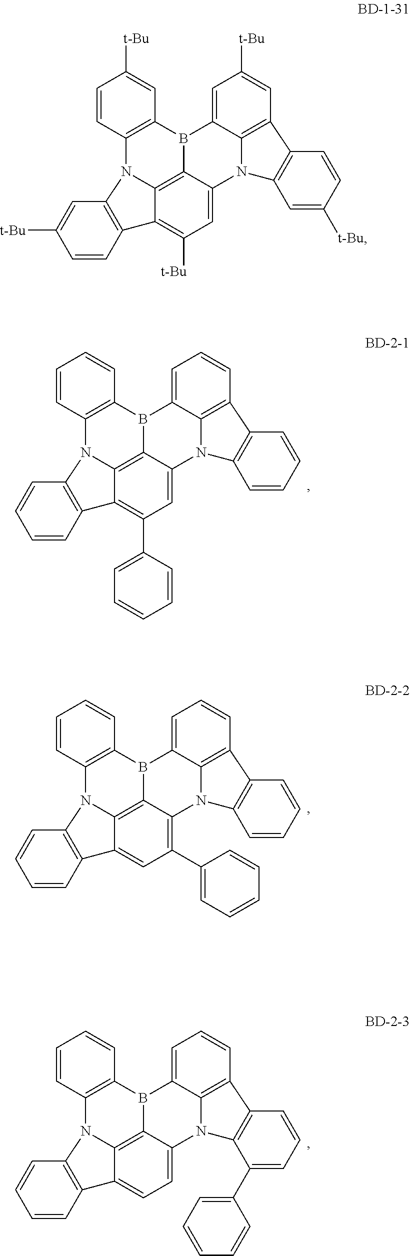 [SMILES: CC(C)(C)c1ccc2c(c1)B1c3cc(C(C)(C)C)cc4c5ccc(C(C)(C)C)cc5n(c34)-c3cc(C(C)(C)C)c4c5ccc(C(C)(C)C)cc5n-2c4c31 ; c1ccc(-c2cc3c4c5c2c2ccccc2n5-c2ccccc2B4c2cccc4c5ccccc5n-3c24)cc1 ; c1ccc(-c2cc3c4ccccc4n4c3c3c2-n2c5ccccc5c5cccc(c52)B3c2ccccc2-4)cc1 ; c1ccc(-c2cccc3c4cccc5c4n(c23)-c2ccc3c4ccccc4n4c3c2B5c2ccccc2-4)cc1] 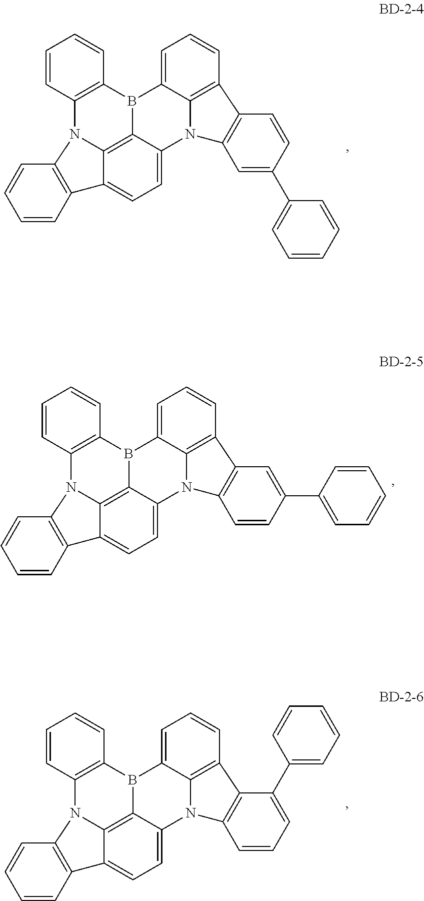 [SMILES: c1ccc(-c2ccc3c4cccc5c4n(c3c2)-c2ccc3c4ccccc4n4c3c2B5c2ccccc2-4)cc1 ; c1ccc(-c2ccc3c(c2)c2cccc4c2n3-c2ccc3c5ccccc5n5c3c2B4c2ccccc2-5)cc1 ; c1ccc(-c2cccc3c2c2cccc4c2n3-c2ccc3c5ccccc5n5c3c2B4c2ccccc2-5)cc1] 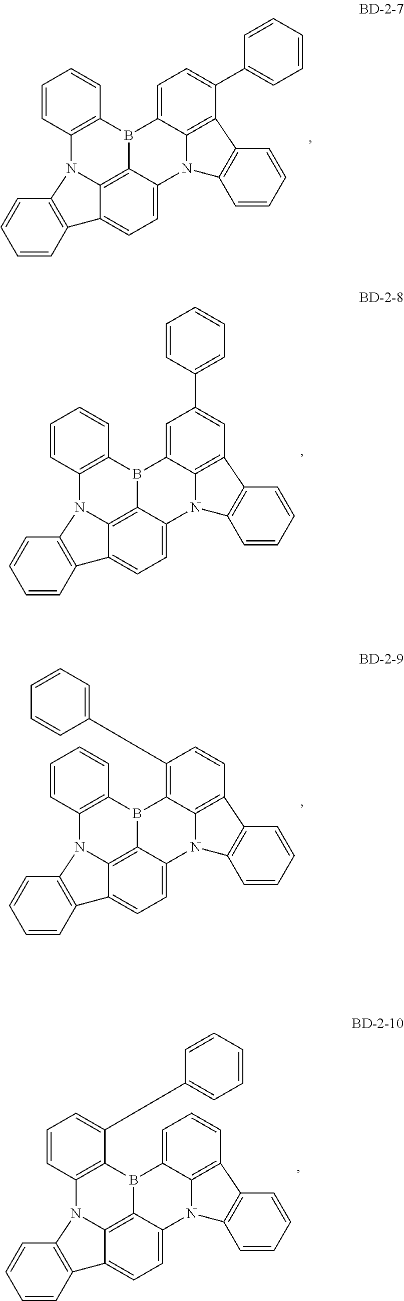 [SMILES: c1ccc(-c2ccc3c4c2c2ccccc2n4-c2ccc4c5ccccc5n5c4c2B3c2ccccc2-5)cc1 ; c1ccc(-c2cc3c4c(c2)c2ccccc2n4-c2ccc4c5ccccc5n5c4c2B3c2ccccc2-5)cc1 ; c1ccc(-c2ccc3c4ccccc4n4c3c2B2c3ccccc3-n3c5ccccc5c5ccc-4c2c53)cc1 ; c1ccc(-c2cccc3c2B2c4cccc5c6ccccc6n(c45)-c4ccc5c6ccccc6n-3c5c42)cc1] 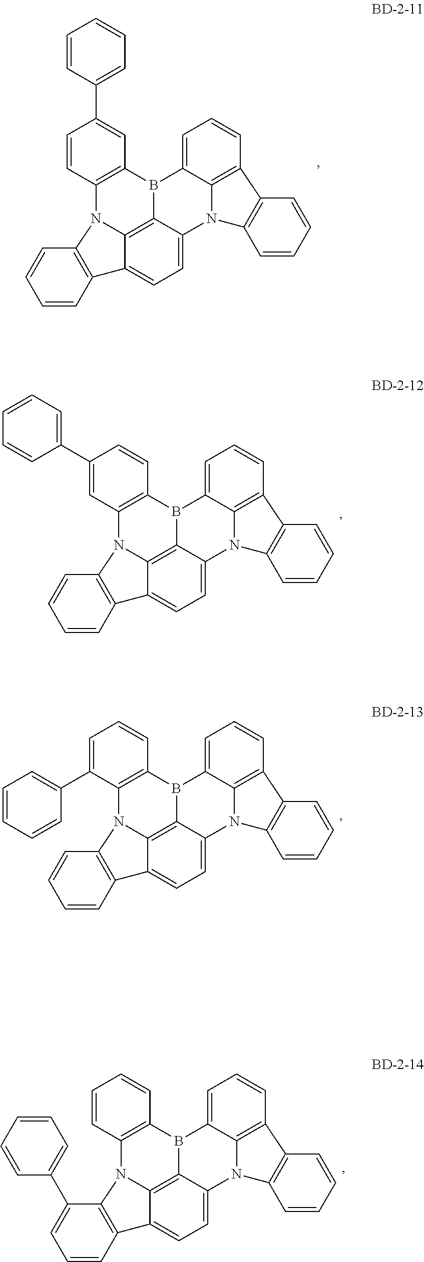 [SMILES: c1ccc(-c2ccc3c(c2)B2c4cccc5c6ccccc6n(c45)-c4ccc5c6ccccc6n-3c5c42)cc1 ; c1ccc(-c2ccc3c(c2)-n2c4ccccc4c4ccc5c(c42)B3c2cccc3c4ccccc4n-5c23)cc1 ; c1ccc(-c2cccc3c2-n2c4ccccc4c4ccc5c(c42)B3c2cccc3c4ccccc4n-5c23)cc1 ; c1ccc(-c2cccc3c4ccc5c6c4n(c23)-c2ccccc2B6c2cccc3c4ccccc4n-5c23)cc1] 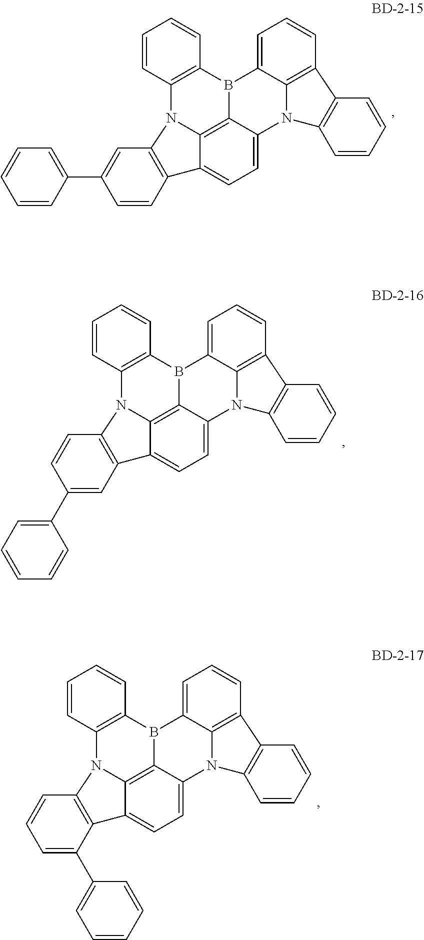 [SMILES: c1ccc(-c2ccc3c4ccc5c6c4n(c3c2)-c2ccccc2B6c2cccc3c4ccccc4n-5c23)cc1 ; c1ccc(-c2ccc3c(c2)c2ccc4c5c2n3-c2ccccc2B5c2cccc3c5ccccc5n-4c23)cc1 ; c1ccc(-c2cccc3c2c2ccc4c5c2n3-c2ccccc2B5c2cccc3c5ccccc5n-4c23)cc1] 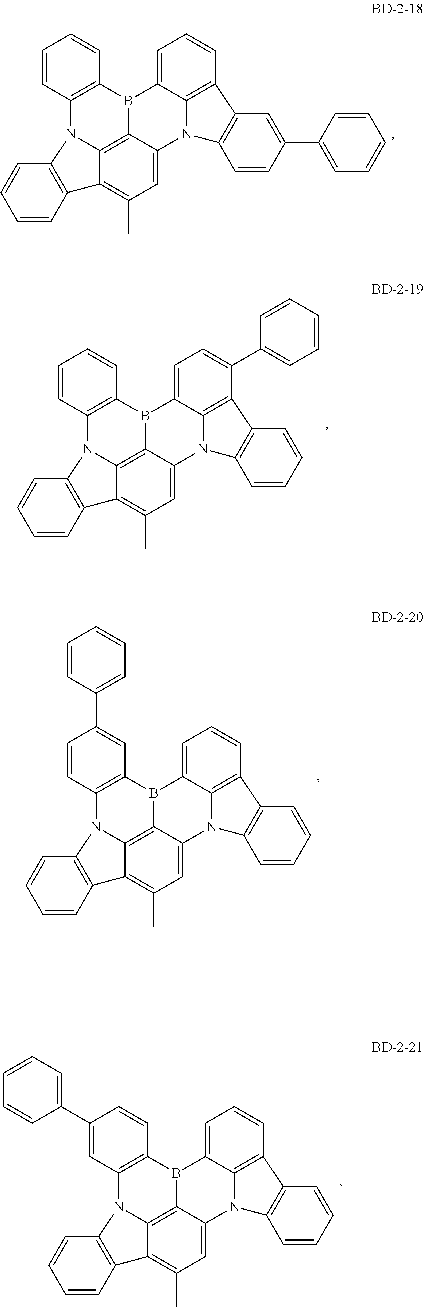 [SMILES: Cc1cc2c3c4c1c1ccccc1n4-c1ccccc1B3c1cccc3c4cc(-c5ccccc5)ccc4n-2c13 ; Cc1cc2c3c4c1c1ccccc1n4-c1ccccc1B3c1ccc(-c3ccccc3)c3c4ccccc4n-2c13 ; Cc1cc2c3c4c1c1ccccc1n4-c1ccc(-c4ccccc4)cc1B3c1cccc3c4ccccc4n-2c13 ; Cc1cc2c3c4c1c1ccccc1n4-c1cc(-c4ccccc4)ccc1B3c1cccc3c4ccccc4n-2c13] 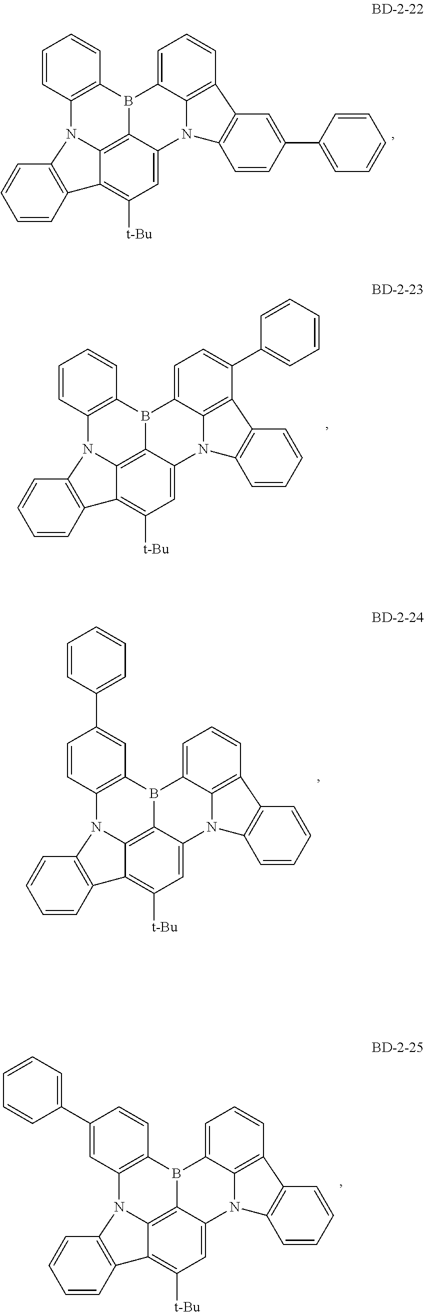 [SMILES: CC(C)(C)c1cc2c3c4c1c1ccccc1n4-c1ccccc1B3c1cccc3c4cc(-c5ccccc5)ccc4n-2c13 ; CC(C)(C)c1cc2c3c4c1c1ccccc1n4-c1ccccc1B3c1ccc(-c3ccccc3)c3c4ccccc4n-2c13 ; CC(C)(C)c1cc2c3c4c1c1ccccc1n4-c1ccc(-c4ccccc4)cc1B3c1cccc3c4ccccc4n-2c13 ; CC(C)(C)c1cc2c3c4c1c1ccccc1n4-c1cc(-c4ccccc4)ccc1B3c1cccc3c4ccccc4n-2c13] 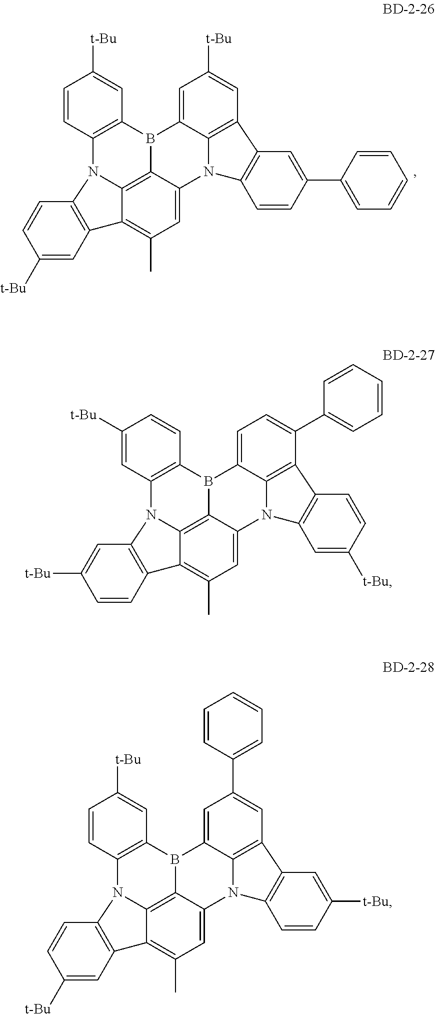 [SMILES: Cc1cc2c3c4c1c1cc(C(C)(C)C)ccc1n4-c1ccc(C(C)(C)C)cc1B3c1cc(C(C)(C)C)cc3c4cc(-c5ccccc5)ccc4n-2c13 ; Cc1cc2c3c4c1c1ccc(C(C)(C)C)cc1n4-c1cc(C(C)(C)C)ccc1B3c1ccc(-c3ccccc3)c3c4ccc(C(C)(C)C)cc4n-2c13 ; Cc1cc2c3c4c1c1cc(C(C)(C)C)ccc1n4-c1ccc(C(C)(C)C)cc1B3c1cc(-c3ccccc3)cc3c4cc(C(C)(C)C)ccc4n-2c13] 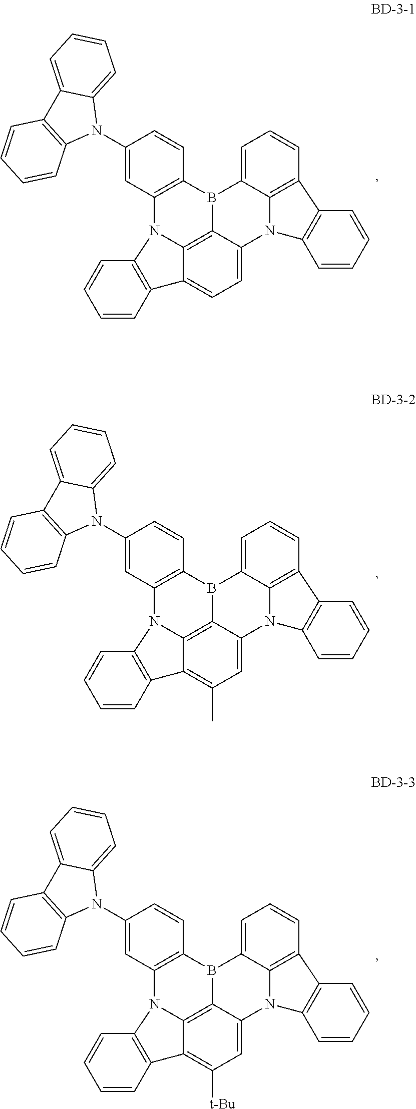 [SMILES: c1ccc2c(c1)c1ccccc1n2-c1ccc2c(c1)-n1c3ccccc3c3ccc4c(c31)B2c1cccc2c3ccccc3n-4c12 ; Cc1cc2c3c4c1c1ccccc1n4-c1cc(-n4c5ccccc5c5ccccc54)ccc1B3c1cccc3c4ccccc4n-2c13 ; CC(C)(C)c1cc2c3c4c1c1ccccc1n4-c1cc(-n4c5ccccc5c5ccccc54)ccc1B3c1cccc3c4ccccc4n-2c13] 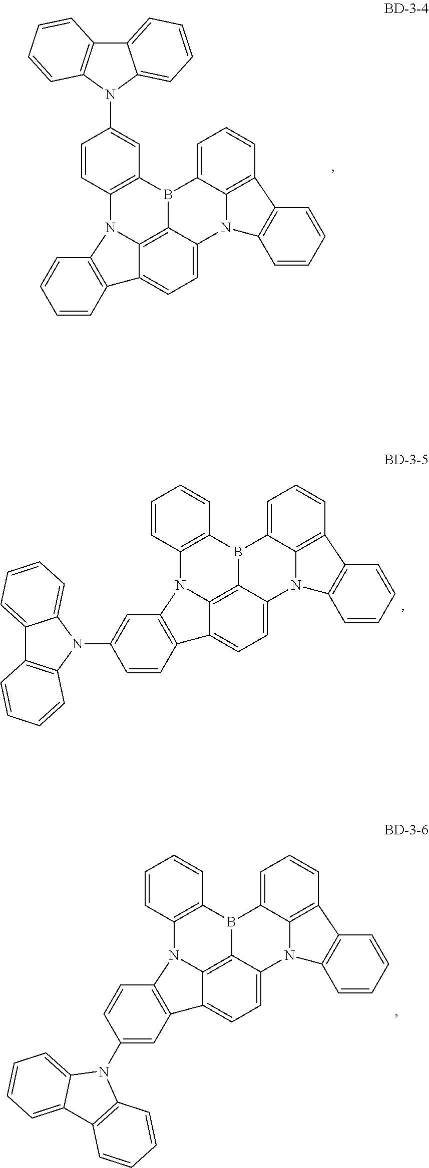 [SMILES: c1ccc2c(c1)c1ccccc1n2-c1ccc2c(c1)B1c3cccc4c5ccccc5n(c34)-c3ccc4c5ccccc5n-2c4c31 ; c1ccc2c(c1)B1c3cccc4c5ccccc5n(c34)-c3ccc4c5ccc(-n6c7ccccc7c7ccccc76)cc5n-2c4c31 ; c1ccc2c(c1)B1c3cccc4c5ccccc5n(c34)-c3ccc4c5cc(-n6c7ccccc7c7ccccc76)ccc5n-2c4c31] 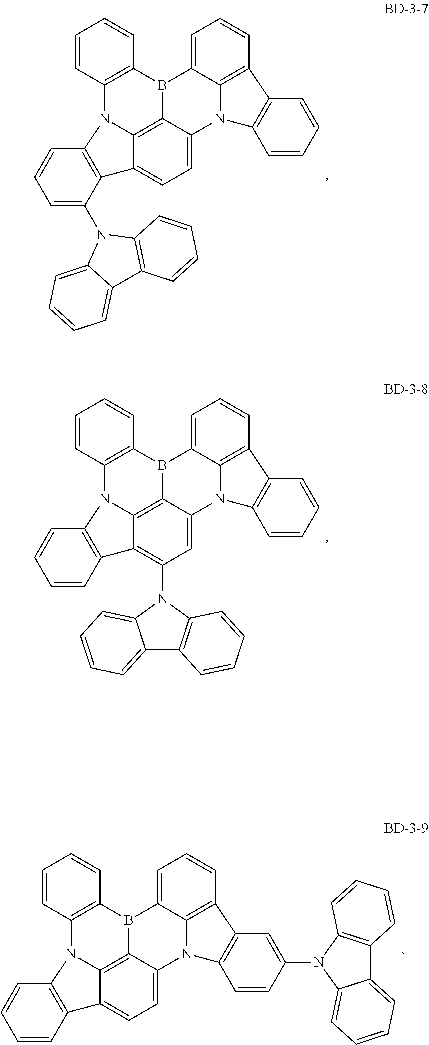 [SMILES: c1ccc2c(c1)B1c3cccc4c5ccccc5n(c34)-c3ccc4c5c(-n6c7ccccc7c7ccccc76)cccc5n-2c4c31 ; c1ccc2c(c1)B1c3cccc4c5ccccc5n(c34)-c3cc(-n4c5ccccc5c5ccccc54)c4c5ccccc5n-2c4c31 ; c1ccc2c(c1)B1c3cccc4c5cc(-n6c7ccccc7c7ccccc76)ccc5n(c34)-c3ccc4c5ccccc5n-2c4c31] 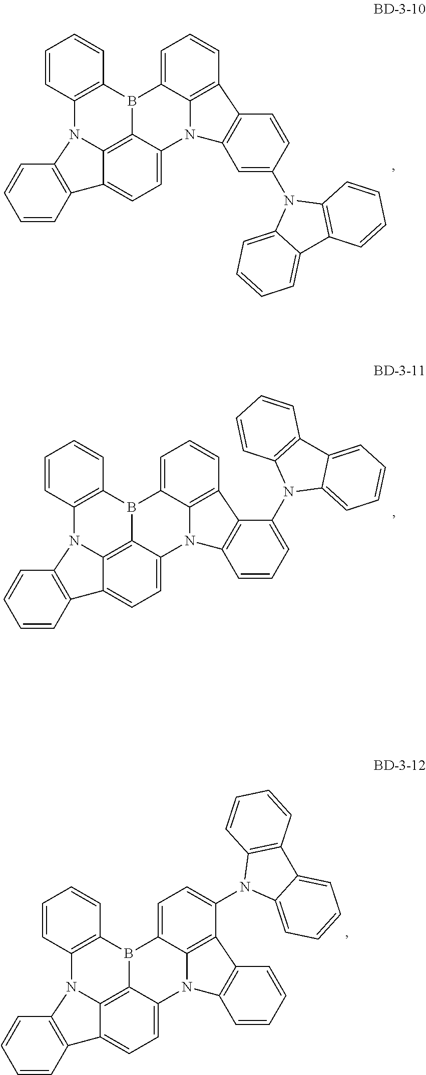 [SMILES: c1ccc2c(c1)B1c3cccc4c5ccc(-n6c7ccccc7c7ccccc76)cc5n(c34)-c3ccc4c5ccccc5n-2c4c31 ; c1ccc2c(c1)B1c3c(ccc4c5ccccc5n-2c34)-n2c3cccc(-n4c5ccccc5c5ccccc54)c3c3cccc1c32 ; c1ccc2c(c1)B1c3c(ccc4c5ccccc5n-2c34)-n2c3ccccc3c3c(-n4c5ccccc5c5ccccc54)ccc1c32] 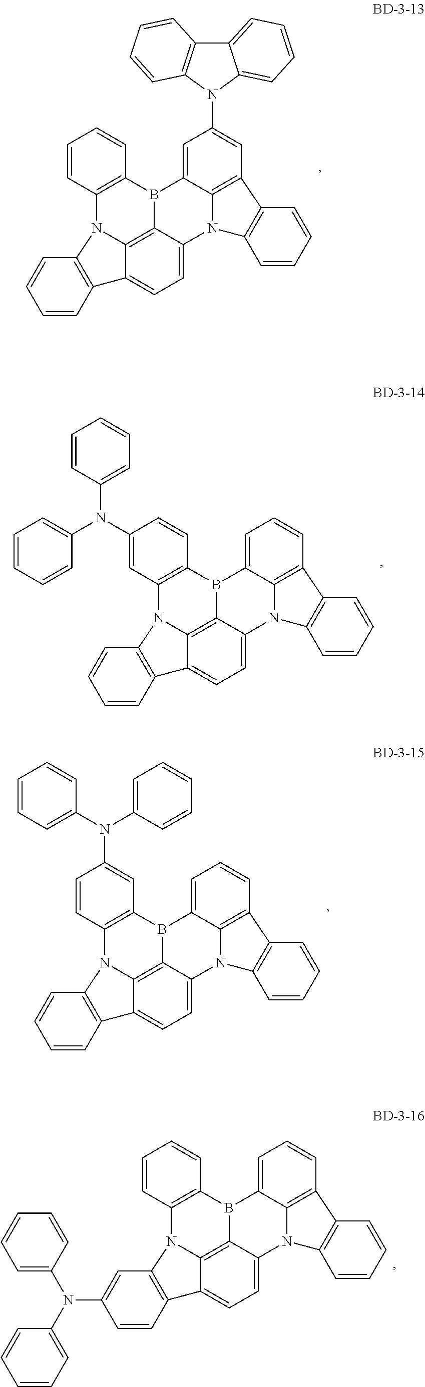 [SMILES: c1ccc2c(c1)B1c3cc(-n4c5ccccc5c5ccccc54)cc4c5ccccc5n(c34)-c3ccc4c5ccccc5n-2c4c31 ; c1ccc(N(c2ccccc2)c2ccc3c(c2)-n2c4ccccc4c4ccc5c(c42)B3c2cccc3c4ccccc4n-5c23)cc1 ; c1ccc(N(c2ccccc2)c2ccc3c(c2)B2c4cccc5c6ccccc6n(c45)-c4ccc5c6ccccc6n-3c5c42)cc1 ; c1ccc(N(c2ccccc2)c2ccc3c4ccc5c6c4n(c3c2)-c2ccccc2B6c2cccc3c4ccccc4n-5c23)cc1] 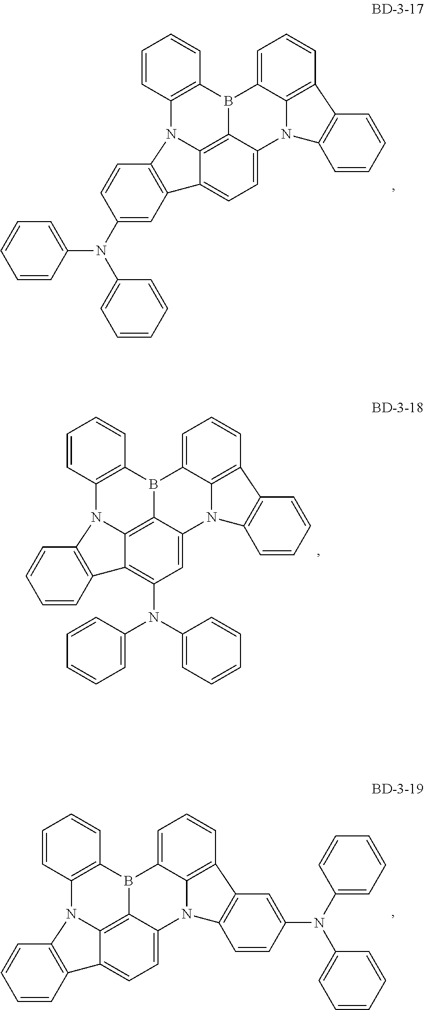 [SMILES: c1ccc(N(c2ccccc2)c2ccc3c(c2)c2ccc4c5c2n3-c2ccccc2B5c2cccc3c5ccccc5n-4c23)cc1 ; c1ccc(N(c2ccccc2)c2cc3c4c5c2c2ccccc2n5-c2ccccc2B4c2cccc4c5ccccc5n-3c24)cc1 ; c1ccc(N(c2ccccc2)c2ccc3c(c2)c2cccc4c2n3-c2ccc3c5ccccc5n5c3c2B4c2ccccc2-5)cc1] 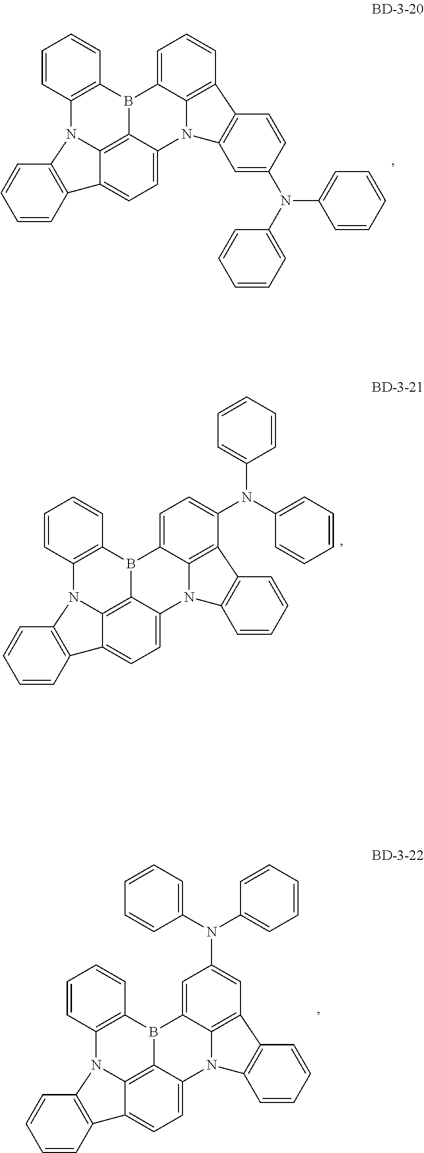 [SMILES: c1ccc(N(c2ccccc2)c2ccc3c4cccc5c4n(c3c2)-c2ccc3c4ccccc4n4c3c2B5c2ccccc2-4)cc1 ; c1ccc(N(c2ccccc2)c2ccc3c4c2c2ccccc2n4-c2ccc4c5ccccc5n5c4c2B3c2ccccc2-5)cc1 ; c1ccc(N(c2ccccc2)c2cc3c4c(c2)c2ccccc2n4-c2ccc4c5ccccc5n5c4c2B3c2ccccc2-5)cc1] 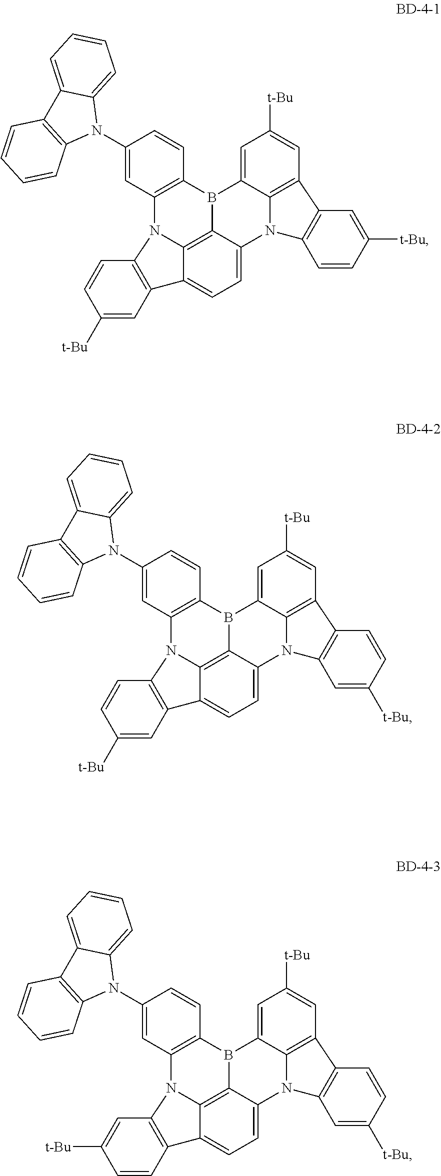 [SMILES: CC(C)(C)c1ccc2c(c1)c1cc(C(C)(C)C)cc3c1n2-c1ccc2c4cc(C(C)(C)C)ccc4n4c2c1B3c1ccc(-n2c3ccccc3c3ccccc32)cc1-4 ; CC(C)(C)c1ccc2c(c1)c1ccc3c4c1n2-c1cc(-n2c5ccccc5c5ccccc52)ccc1B4c1cc(C(C)(C)C)cc2c4ccc(C(C)(C)C)cc4n-3c12 ; CC(C)(C)c1cc2c3c(c1)c1ccc(C(C)(C)C)cc1n3-c1ccc3c4ccc(C(C)(C)C)cc4n4c3c1B2c1ccc(-n2c3ccccc3c3ccccc32)cc1-4] 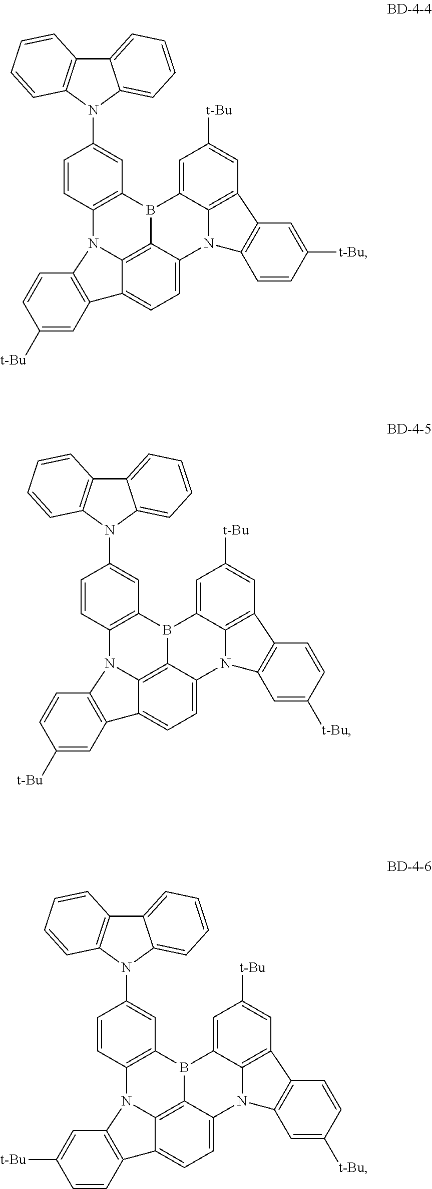 [SMILES: CC(C)(C)c1ccc2c(c1)c1cc(C(C)(C)C)cc3c1n2-c1ccc2c4cc(C(C)(C)C)ccc4n4c2c1B3c1cc(-n2c3ccccc3c3ccccc32)ccc1-4 ; CC(C)(C)c1ccc2c(c1)c1ccc3c4c1n2-c1ccc(-n2c5ccccc5c5ccccc52)cc1B4c1cc(C(C)(C)C)cc2c4ccc(C(C)(C)C)cc4n-3c12 ; CC(C)(C)c1cc2c3c(c1)c1ccc(C(C)(C)C)cc1n3-c1ccc3c4ccc(C(C)(C)C)cc4n4c3c1B2c1cc(-n2c3ccccc3c3ccccc32)ccc1-4] 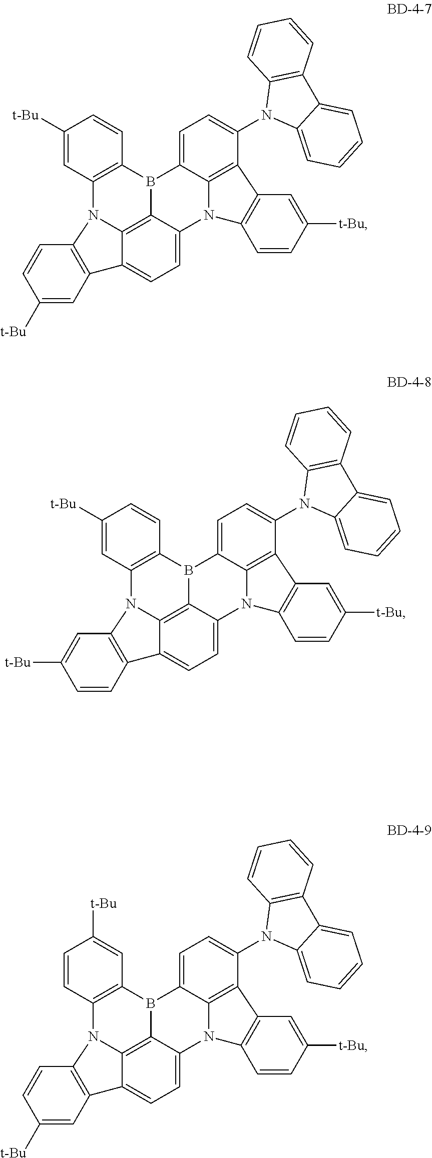 [SMILES: CC(C)(C)c1ccc2c(c1)-n1c3ccc(C(C)(C)C)cc3c3ccc4c(c31)B2c1ccc(-n2c3ccccc3c3ccccc32)c2c3cc(C(C)(C)C)ccc3n-4c12 ; CC(C)(C)c1ccc2c(c1)-n1c3cc(C(C)(C)C)ccc3c3ccc4c(c31)B2c1ccc(-n2c3ccccc3c3ccccc32)c2c3cc(C(C)(C)C)ccc3n-4c12 ; CC(C)(C)c1ccc2c(c1)B1c3c(ccc4c5cc(C(C)(C)C)ccc5n-2c34)-n2c3ccc(C(C)(C)C)cc3c3c(-n4c5ccccc5c5ccccc54)ccc1c32] 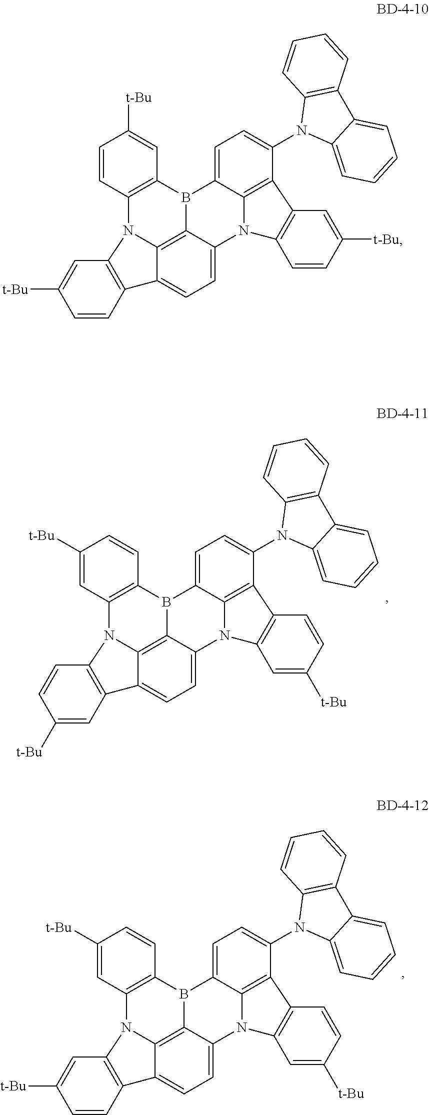 [SMILES: CC(C)(C)c1ccc2c(c1)B1c3c(ccc4c5ccc(C(C)(C)C)cc5n-2c34)-n2c3ccc(C(C)(C)C)cc3c3c(-n4c5ccccc5c5ccccc54)ccc1c32 ; CC(C)(C)c1ccc2c(c1)-n1c3ccc(C(C)(C)C)cc3c3ccc4c(c31)B2c1ccc(-n2c3ccccc3c3ccccc32)c2c3ccc(C(C)(C)C)cc3n-4c12 ; CC(C)(C)c1ccc2c(c1)-n1c3cc(C(C)(C)C)ccc3c3ccc4c(c31)B2c1ccc(-n2c3ccccc3c3ccccc32)c2c3ccc(C(C)(C)C)cc3n-4c12] 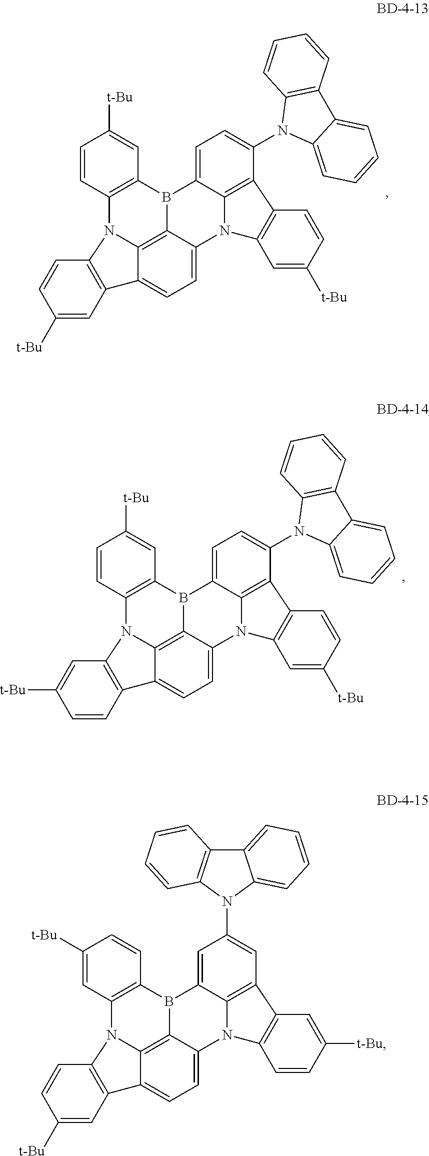 [SMILES: CC(C)(C)c1ccc2c(c1)B1c3c(ccc4c5cc(C(C)(C)C)ccc5n-2c34)-n2c3cc(C(C)(C)C)ccc3c3c(-n4c5ccccc5c5ccccc54)ccc1c32 ; CC(C)(C)c1ccc2c(c1)B1c3c(ccc4c5ccc(C(C)(C)C)cc5n-2c34)-n2c3cc(C(C)(C)C)ccc3c3c(-n4c5ccccc5c5ccccc54)ccc1c32 ; CC(C)(C)c1ccc2c(c1)-n1c3ccc(C(C)(C)C)cc3c3ccc4c(c31)B2c1cc(-n2c3ccccc3c3ccccc32)cc2c3cc(C(C)(C)C)ccc3n-4c12] 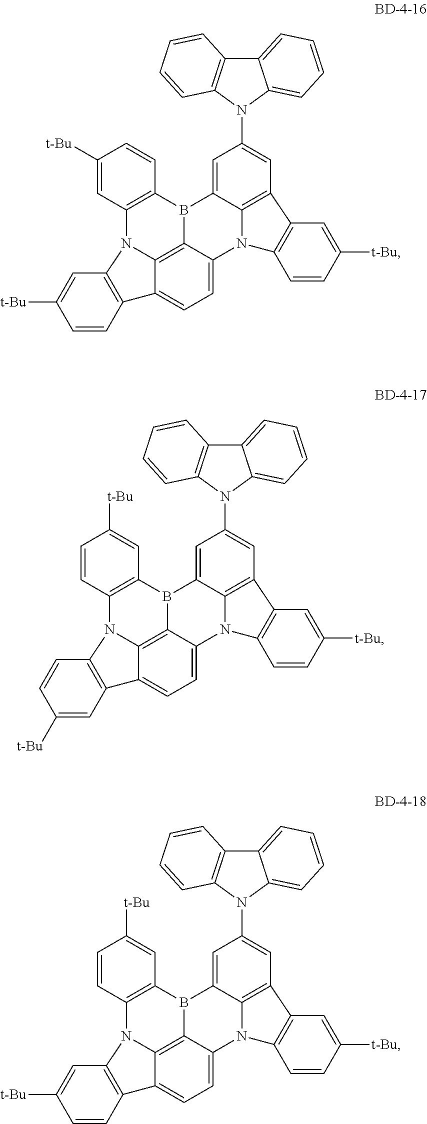 [SMILES: CC(C)(C)c1ccc2c(c1)-n1c3cc(C(C)(C)C)ccc3c3ccc4c(c31)B2c1cc(-n2c3ccccc3c3ccccc32)cc2c3cc(C(C)(C)C)ccc3n-4c12 ; CC(C)(C)c1ccc2c(c1)B1c3cc(-n4c5ccccc5c5ccccc54)cc4c5cc(C(C)(C)C)ccc5n(c34)-c3ccc4c5cc(C(C)(C)C)ccc5n-2c4c31 ; CC(C)(C)c1ccc2c(c1)B1c3cc(-n4c5ccccc5c5ccccc54)cc4c5cc(C(C)(C)C)ccc5n(c34)-c3ccc4c5ccc(C(C)(C)C)cc5n-2c4c31] 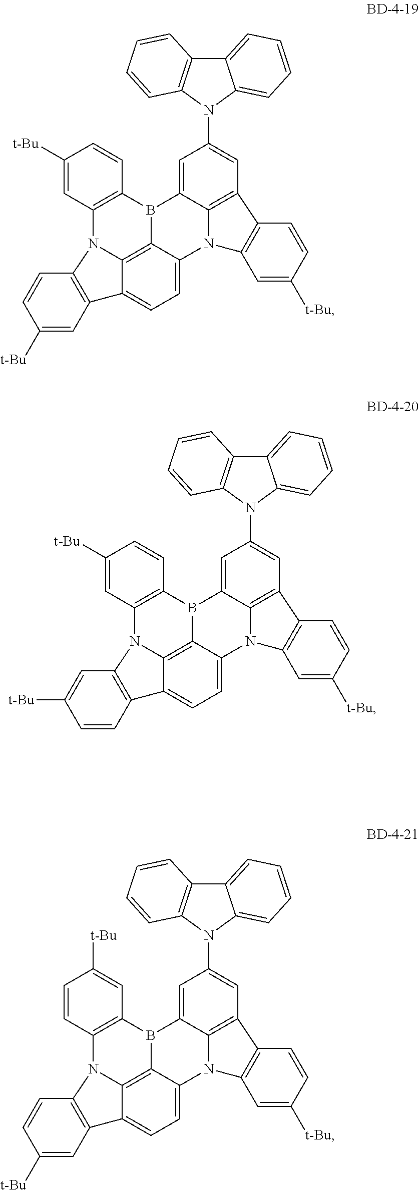 [SMILES: CC(C)(C)c1ccc2c(c1)-n1c3ccc(C(C)(C)C)cc3c3ccc4c(c31)B2c1cc(-n2c3ccccc3c3ccccc32)cc2c3ccc(C(C)(C)C)cc3n-4c12 ; CC(C)(C)c1ccc2c(c1)-n1c3cc(C(C)(C)C)ccc3c3ccc4c(c31)B2c1cc(-n2c3ccccc3c3ccccc32)cc2c3ccc(C(C)(C)C)cc3n-4c12 ; CC(C)(C)c1ccc2c(c1)B1c3cc(-n4c5ccccc5c5ccccc54)cc4c5ccc(C(C)(C)C)cc5n(c34)-c3ccc4c5cc(C(C)(C)C)ccc5n-2c4c31] 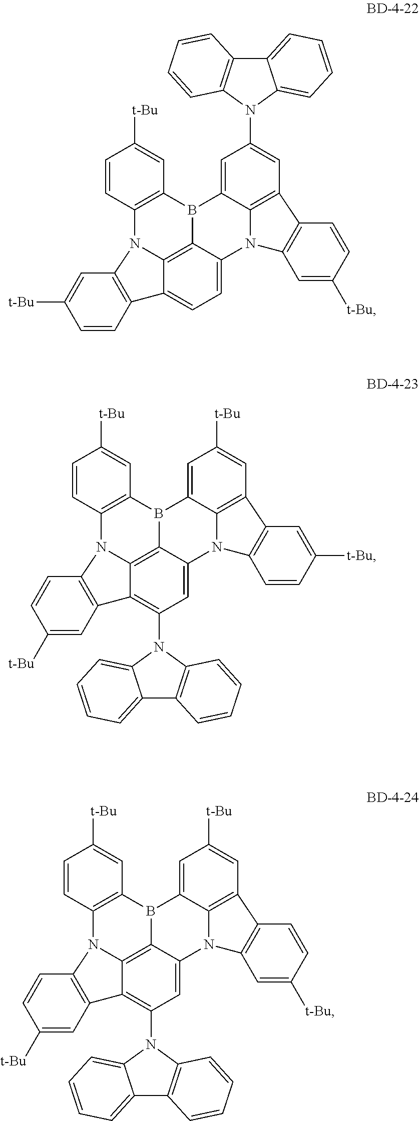 [SMILES: CC(C)(C)c1ccc2c(c1)B1c3cc(-n4c5ccccc5c5ccccc54)cc4c5ccc(C(C)(C)C)cc5n(c34)-c3ccc4c5ccc(C(C)(C)C)cc5n-2c4c31 ; CC(C)(C)c1ccc2c(c1)B1c3cc(C(C)(C)C)cc4c5cc(C(C)(C)C)ccc5n(c34)-c3cc(-n4c5ccccc5c5ccccc54)c4c5cc(C(C)(C)C)ccc5n-2c4c31 ; CC(C)(C)c1ccc2c(c1)B1c3cc(C(C)(C)C)cc4c5ccc(C(C)(C)C)cc5n(c34)-c3cc(-n4c5ccccc5c5ccccc54)c4c5cc(C(C)(C)C)ccc5n-2c4c31] 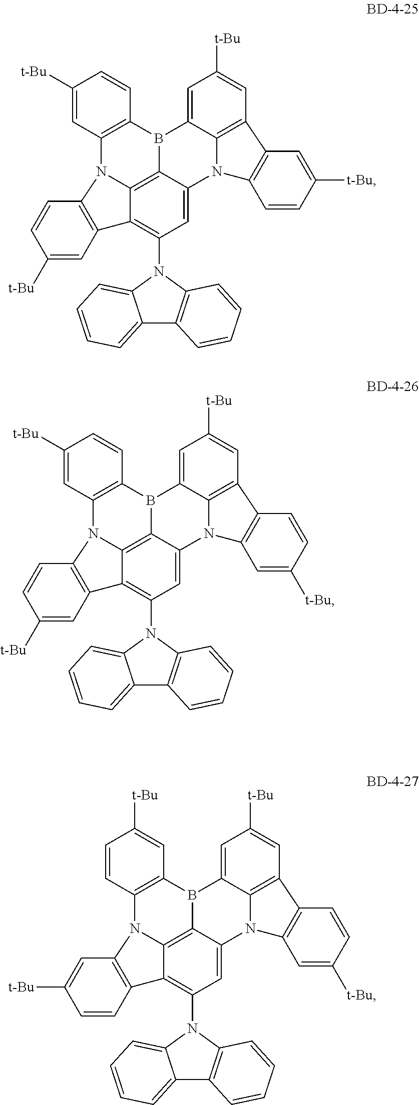 [SMILES: CC(C)(C)c1ccc2c(c1)-n1c3ccc(C(C)(C)C)cc3c3c(-n4c5ccccc5c5ccccc54)cc4c(c31)B2c1cc(C(C)(C)C)cc2c3cc(C(C)(C)C)ccc3n-4c12 ; CC(C)(C)c1ccc2c(c1)-n1c3ccc(C(C)(C)C)cc3c3c(-n4c5ccccc5c5ccccc54)cc4c(c31)B2c1cc(C(C)(C)C)cc2c3ccc(C(C)(C)C)cc3n-4c12 ; CC(C)(C)c1ccc2c(c1)B1c3cc(C(C)(C)C)cc4c5ccc(C(C)(C)C)cc5n(c34)-c3cc(-n4c5ccccc5c5ccccc54)c4c5ccc(C(C)(C)C)cc5n-2c4c31] 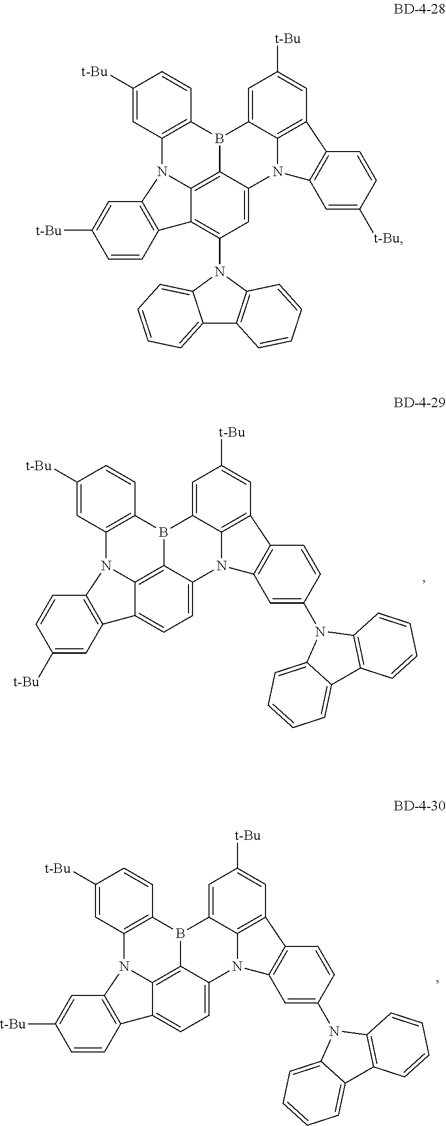 [SMILES: CC(C)(C)c1ccc2c(c1)-n1c3cc(C(C)(C)C)ccc3c3c(-n4c5ccccc5c5ccccc54)cc4c(c31)B2c1cc(C(C)(C)C)cc2c3ccc(C(C)(C)C)cc3n-4c12 ; CC(C)(C)c1ccc2c(c1)-n1c3ccc(C(C)(C)C)cc3c3ccc4c(c31)B2c1cc(C(C)(C)C)cc2c3ccc(-n5c6ccccc6c6ccccc65)cc3n-4c12 ; CC(C)(C)c1ccc2c(c1)-n1c3cc(C(C)(C)C)ccc3c3ccc4c(c31)B2c1cc(C(C)(C)C)cc2c3ccc(-n5c6ccccc6c6ccccc65)cc3n-4c12] 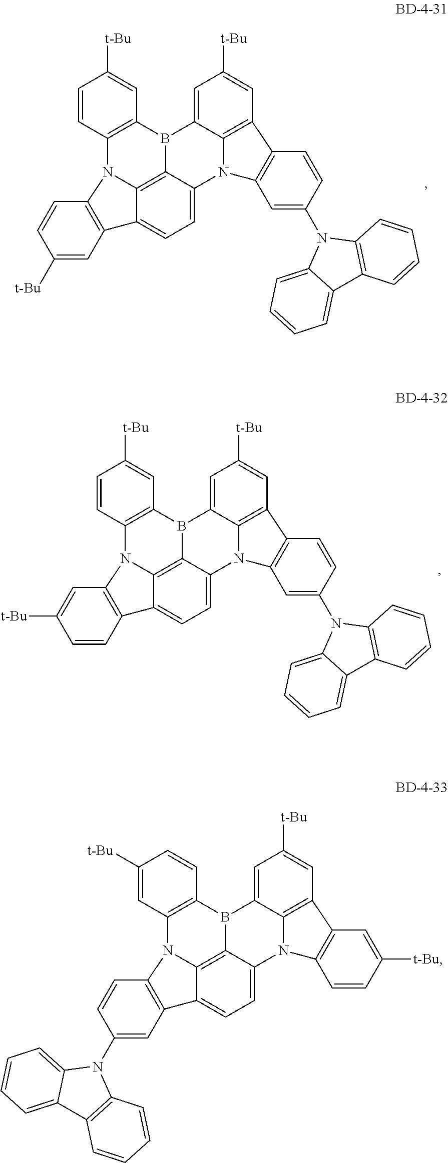 [SMILES: CC(C)(C)c1ccc2c(c1)B1c3cc(C(C)(C)C)cc4c5ccc(-n6c7ccccc7c7ccccc76)cc5n(c34)-c3ccc4c5cc(C(C)(C)C)ccc5n-2c4c31 ; CC(C)(C)c1ccc2c(c1)B1c3cc(C(C)(C)C)cc4c5ccc(-n6c7ccccc7c7ccccc76)cc5n(c34)-c3ccc4c5ccc(C(C)(C)C)cc5n-2c4c31 ; CC(C)(C)c1ccc2c(c1)-n1c3ccc(-n4c5ccccc5c5ccccc54)cc3c3ccc4c(c31)B2c1cc(C(C)(C)C)cc2c3cc(C(C)(C)C)ccc3n-4c12] 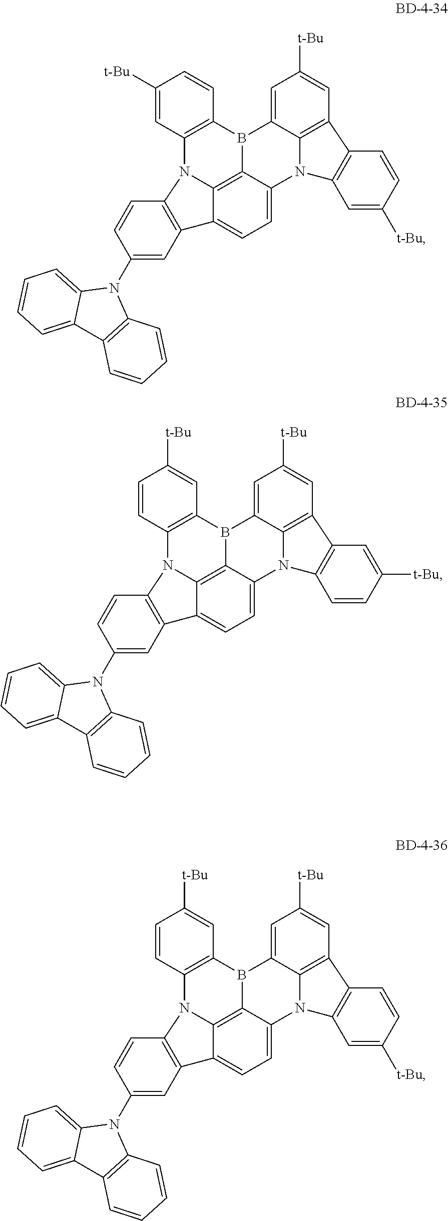 [SMILES: CC(C)(C)c1ccc2c(c1)-n1c3ccc(-n4c5ccccc5c5ccccc54)cc3c3ccc4c(c31)B2c1cc(C(C)(C)C)cc2c3ccc(C(C)(C)C)cc3n-4c12 ; CC(C)(C)c1ccc2c(c1)B1c3cc(C(C)(C)C)cc4c5cc(C(C)(C)C)ccc5n(c34)-c3ccc4c5cc(-n6c7ccccc7c7ccccc76)ccc5n-2c4c31 ; CC(C)(C)c1ccc2c(c1)B1c3cc(C(C)(C)C)cc4c5ccc(C(C)(C)C)cc5n(c34)-c3ccc4c5cc(-n6c7ccccc7c7ccccc76)ccc5n-2c4c31] 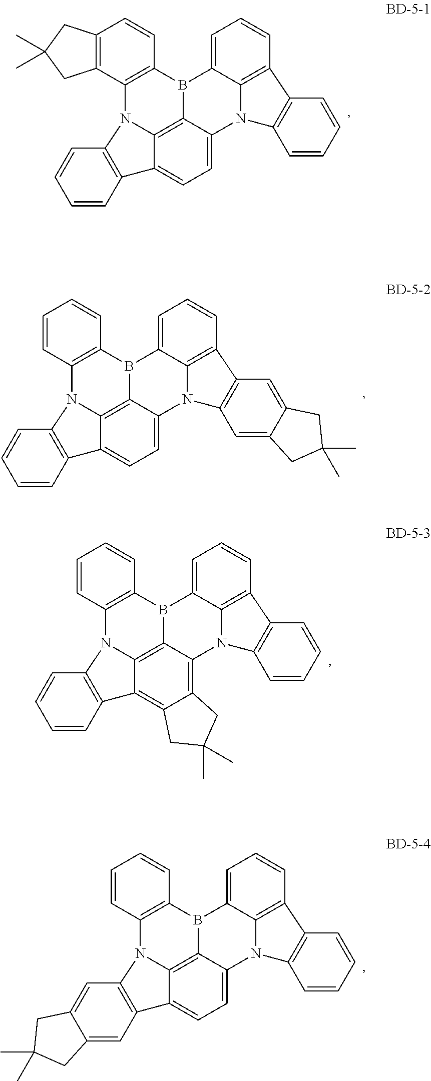 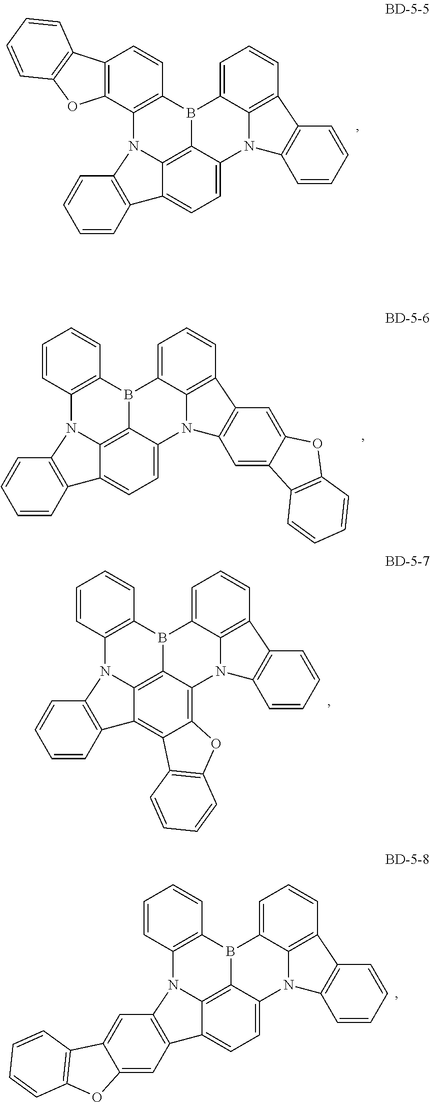 [SMILES: c1ccc2c(c1)oc1c3c(ccc12)B1c2cccc4c5ccccc5n(c24)-c2ccc4c5ccccc5n-3c4c21 ; c1ccc2c(c1)B1c3cccc4c5cc6oc7ccccc7c6cc5n(c34)-c3ccc4c5ccccc5n-2c4c31 ; c1ccc2c(c1)B1c3cccc4c5ccccc5n(c34)-c3c1c1c(c4ccccc4n1-2)c1c3oc2ccccc21 ; c1ccc2c(c1)B1c3cccc4c5ccccc5n(c34)-c3ccc4c5cc6oc7ccccc7c6cc5n-2c4c31] 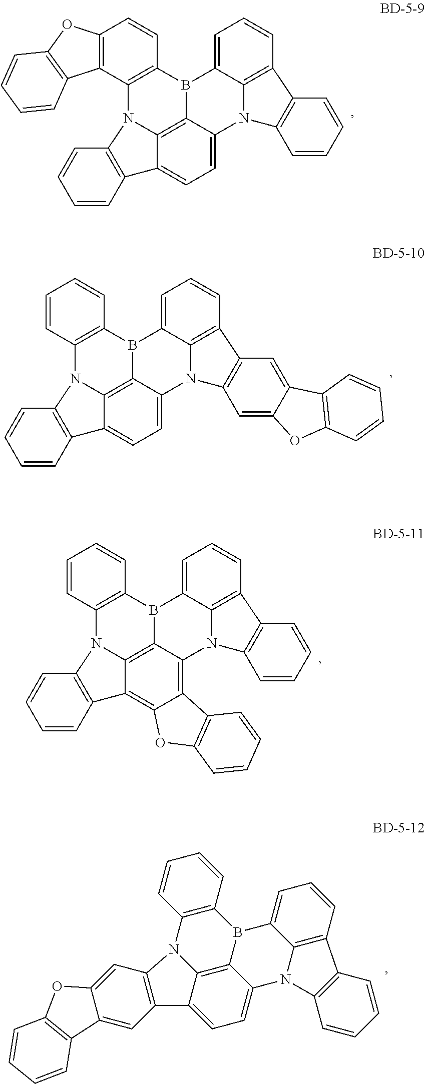 [SMILES: c1ccc2c(c1)oc1ccc3c(c12)-n1c2ccccc2c2ccc4c(c21)B3c1cccc2c3ccccc3n-4c12 ; c1ccc2c(c1)B1c3cccc4c5cc6c(cc5n(c34)-c3ccc4c5ccccc5n-2c4c31)oc1ccccc16 ; c1ccc2c(c1)B1c3cccc4c5ccccc5n(c34)-c3c1c1c(c4ccccc4n1-2)c1oc2ccccc2c31 ; c1ccc2c(c1)B1c3cccc4c5ccccc5n(c34)-c3ccc4c5cc6c(cc5n-2c4c31)oc1ccccc16] 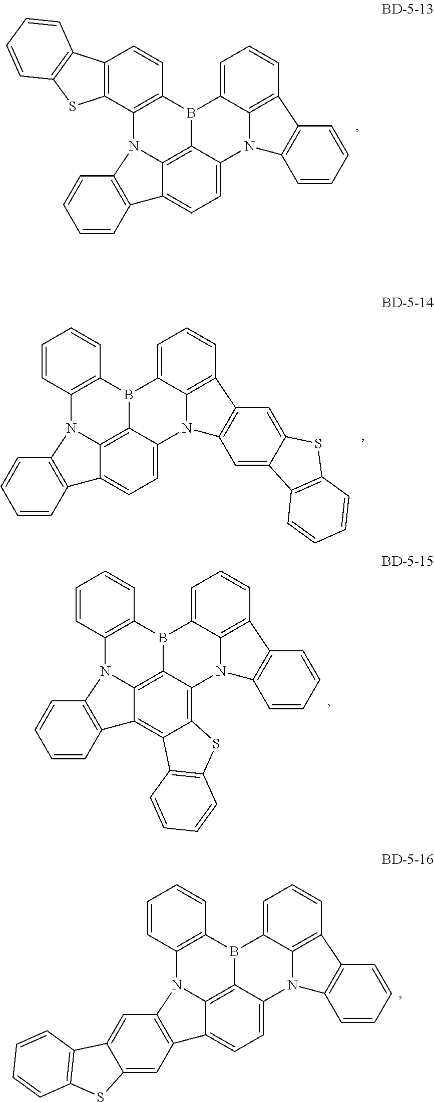 [SMILES: c1ccc2c(c1)sc1c3c(ccc12)B1c2cccc4c5ccccc5n(c24)-c2ccc4c5ccccc5n-3c4c21 ; c1ccc2c(c1)B1c3cccc4c5cc6sc7ccccc7c6cc5n(c34)-c3ccc4c5ccccc5n-2c4c31 ; c1ccc2c(c1)B1c3cccc4c5ccccc5n(c34)-c3c1c1c(c4ccccc4n1-2)c1c3sc2ccccc21 ; c1ccc2c(c1)B1c3cccc4c5ccccc5n(c34)-c3ccc4c5cc6sc7ccccc7c6cc5n-2c4c31] 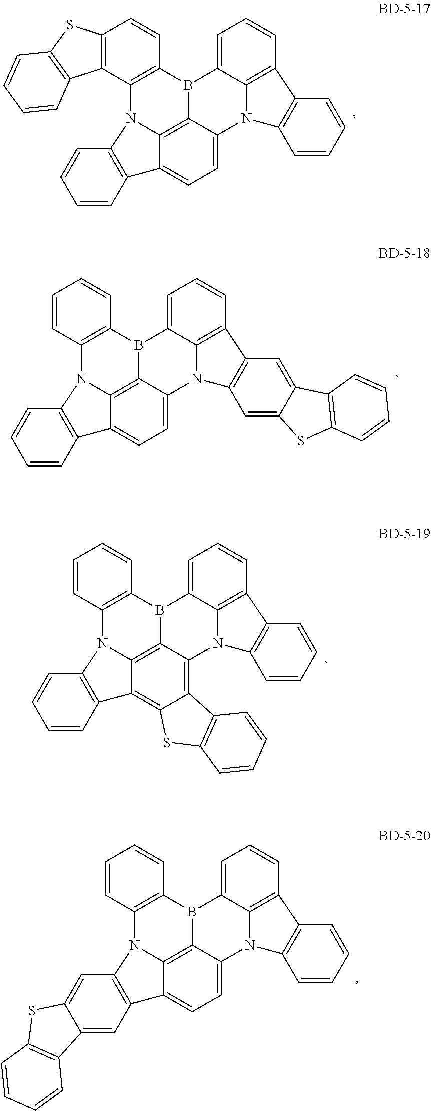 [SMILES: c1ccc2c(c1)sc1ccc3c(c12)-n1c2ccccc2c2ccc4c(c21)B3c1cccc2c3ccccc3n-4c12 ; c1ccc2c(c1)B1c3cccc4c5cc6c(cc5n(c34)-c3ccc4c5ccccc5n-2c4c31)sc1ccccc16 ; c1ccc2c(c1)B1c3cccc4c5ccccc5n(c34)-c3c1c1c(c4ccccc4n1-2)c1sc2ccccc2c31 ; c1ccc2c(c1)B1c3cccc4c5ccccc5n(c34)-c3ccc4c5cc6c(cc5n-2c4c31)sc1ccccc16] 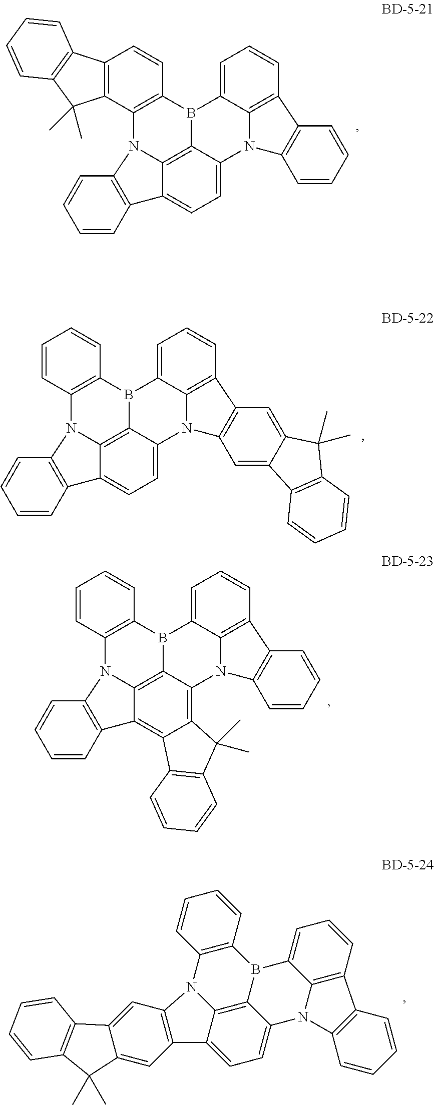 [SMILES: CC1(C)c2ccccc2-c2ccc3c(c21)-n1c2ccccc2c2ccc4c(c21)B3c1cccc2c3ccccc3n-4c12 ; CC1(C)c2ccccc2-c2cc3c(cc21)c1cccc2c1n3-c1ccc3c4ccccc4n4c3c1B2c1ccccc1-4 ; CC1(C)c2ccccc2-c2c1c1c3c4c2c2ccccc2n4-c2ccccc2B3c2cccc3c4ccccc4n-1c23 ; CC1(C)c2ccccc2-c2cc3c(cc21)c1ccc2c4c1n3-c1ccccc1B4c1cccc3c4ccccc4n-2c13] 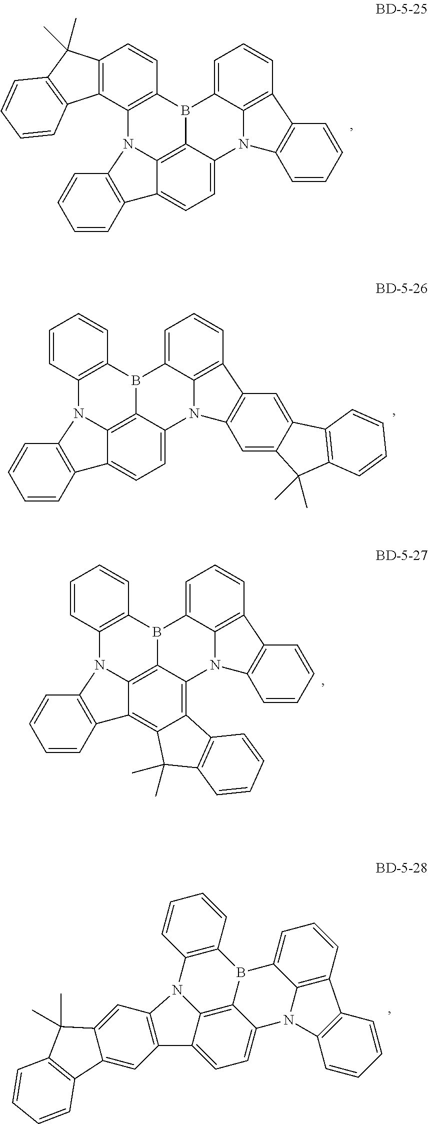 [SMILES: CC1(C)c2ccccc2-c2c1ccc1c2-n2c3ccccc3c3ccc4c(c32)B1c1cccc2c3ccccc3n-4c12 ; CC1(C)c2ccccc2-c2cc3c4cccc5c4n(c3cc21)-c1ccc2c3ccccc3n3c2c1B5c1ccccc1-3 ; CC1(C)c2ccccc2-c2c3c4c5c(c21)c1ccccc1n5-c1ccccc1B4c1cccc2c4ccccc4n-3c12 ; CC1(C)c2ccccc2-c2cc3c4ccc5c6c4n(c3cc21)-c1ccccc1B6c1cccc2c3ccccc3n-5c12] 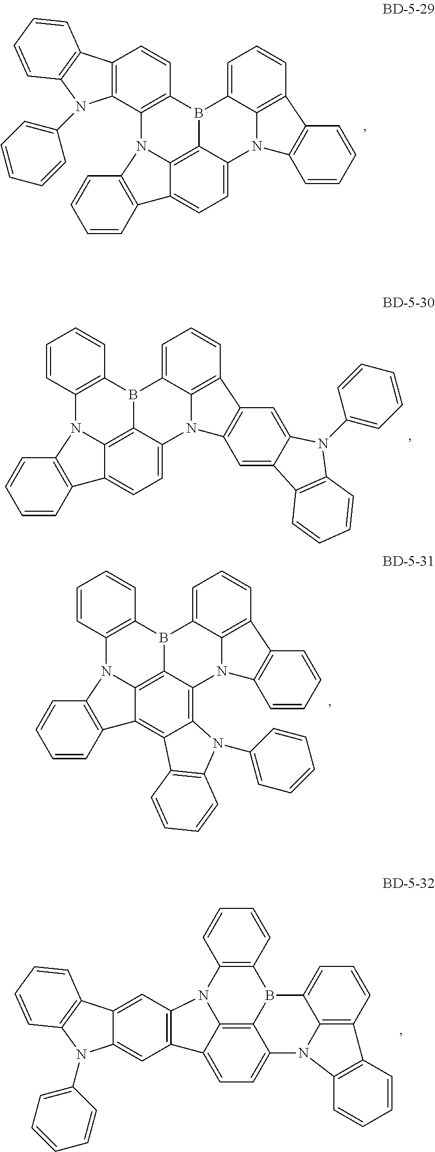 [SMILES: c1ccc(-n2c3ccccc3c3ccc4c(c32)-n2c3ccccc3c3ccc5c(c32)B4c2cccc3c4ccccc4n-5c23)cc1 ; c1ccc(-n2c3ccccc3c3cc4c(cc32)c2cccc3c2n4-c2ccc4c5ccccc5n5c4c2B3c2ccccc2-5)cc1 ; c1ccc(-n2c3ccccc3c3c4c5ccccc5n5c4c4c(c32)-n2c3ccccc3c3cccc(c32)B4c2ccccc2-5)cc1 ; c1ccc(-n2c3ccccc3c3cc4c(cc32)c2ccc3c5c2n4-c2ccccc2B5c2cccc4c5ccccc5n-3c24)cc1] 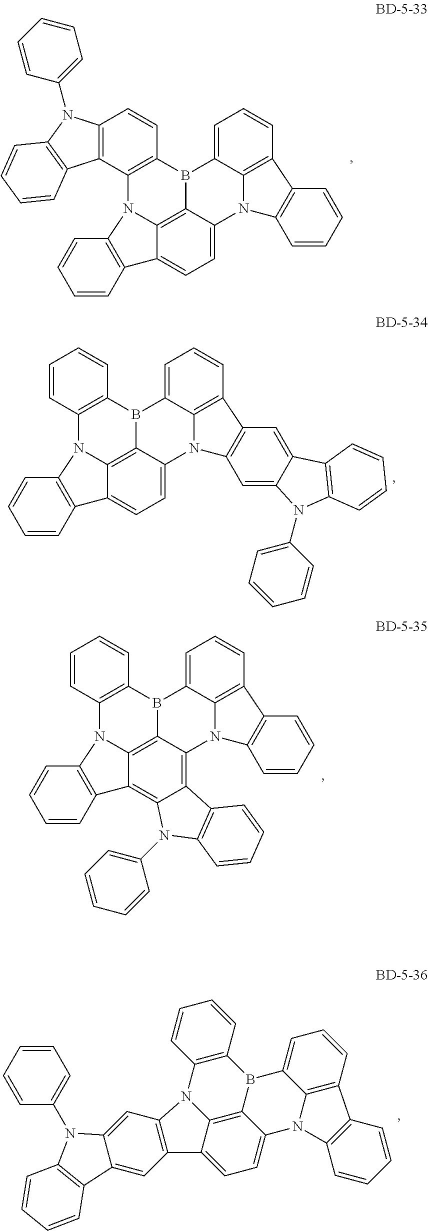 [SMILES: c1ccc(-n2c3ccccc3c3c4c(ccc32)B2c3cccc5c6ccccc6n(c35)-c3ccc5c6ccccc6n-4c5c32)cc1 ; c1ccc(-n2c3ccccc3c3cc4c5cccc6c5n(c4cc32)-c2ccc3c4ccccc4n4c3c2B6c2ccccc2-4)cc1 ; c1ccc(-n2c3ccccc3c3c4c5c6c(c7ccccc7n6-c6ccccc6B5c5cccc6c7ccccc7n-4c56)c32)cc1 ; c1ccc(-n2c3ccccc3c3cc4c5ccc6c7c5n(c4cc32)-c2ccccc2B7c2cccc3c4ccccc4n-6c23)cc1] 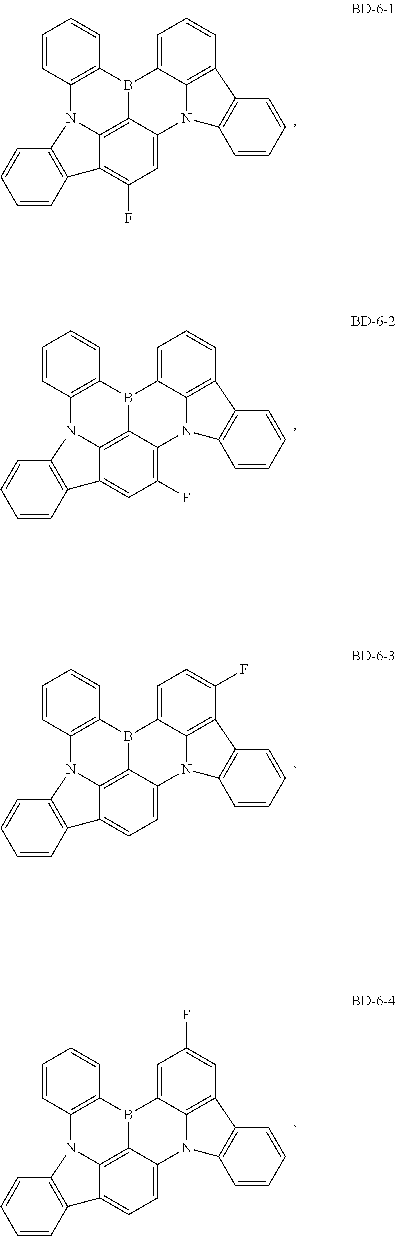 [SMILES: Fc1cc2c3c4c1c1ccccc1n4-c1ccccc1B3c1cccc3c4ccccc4n-2c13 ; Fc1cc2c3ccccc3n3c2c2c1-n1c4ccccc4c4cccc(c41)B2c1ccccc1-3 ; Fc1ccc2c3c1c1ccccc1n3-c1ccc3c4ccccc4n4c3c1B2c1ccccc1-4 ; Fc1cc2c3c(c1)c1ccccc1n3-c1ccc3c4ccccc4n4c3c1B2c1ccccc1-4] 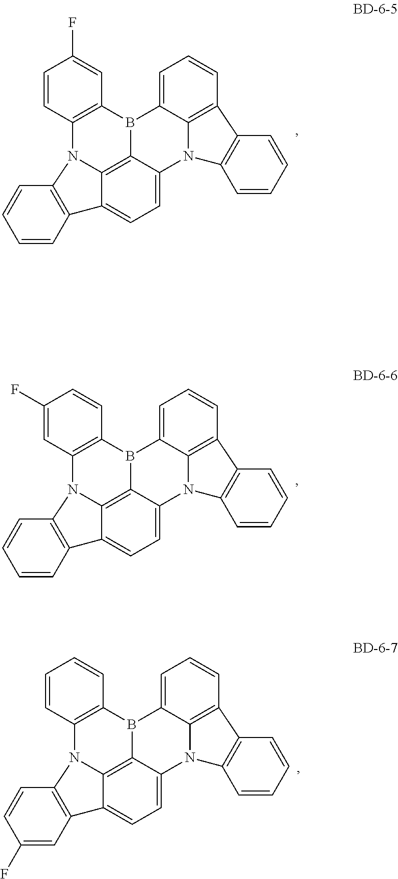 [SMILES: Fc1ccc2c(c1)B1c3cccc4c5ccccc5n(c34)-c3ccc4c5ccccc5n-2c4c31 ; Fc1ccc2c(c1)-n1c3ccccc3c3ccc4c(c31)B2c1cccc2c3ccccc3n-4c12 ; Fc1ccc2c(c1)c1ccc3c4c1n2-c1ccccc1B4c1cccc2c4ccccc4n-3c12] 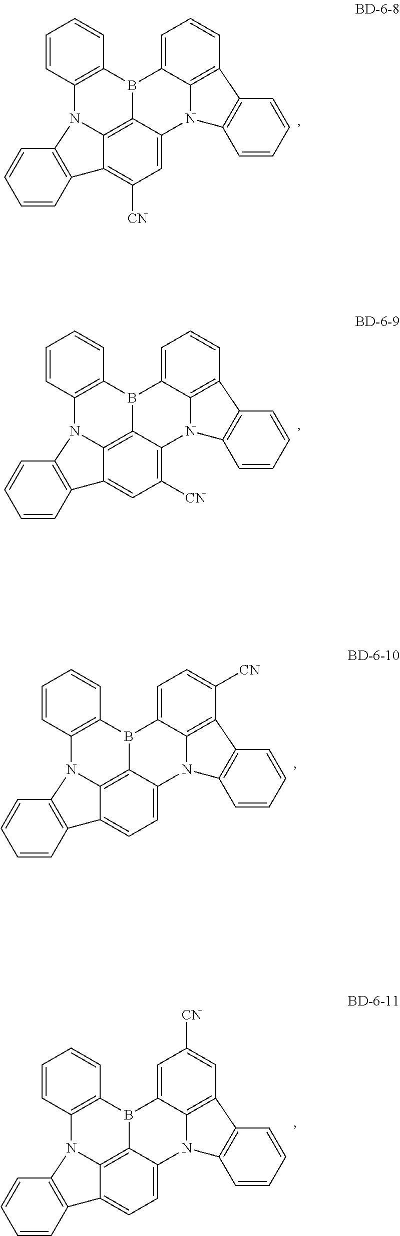 [SMILES: N#Cc1cc2c3c4c1c1ccccc1n4-c1ccccc1B3c1cccc3c4ccccc4n-2c13 ; N#Cc1cc2c3ccccc3n3c2c2c1-n1c4ccccc4c4cccc(c41)B2c1ccccc1-3 ; N#Cc1ccc2c3c1c1ccccc1n3-c1ccc3c4ccccc4n4c3c1B2c1ccccc1-4 ; N#Cc1cc2c3c(c1)c1ccccc1n3-c1ccc3c4ccccc4n4c3c1B2c1ccccc1-4] 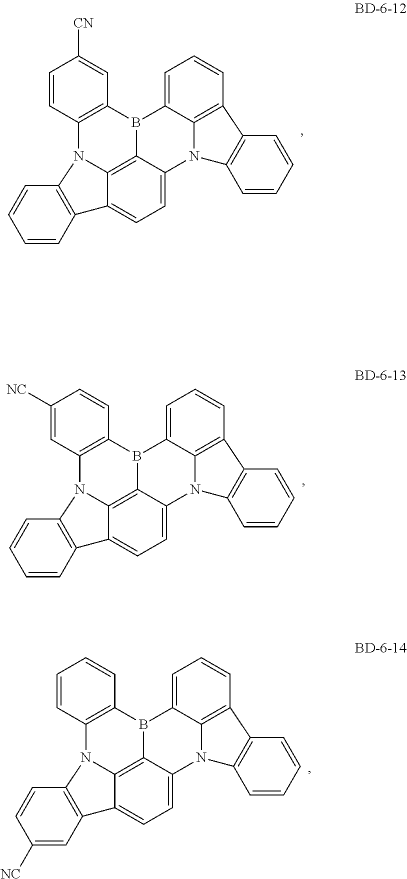 [SMILES: N#Cc1ccc2c(c1)B1c3cccc4c5ccccc5n(c34)-c3ccc4c5ccccc5n-2c4c31 ; N#Cc1ccc2c(c1)-n1c3ccccc3c3ccc4c(c31)B2c1cccc2c3ccccc3n-4c12 ; N#Cc1ccc2c(c1)c1ccc3c4c1n2-c1ccccc1B4c1cccc2c4ccccc4n-3c12] 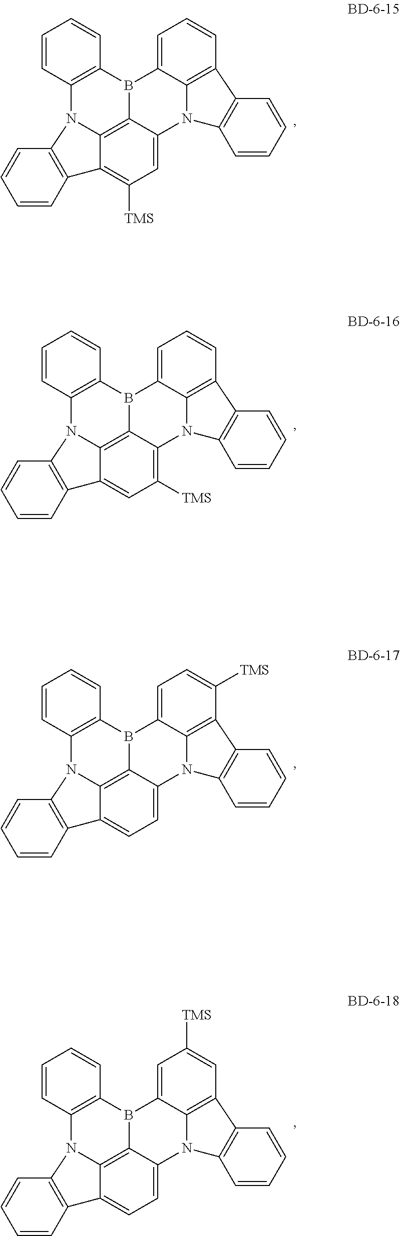 [SMILES: C[Si](C)(C)c1cc2c3c4c1c1ccccc1n4-c1ccccc1B3c1cccc3c4ccccc4n-2c13 ; C[Si](C)(C)c1cc2c3ccccc3n3c2c2c1-n1c4ccccc4c4cccc(c41)B2c1ccccc1-3 ; C[Si](C)(C)c1ccc2c3c1c1ccccc1n3-c1ccc3c4ccccc4n4c3c1B2c1ccccc1-4 ; C[Si](C)(C)c1cc2c3c(c1)c1ccccc1n3-c1ccc3c4ccccc4n4c3c1B2c1ccccc1-4] 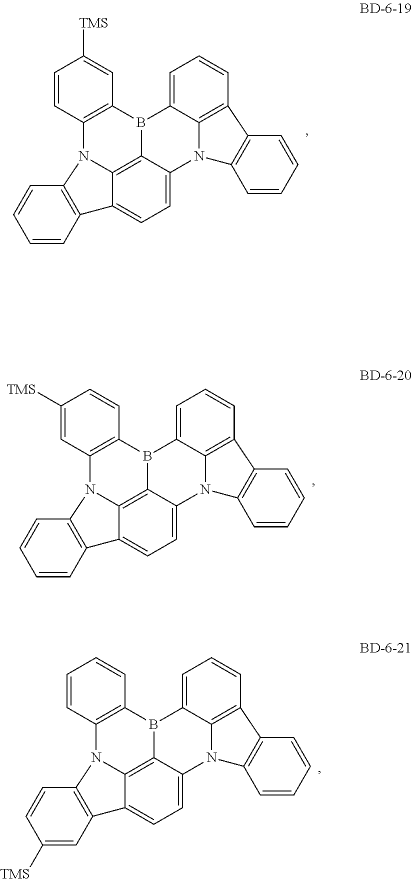 [SMILES: C[Si](C)(C)c1ccc2c(c1)B1c3cccc4c5ccccc5n(c34)-c3ccc4c5ccccc5n-2c4c31 ; C[Si](C)(C)c1ccc2c(c1)-n1c3ccccc3c3ccc4c(c31)B2c1cccc2c3ccccc3n-4c12 ; C[Si](C)(C)c1ccc2c(c1)c1ccc3c4c1n2-c1ccccc1B4c1cccc2c4ccccc4n-3c12] 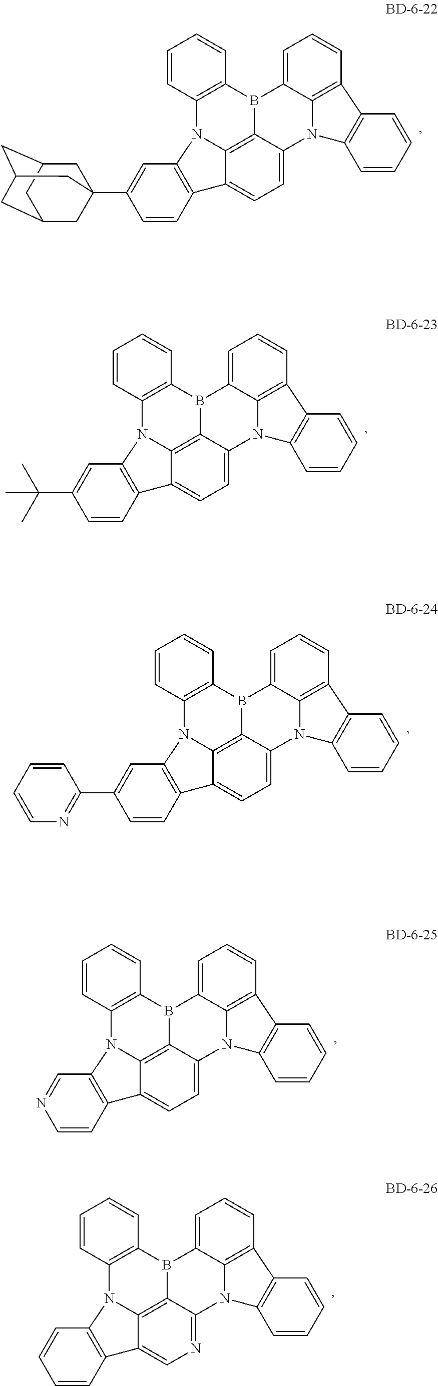 [SMILES: c1ccc2c(c1)B1c3cccc4c5ccccc5n(c34)-c3ccc4c5ccc(C67CC8CC(CC(C8)C6)C7)cc5n-2c4c31 ; CC(C)(C)c1ccc2c3ccc4c5c3n(c2c1)-c1ccccc1B5c1cccc2c3ccccc3n-4c12 ; c1ccc(-c2ccc3c4ccc5c6c4n(c3c2)-c2ccccc2B6c2cccc3c4ccccc4n-5c23)nc1 ; c1ccc2c(c1)B1c3cccc4c5ccccc5n(c34)-c3ccc4c5ccncc5n-2c4c31 ; c1ccc2c(c1)B1c3cccc4c5ccccc5n(c34)-c3ncc4c5ccccc5n-2c4c31] 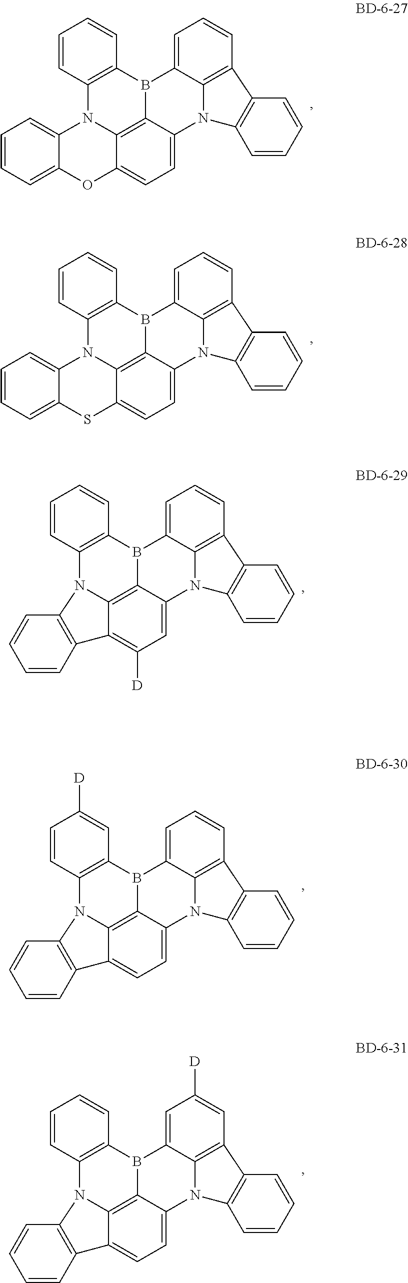 [SMILES: c1ccc2c(c1)Oc1ccc3c4c1N2c1ccccc1B4c1cccc2c4ccccc4n-3c12 ; c1ccc2c(c1)Sc1ccc3c4c1N2c1ccccc1B4c1cccc2c4ccccc4n-3c12 ; [2H]c1cc2c3c4c1c1ccccc1n4-c1ccccc1B3c1cccc3c4ccccc4n-2c13 ; [2H]c1ccc2c(c1)B1c3cccc4c5ccccc5n(c34)-c3ccc4c5ccccc5n-2c4c31 ; [2H]c1cc2c3c(c1)c1ccccc1n3-c1ccc3c4ccccc4n4c3c1B2c1ccccc1-4] 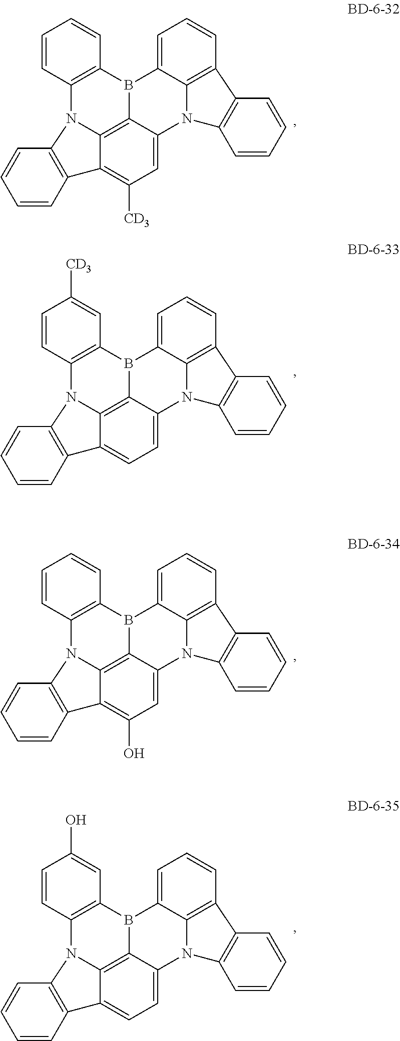 [SMILES: [2H]C([2H])([2H])c1cc2c3c4c1c1ccccc1n4-c1ccccc1B3c1cccc3c4ccccc4n-2c13 ; [2H]C([2H])([2H])c1ccc2c(c1)B1c3cccc4c5ccccc5n(c34)-c3ccc4c5ccccc5n-2c4c31 ; Oc1cc2c3c4c1c1ccccc1n4-c1ccccc1B3c1cccc3c4ccccc4n-2c13 ; Oc1ccc2c(c1)B1c3cccc4c5ccccc5n(c34)-c3ccc4c5ccccc5n-2c4c31] 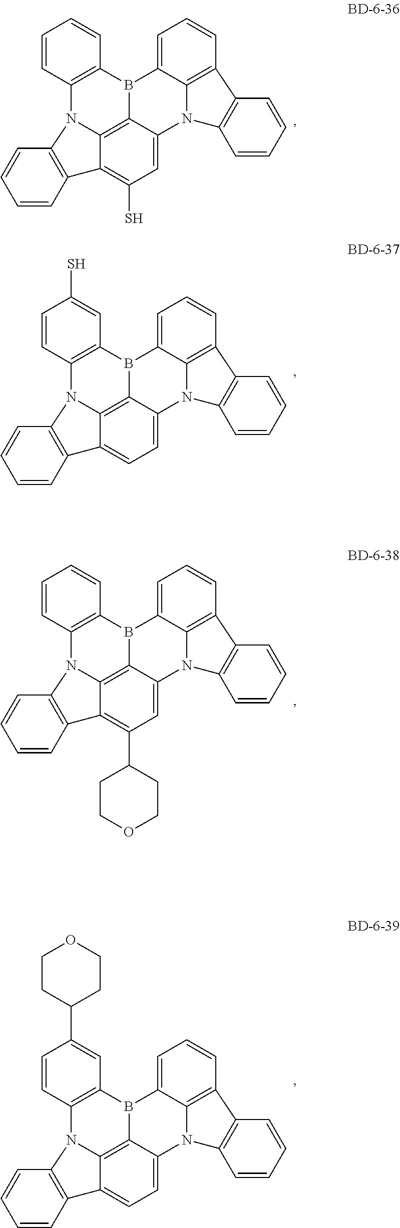 [SMILES: Sc1cc2c3c4c1c1ccccc1n4-c1ccccc1B3c1cccc3c4ccccc4n-2c13 ; Sc1ccc2c(c1)B1c3cccc4c5ccccc5n(c34)-c3ccc4c5ccccc5n-2c4c31 ; c1ccc2c(c1)B1c3cccc4c5ccccc5n(c34)-c3cc(C4CCOCC4)c4c5ccccc5n-2c4c31 ; c1ccc2c(c1)c1cccc3c1n2-c1ccc2c4ccccc4n4c2c1B3c1cc(C2CCOCC2)ccc1-4] 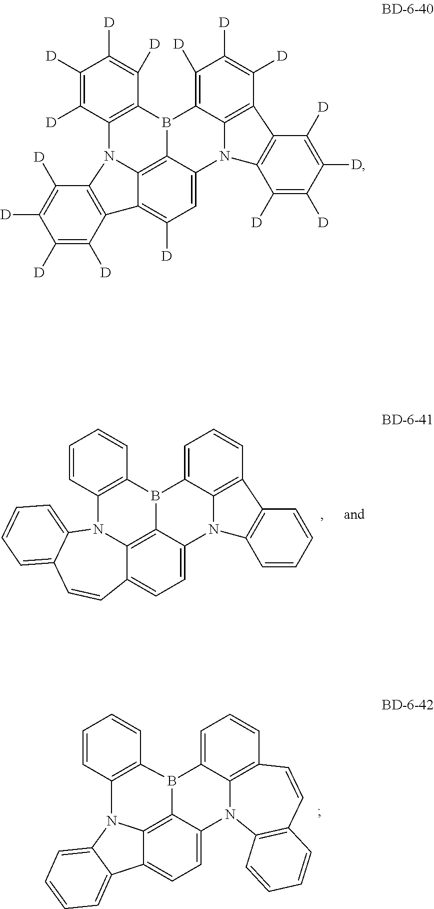
wherein optionally, hydrogens in Compound BD-1-1 to Compound BD-1-31, Compound BD-2-1 to Compound BD-2-28, Compound BD-3-1 to Compound BD-3-22, Compound BD-4-1 to Compound BD-4-36, Compound BD-5-1 to Compound BD-5-36, and Compound BD-6-1 to Compound BD-6-42 can be partially or fully substituted with deuterium.

9. The organic electroluminescent device according to claim 1, wherein the maximum emission wavelength λ_{max-PL} in the photoluminescence spectrum of the fluorescent emissive material is 450 nm to 500 nm; preferably, the maximum emission wavelength λ_{max-PL} in the photoluminescence spectrum of the fluorescent emissive material is 450 nm to 470 nm; more preferably, the maximum emission wavelength λ_{max-PL} in the photoluminescence spectrum of the fluorescent emissive material is 455 nm to 465 nm.

10. The organic electroluminescent device according to claim 1, wherein the full width at half maximum FWHM-_{PL} in the photoluminescence spectrum of the fluorescent emissive material is less than or equal to 45 nm; preferably, the full width at half maximum FWHM-_{PL} in the photoluminescence spectrum of the fluorescent emissive material is less than or equal to 35 nm; more preferably, the full width at half maximum FWHM-_{PL} in the photoluminescence spectrum of the fluorescent emissive material is less than or equal to 30 nm.

11. The organic electroluminescent device according to claim 1, wherein the metal complex has a general formula of M(Lₐ)ₘ(L_{b})ₙ(L_{c})_{q};
wherein the metal M is selected from a metal with a relative atomic mass greater than 40;
preferably, the metal M is selected from the group consisting of Cu, Ag, Au, Zn, Ru, Rh, Pd, Os, Ir, and Pt;
the ligands Lₐ, L_{b}, and L_{c} are a first ligand, a second ligand, and a third ligand coordinated to the metal M, respectively, and the ligands Lₐ, L_{b}, and L_{c} may be the same or different;
the ligands Lₐ, L_{b}, and L_{c} can be optionally joined to form a multidentate ligand;
m is 1, 2 or 3; n is 0, 1 or 2; q is 0, 1 or 2; the sum of m, n, and q is equal to an oxidation state of the metal M; when m is greater than or equal to 2, a plurality of Lₐ may be the same or different;
when n is 2, two L_{b} may be the same or different; when q is 2, two L_{c} may be the same or different;
the ligand Lₐ has a structure represented by Formula 2: 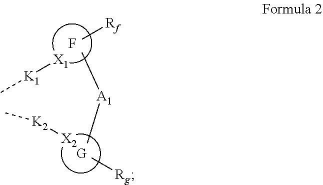
wherein the ring F and the ring G are, at each occurrence identically or differently, selected from an unsaturated carbocyclic ring having 5 to 30 carbon atoms, an unsaturated heterocyclic ring having 1 to 30 carbon atoms or a combination thereof;
X₁ and X₂ are, at each occurrence identically or differently, selected from C or N;
K₁ and K₂ are each independently selected from a single bond, O or S;
A₁ is selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2, 3, 4 or 5;
R_{f} and R_{g} represent, at each occurrence identically or differently, mono-substitution, multiple substitutions or non-substitution;
R_{f} and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{f} and R_{g} can be optionally joined to form a ring;
the ligands L_{b} and L_{c} are, at each occurrence identically or differently, selected from a monoanionic bidentate ligand;
preferably, the ligands L_{b} and L_{c} are, at each occurrence identically or differently, selected from the group consisting of the following structures: 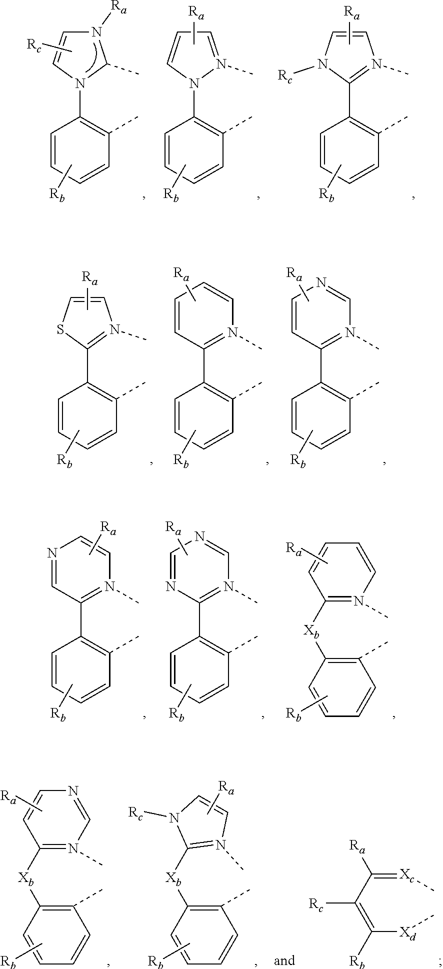
wherein,
Rₐ and R_{b} represent, at each occurrence identically or differently, mono-substitution, multiple substitutions or non-substitution;
X_{b} is, at each occurrence identically or differently, selected from the group consisting of O, S, Se, NR_{N1}, and CR_{C1}R_{C2};
X_{c} and X_{d} are, at each occurrence identically or differently, selected from the group consisting of O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₐ, R_{b}, R_{c}, R_{N1}, R_{N2}, R_{C1}, and R_{C2} can be optionally joined to form a ring.

12. The organic electroluminescent device according to claim 1, wherein the metal complex has a structure represented by Formula 3: 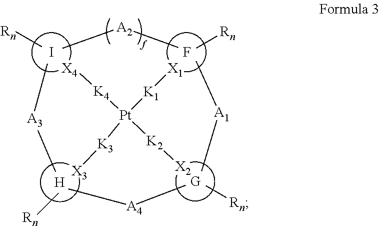
wherein in Formula 3,
the ring F, the ring G, the ring H, and the ring I are each independently selected from an unsaturated carbocyclic ring having 5 to 30 carbon atoms, an unsaturated heterocyclic ring having 1 to 30 carbon atoms or a combination thereof;
f is selected from 0 or 1;
A₁ to A₄ are, at each occurrence identically or differently, selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof;
y is, at each occurrence identically or differently, selected from 1, 2, 3, 4 or 5;
X₁ to X₄ are each independently selected from C or N;
K₁ to K₄ are each independently selected from a single bond, O or S;
Rₙ represents, at each occurrence identically or differently, mono-substitution, multiple substitutions or non-substitution;
R_{q} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{q} and Rₙ can be optionally joined to form a ring;
preferably, the metal complex has a structure represented by Formula 3-A: 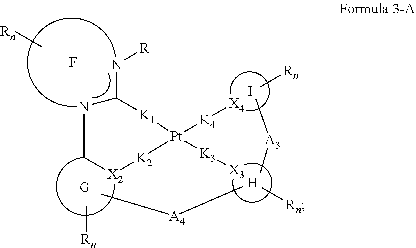
wherein in Formula 3-A,
the ring F is selected from an unsaturated heterocyclic ring having 1 to 30 carbon atoms; the ring G, the ring H, and the ring I are each independently selected from an unsaturated carbocyclic ring having 5 to 30 carbon atoms, an unsaturated heterocyclic ring having 3 to 30 carbon atoms or a combination thereof;
A₃ and A₄ are each independently selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2, 3, 4 or 5;
K₁ to K₄ are each independently selected from a single bond, O or S;
X₂ to X₄ are each independently selected from C or N;
Rₙ represents, at each occurrence identically or differently, mono-substitution, multiple substitutions or non-substitution;
R, R_{q}, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R, R_{q}, and Rₙ can be optionally joined to form a ring.

13. The organic electroluminescent device according to claim 12, wherein the ring F is selected from an unsaturated heterocyclic ring having 3 to 30 carbon atoms; the ring G, the ring H, and the ring I are each independently selected from a five-membered unsaturated carbocyclic ring, an aromatic ring having 6 to 30 carbon atoms or a heteroaromatic ring having 3 to 30 carbon atoms;
preferably, the ring F is selected from an unsaturated heterocyclic ring having 3 to 18 carbon atoms; the ring G, the ring H, and the ring I are each independently selected from a five-membered unsaturated carbocyclic ring, an aromatic ring having 6 to 18 carbon atoms or a heteroaromatic ring having 3 to 18 carbon atoms;
more preferably, the ring F is selected from an imidazole-carbene ring or a benzimidazole-carbene ring; the ring G, the ring H, and the ring I are each independently selected from a benzene ring, a pyridine ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring or a silole ring.

14. The organic electroluminescent device according to claim 1, wherein the metal complex has a structure represented by one of Formula 3-1 to Formula 3-20: 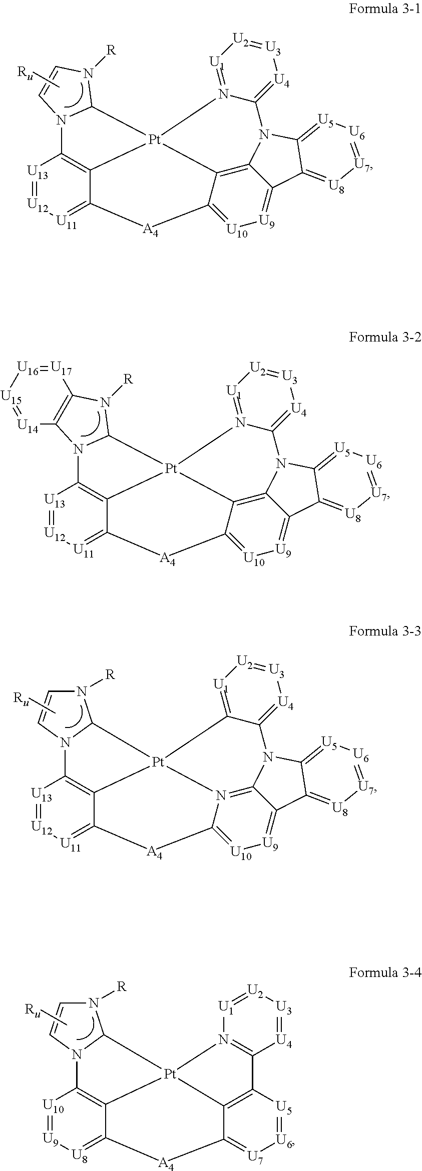 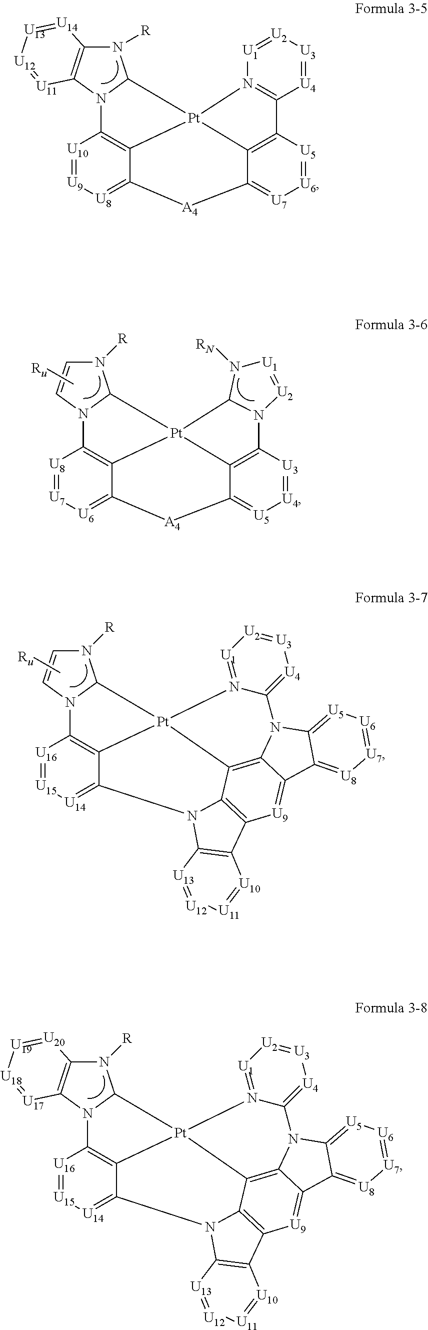 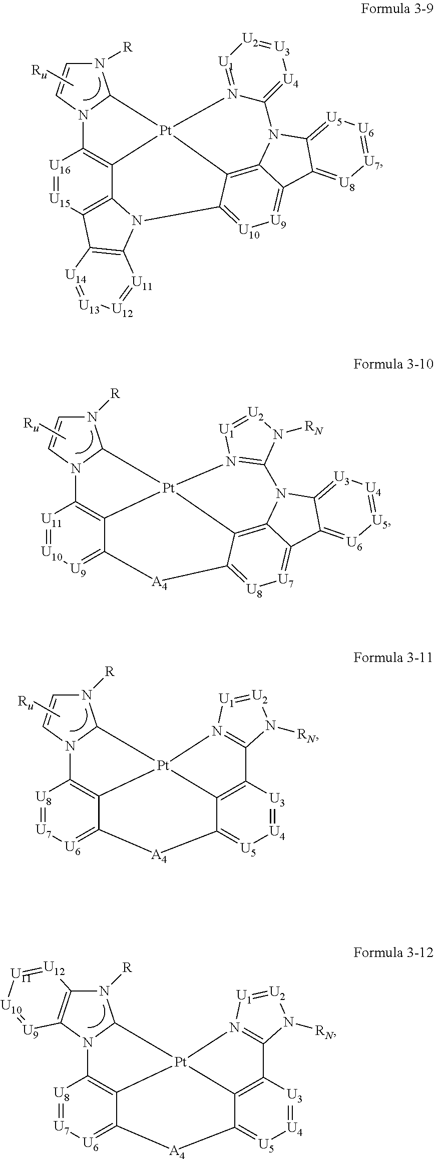 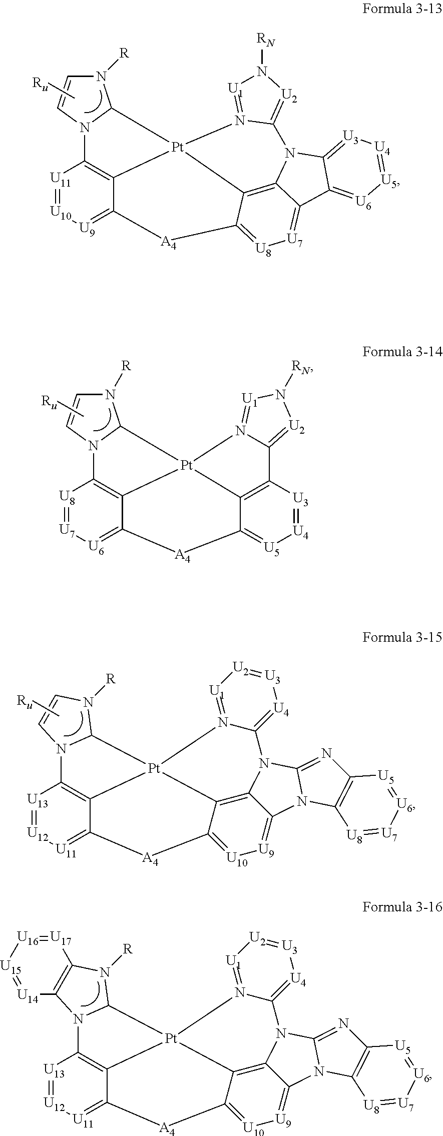 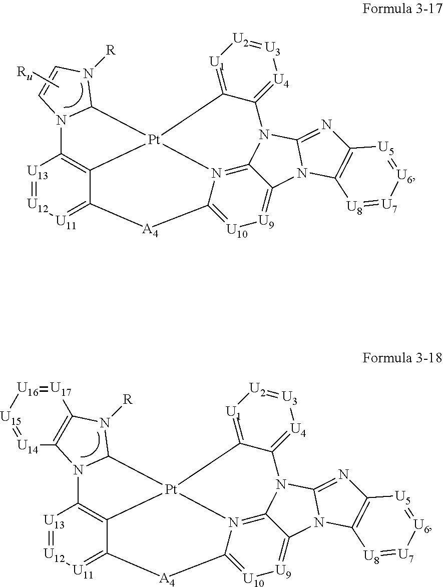 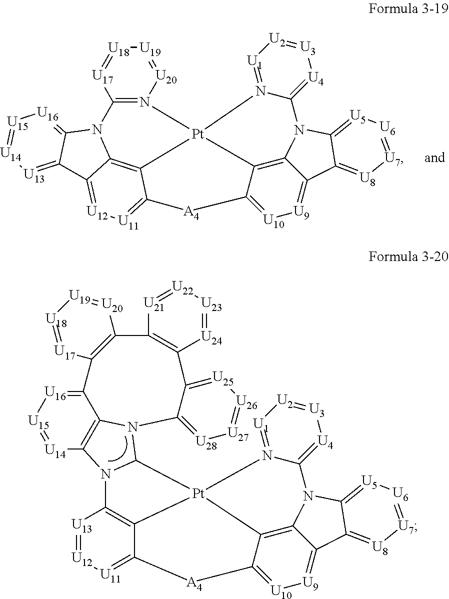
wherein,
A₄ is, at each occurrence identically or differently, selected from a single bond, O, S, Se, (SiR_{q}R_{q})_{y}, PR_{q}, NR_{q}, substituted or unsubstituted arylene having 6 to 30 carbon atoms, substituted or unsubstituted heteroarylene having 3 to 30 carbon atoms or a combination thereof; y is, at each occurrence identically or differently, selected from 1, 2 or 3;
U₁ to U₂₈ are, at each occurrence identically or differently, selected from CRₙ or N;
Rᵤ represents, at each occurrence identically or differently, mono-substitution, multiple substitutions or non-substitution;
R, R_{N}, R_{q}, Rᵤ, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R, R_{N}, R_{q}, Rᵤ, and Rₙ can be optionally joined to form a ring;
preferably, the metal complex has a structure represented by Formula 3-1 or Formula 3-2.

15. The organic electroluminescent device according to claim 12, wherein R has a structure represented by Formula 4: 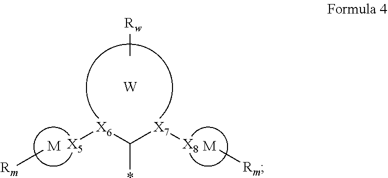
wherein in Formula 4,
the ring M and the ring W are, at each occurrence identically or differently, selected from an unsaturated carbocyclic ring having 5 to 30 carbon atoms, an unsaturated heterocyclic ring having 3 to 30 carbon atoms or a combination thereof;
X₅ to X₈ are, at each occurrence identically or differently, selected from C or N;
“*” represents a position where Formula 4 is joined;
Rₘ and R_{w} represent, at each occurrence identically or differently, mono-substitution, multiple substitutions or non-substitution;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₘ and R_{w} can be optionally joined to form a ring;
preferably, R has a structure represented by Formula 4-1: 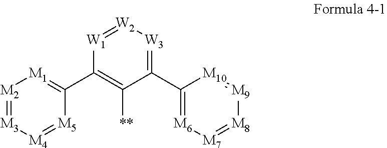
wherein in Formula 4-1,
M₁ to M₁₀ are each independently selected from CRₘ or N;
W₁ to W₃ are each independently selected from CR_{w} or N;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₘ and R_{w} can be optionally joined to form a ring;
more preferably, at least one R_{w} in the R is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

16. The organic electroluminescent device according to claim 1, wherein the metal complex is selected from the group consisting of BD1 to BD18: 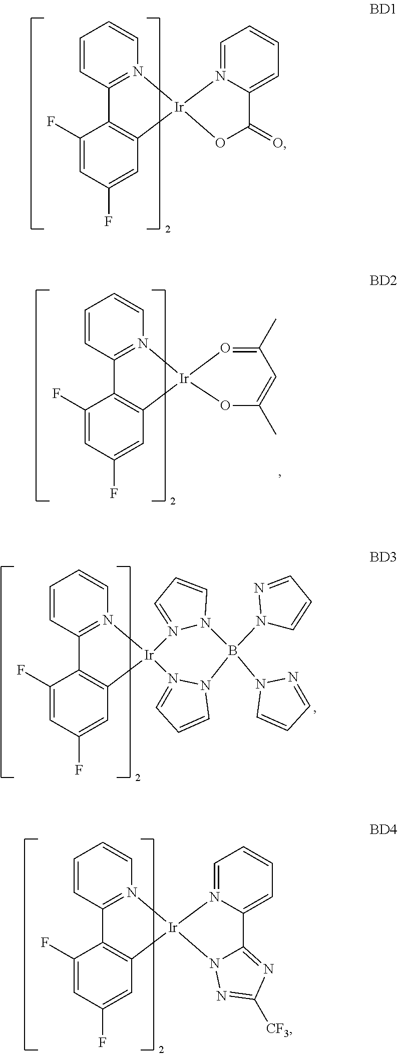 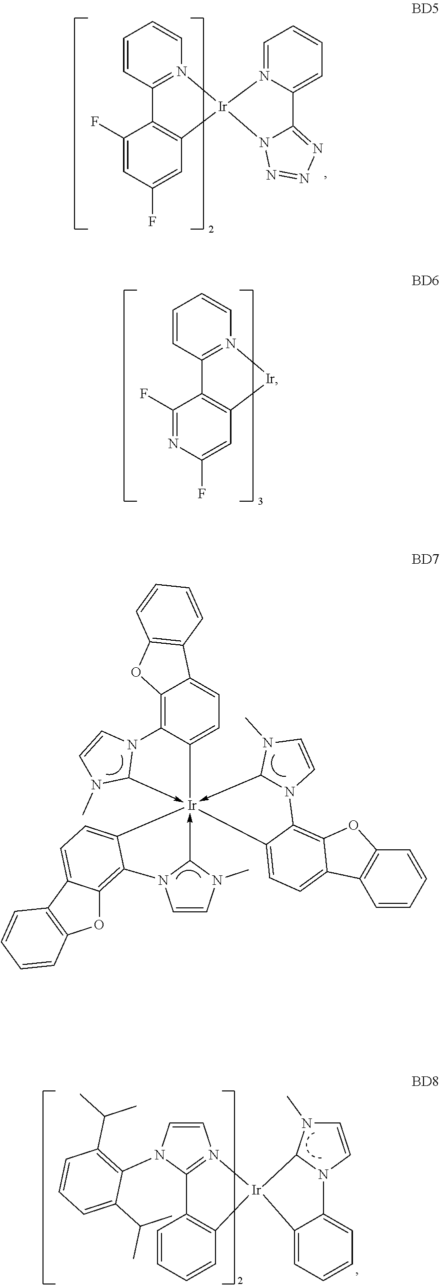 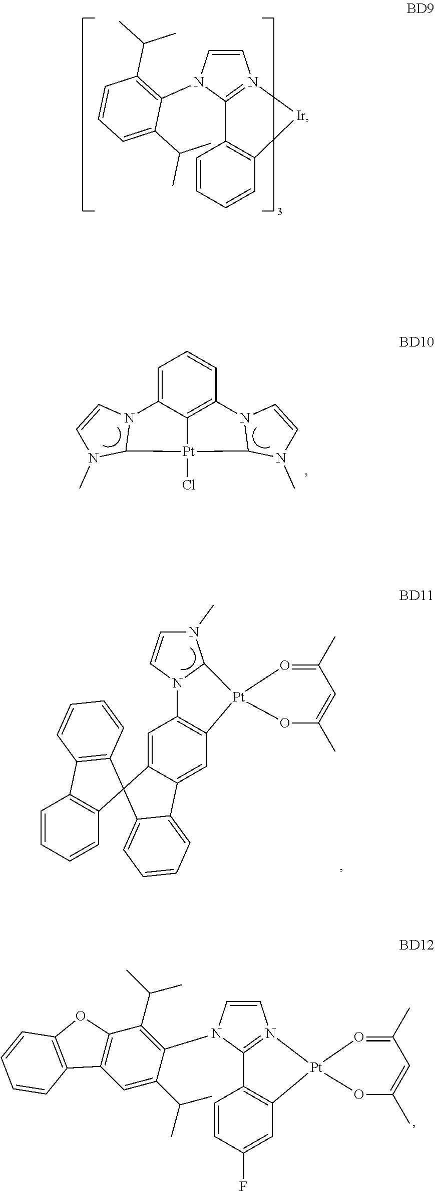 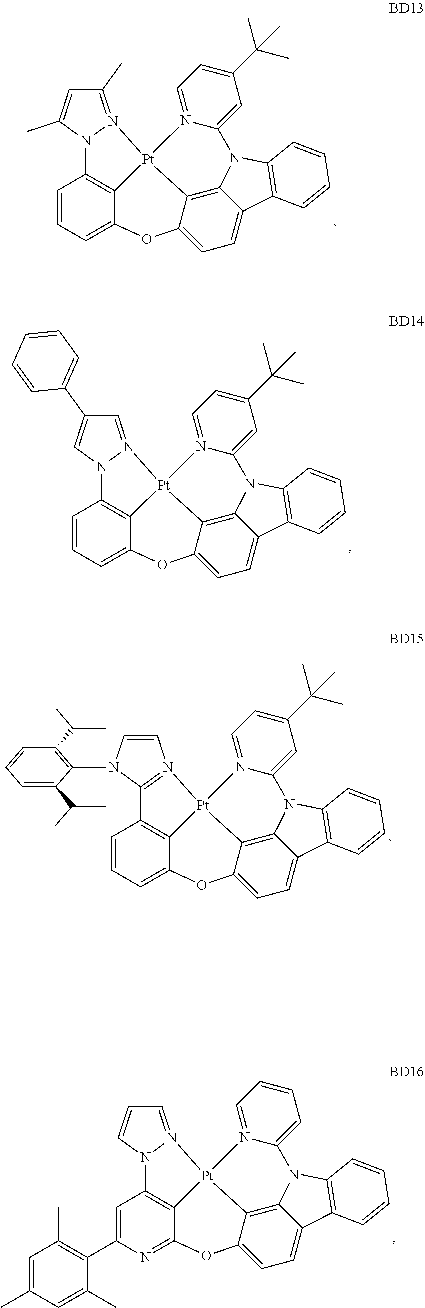 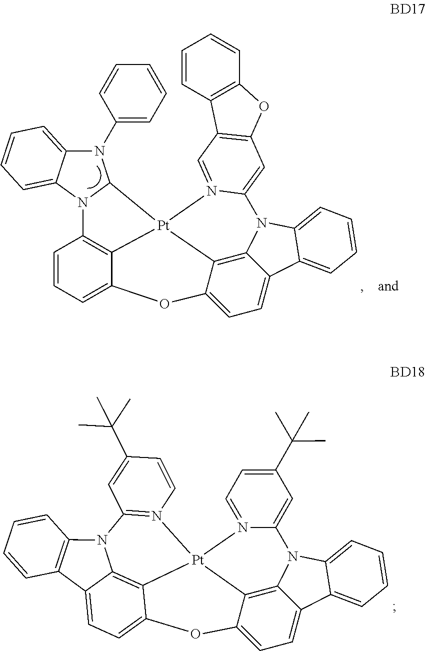
or the metal complex has a structure represented by Pt(Lₐ)(L_{b}), wherein Lₐ and L_{b} are a first ligand and a second ligand coordinated to metal Pt, respectively, and Lₐ is selected from the group consisting of Lₐ1-1 to Lₐ1-25 and Lₐ2-1 to Lₐ2-6: 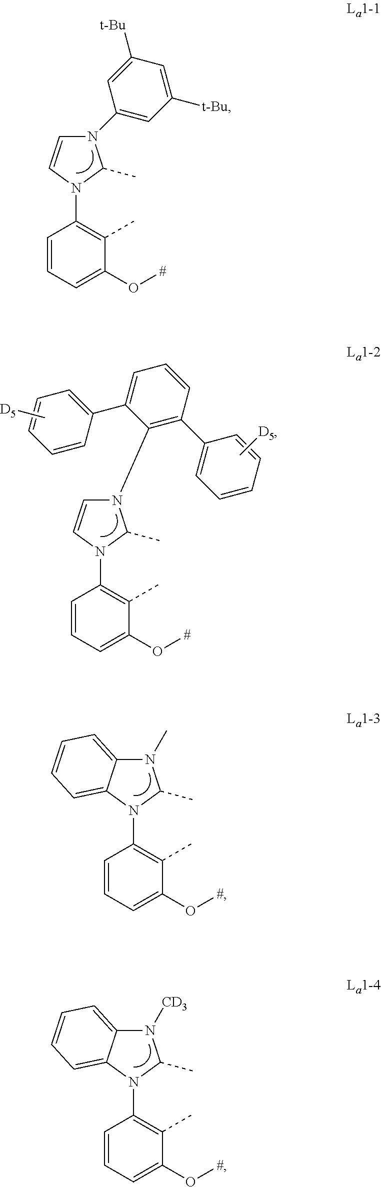 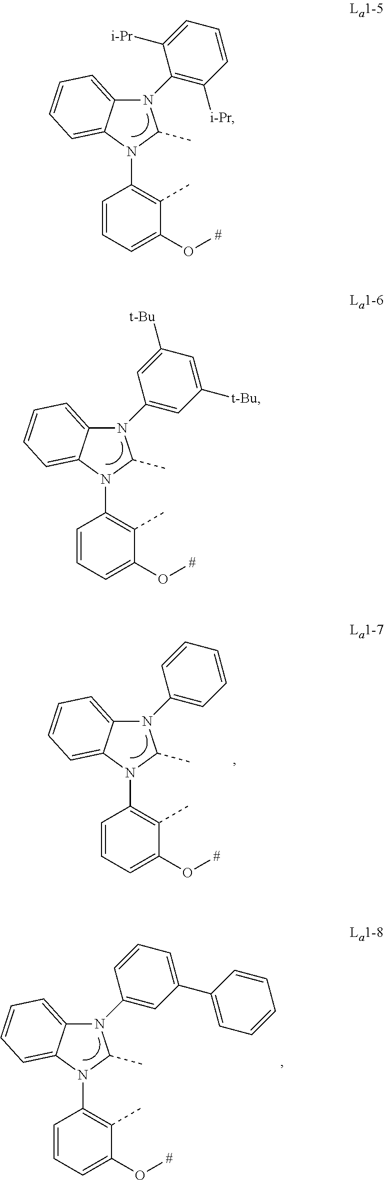 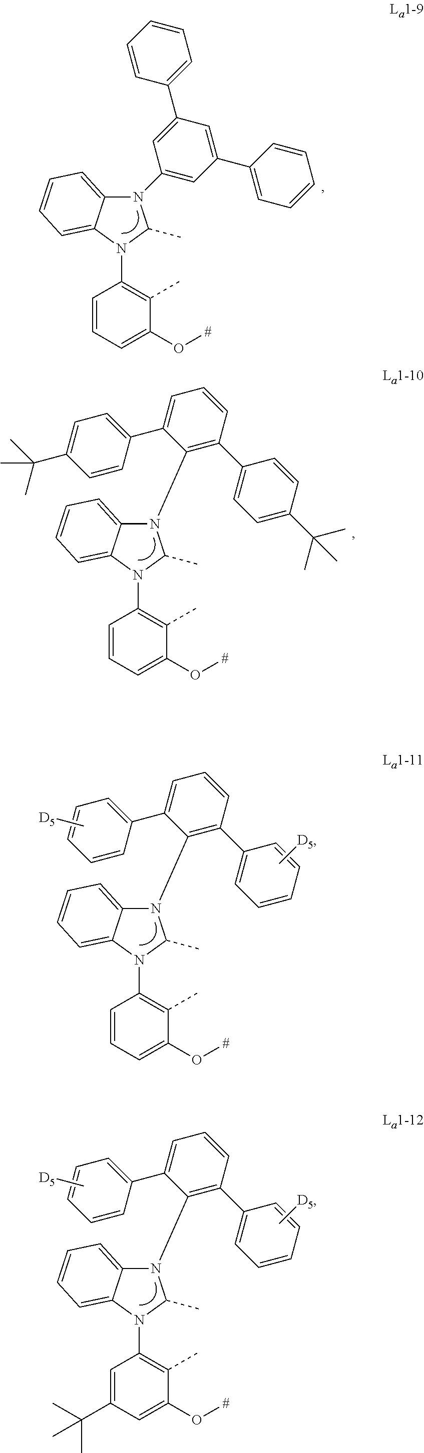 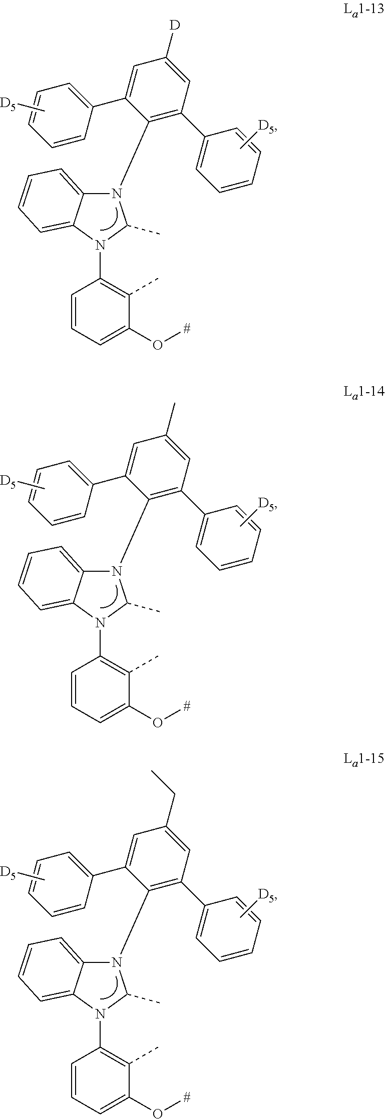 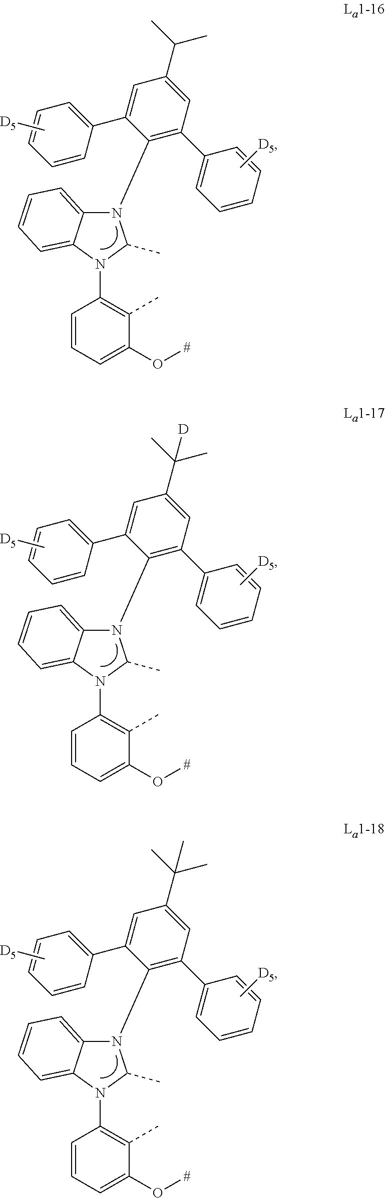 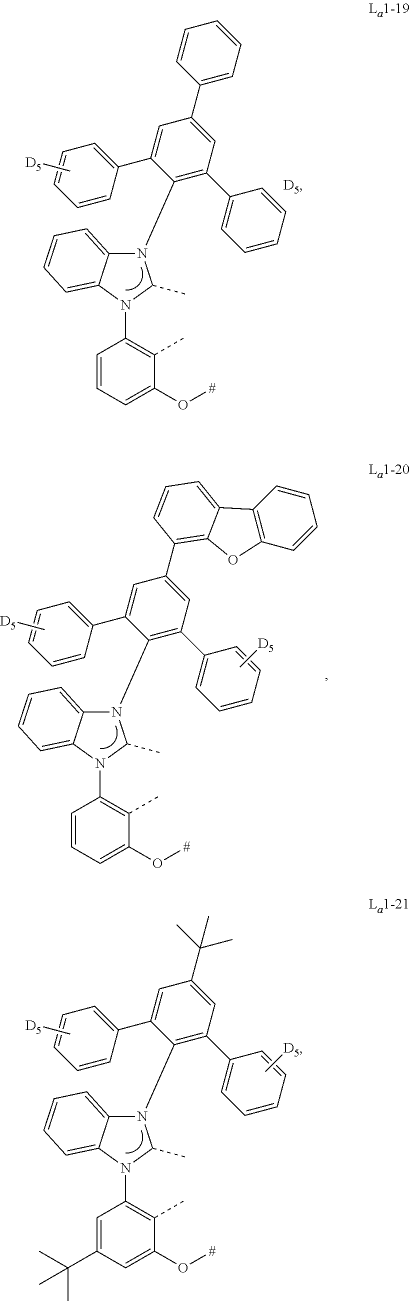 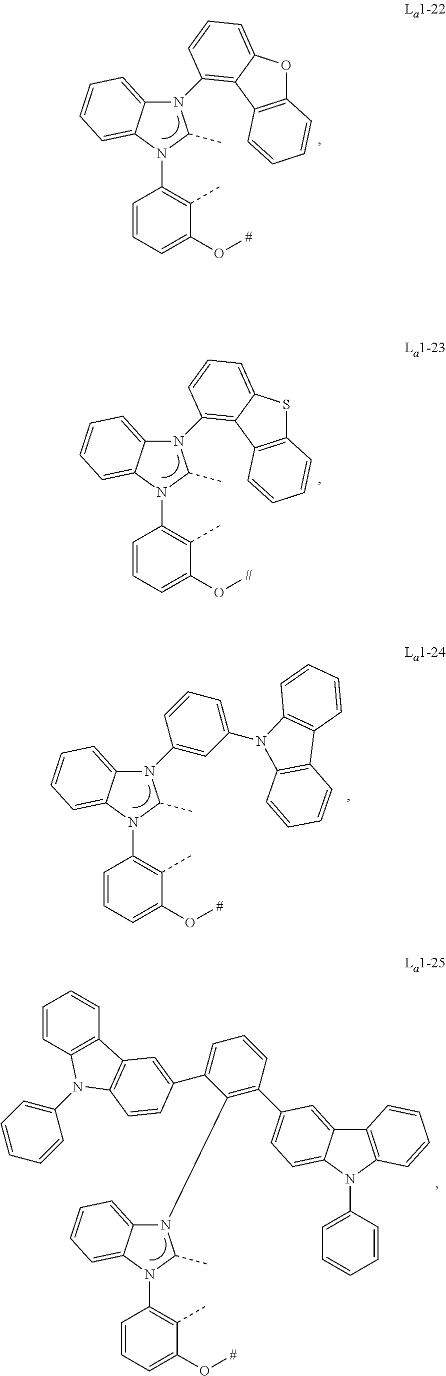 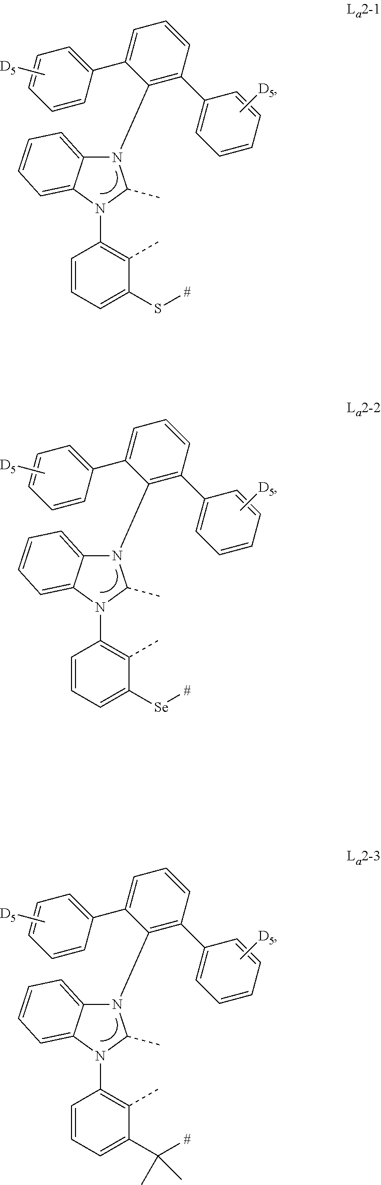 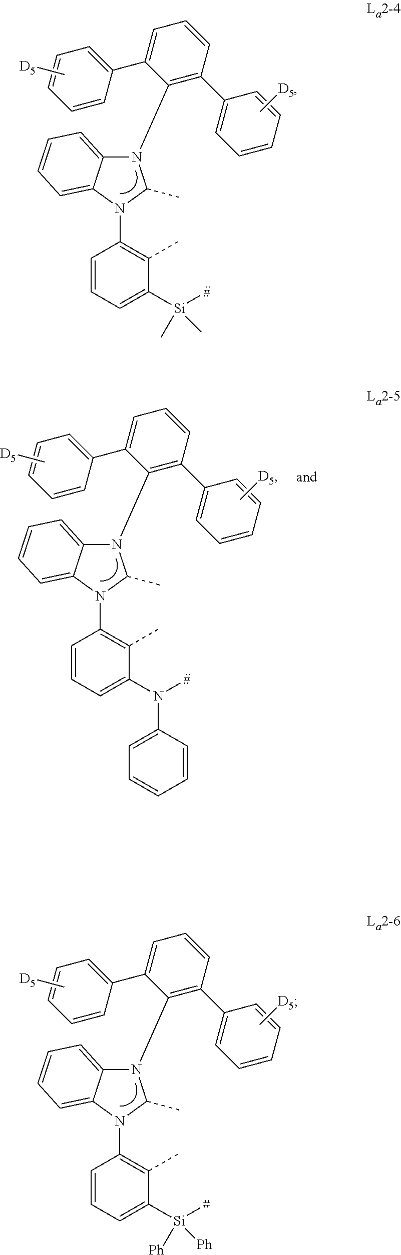
wherein “#” in the structures of Lₐ1-1 to Lₐ1-25 and Lₐ2-1 to Lₐ2-6 represents a position where L_{b} is joined;
L_{b} is selected from the group consisting of L_{b}1-1 to L_{b}1-8 and L_{b}2-1 to L_{b}2-22: 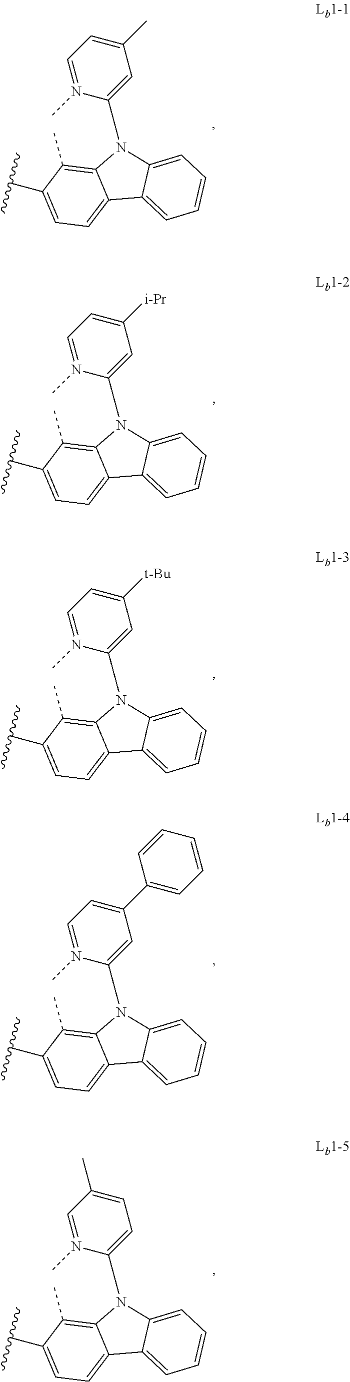 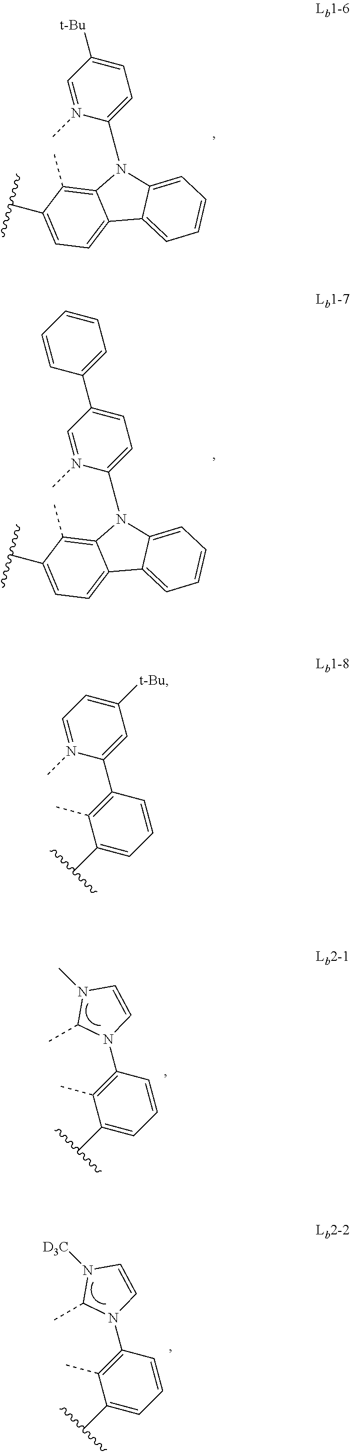 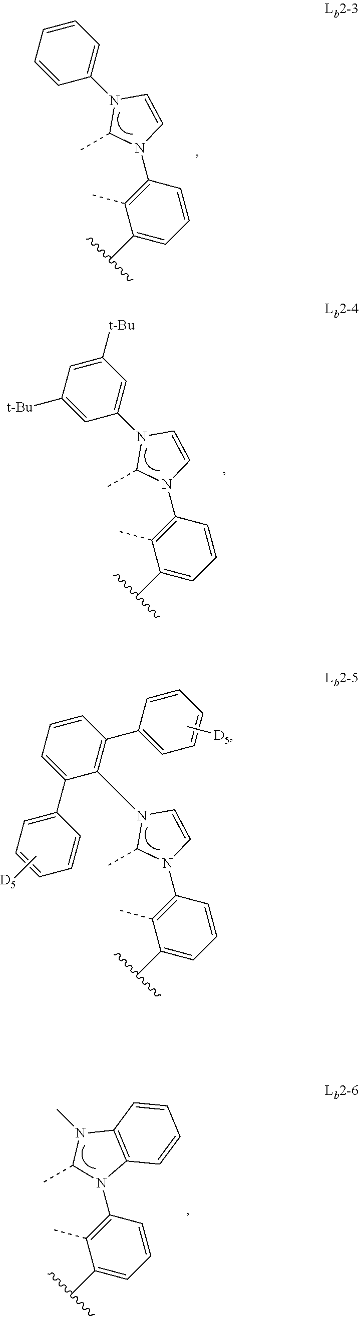 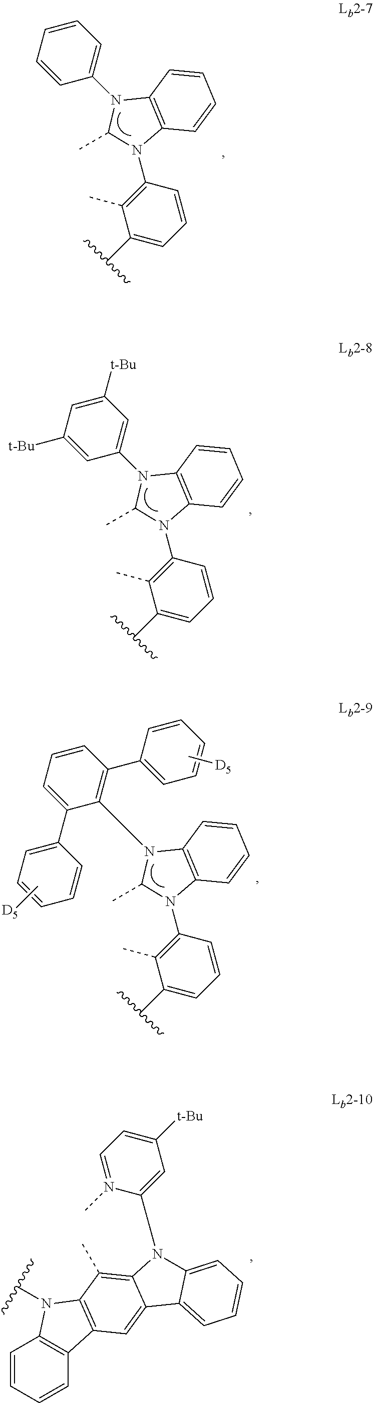 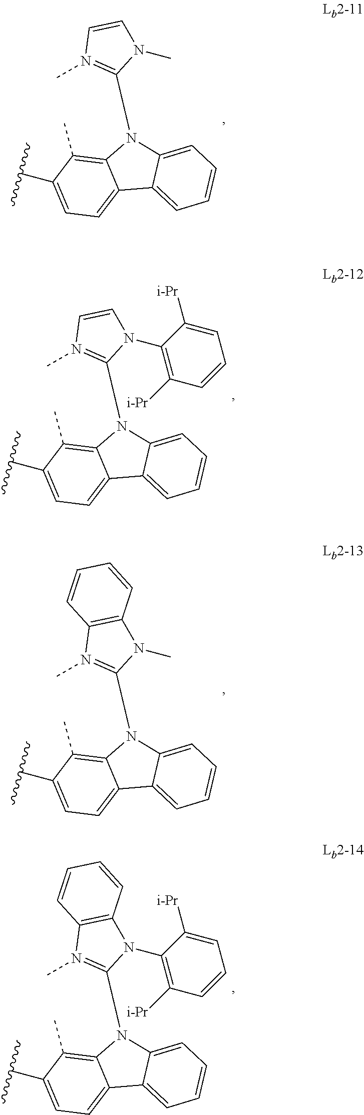 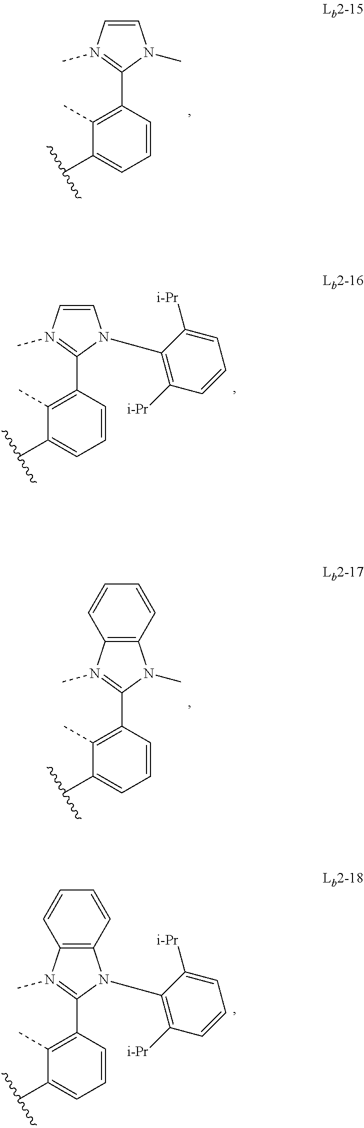 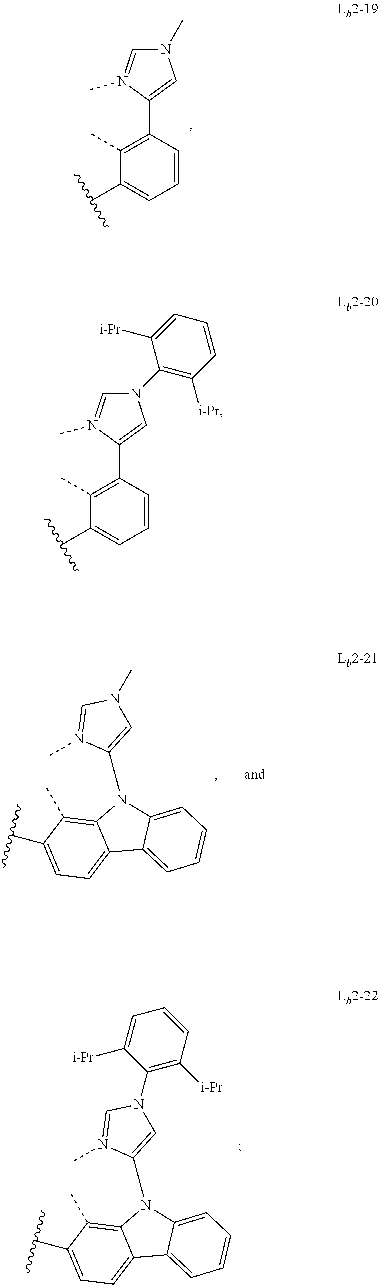
wherein “#” in the structures L_{b}1-1 to L_{b}1-8 and L_{b}2-1 to L_{b}2-22 represents a position joined to where L_{b} is joined;
preferably, the metal complex is selected from the group consisting of Pt1 to Pt81, and the Pt1 to Pt81 each have a structure represented by Pt(Lₐ)(L_{b}), wherein the Lₐ and the L_{b} are selected from structures shown in the following table, respectively:

| Metal | | | Metal | | |
|---|---|---|---|---|---|
| Complex No. | Lₐ | L_{b} | Complex No. | Lₐ | L_{b} |
| Pt1 | Lₐ1-6 | L_{b}1-1 | Pt2 | Lₐ1-6 | L_{b}1-2 |
| Pt3 | Lₐ1-6 | L_{b}1-3 | Pt4 | Lₐ1-6 | L_{b}1-4 |
| Pt5 | Lₐ1-6 | L_{b}1-5 | Pt6 | Lₐ1-6 | L_{b}1-6 |
| Pt7 | Lₐ1-6 | L_{b}1-7 | Pt8 | Lₐ1-6 | L_{b}1-8 |
| Pt9 | Lₐ1-11 | L_{b}1-1 | Pt10 | Lₐ1-11 | L_{b}1-2 |
| Pt11 | Lₐ1-11 | L_{b}1-3 | Pt12 | Lₐ1-11 | L_{b}1-4 |
| Pt13 | Lₐ1-11 | L_{b}1-5 | Pt14 | Lₐ1-11 | L_{b}1-6 |
| Pt15 | Lₐ1-11 | L_{b}1-7 | Pt16 | Lₐ1-11 | L_{b}1-8 |
| Pt17 | Lₐ1-12 | L_{b}1-1 | Pt18 | Lₐ1-12 | L_{b}1-2 |
| Pt19 | Lₐ1-12 | L_{b}1-3 | Pt20 | Lₐ1-12 | L_{b}1-4 |
| Pt21 | Lₐ1-12 | L_{b}1-5 | Pt22 | Lₐ1-12 | L_{b}1-6 |
| Pt23 | Lₐ1-12 | L_{b}1-7 | Pt24 | Lₐ1-12 | L_{b}1-8 |
| Pt25 | Lₐ1-18 | L_{b}1-1 | Pt26 | Lₐ1-18 | L_{b}1-2 |
| Pt27 | Lₐ1-18 | L_{b}1-3 | Pt28 | Lₐ1-18 | L_{b}1-4 |
| Pt29 | Lₐ1-18 | L_{b}1-5 | Pt30 | Lₐ1-18 | L_{b}1-6 |
| Pt31 | Lₐ1-18 | L_{b}1-7 | Pt32 | Lₐ1-18 | L_{b}1-8 |
| Pt33 | Lₐ1-18 | L_{b}2-1 | Pt34 | Lₐ1-18 | L_{b}2-2 |
| Pt35 | Lₐ1-18 | L_{b}2-3 | Pt36 | Lₐ1-18 | L_{b}2-4 |
| Pt37 | Lₐ1-18 | L_{b}2-5 | Pt38 | Lₐ1-18 | L_{b}2-6 |
| Pt39 | Lₐ1-18 | L_{b}2-7 | Pt40 | Lₐ1-18 | L_{b}2-8 |
| Pt41 | Lₐ1-18 | L_{b}2-9 | Pt42 | Lₐ1-18 | L_{b}2-10 |
| Pt43 | Lₐ1-18 | L_{b}2-11 | Pt44 | Lₐ1-18 | L_{b}2-12 |
| Pt45 | Lₐ1-18 | L_{b}2-13 | Pt46 | Lₐ1-18 | L_{b}2-14 |
| Pt47 | Lₐ1-18 | L_{b}2-15 | Pt48 | Lₐ1-18 | L_{b}2-16 |
| Pt49 | Lₐ1-18 | L_{b}2-17 | Pt50 | Lₐ1-18 | L_{b}2-18 |
| Pt51 | Lₐ1-18 | L_{b}2-19 | Pt52 | Lₐ1-18 | L_{b}2-20 |
| Pt53 | Lₐ1-18 | L_{b}2-21 | Pt54 | Lₐ1-18 | L_{b}2-22 |
| Pt55 | Lₐ1-1 | L_{b}1-3 | Pt56 | Lₐ1-2 | L_{b}1-3 |
| Pt57 | Lₐ1-3 | L_{b}1-3 | Pt58 | Lₐ1-4 | L_{b}1-3 |
| Pt59 | Lₐ1-5 | L_{b}1-3 | Pt60 | Lₐ1-7 | L_{b}1-3 |
| Pt61 | Lₐ1-8 | L_{b}1-3 | Pt62 | Lₐ1-9 | L_{b}1-3 |
| Pt63 | Lₐ1-10 | L_{b}1-3 | Pt64 | Lₐ1-13 | L_{b}1-3 |
| Pt65 | Lₐ1-14 | L_{b}1-3 | Pt66 | Lₐ1-15 | L_{b}1-3 |
| Pt67 | Lₐ1-16 | L_{b}1-3 | Pt68 | Lₐ1-17 | L_{b}1-3 |
| Pt69 | Lₐ1-19 | L_{b}1-3 | Pt70 | Lₐ1-20 | L_{b}1-3 |
| Pt71 | Lₐ1-21 | L_{b}1-3 | Pt72 | Lₐ1-22 | L_{b}1-3 |
| Pt73 | Lₐ1-23 | L_{b}1-3 | Pt74 | Lₐ1-24 | L_{b}1-3 |
| Pt75 | Lₐ1-25 | L_{b}1-3 | Pt76 | Lₐ2-1 | L_{b}1-3 |
| Pt77 | Lₐ2-2 | L_{b}1-3 | Pt78 | Lₐ2-3 | L_{b}1-3 |
| Pt79 | Lₐ2-4 | L_{b}1-3 | Pt80 | Lₐ2-5 | L_{b}1-3 |
| Pt81 | Lₐ2-6 | L_{b}1-3. | | | |

17. The organic electroluminescent device according to claim 1, wherein the metal complex is a phosphorescent sensitizer.

18. The organic electroluminescent device according to claim 1, wherein the first host compound and the second host compound are each independently selected from the group consisting of compounds containing at least one of the following chemical groups: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

19. The organic electroluminescent device according to claim 1, wherein the first host compound has a structure represented by one of Formula 5 to Formula 7: 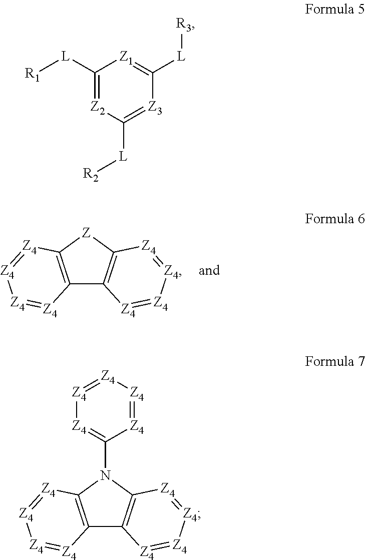
wherein in Formula 5, Z₁ to Z₃ are, at each occurrence identically or differently, selected from CR₄ or N, and at least one of Z₁ to Z₃ is N;
L is, at each occurrence identically or differently, selected from the group consisting of: a single bond, substituted or unsubstituted arylene having 6 to 30 carbon atoms, substituted or unsubstituted heteroarylene having 3 to 30 carbon atoms, and combinations thereof;
in Formula 6 and Formula 7, Z₄ is, at each occurrence identically or differently, selected from CR₄ or N, and at least one Z₄ is N;
Z is, at each occurrence identically or differently, selected from O or S;
R₁ to R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₄ can be optionally joined to form a ring;
preferably, the first host compound has a structure represented by Formula 5-1 or Formula 6-1: 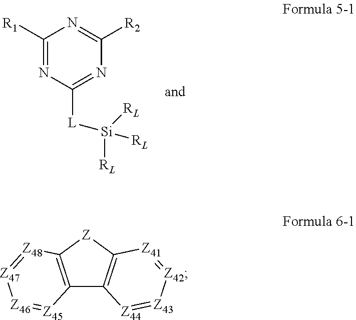
wherein in Formula 5-1,
R₁ and R₂ are each independently selected from substituted or unsubstituted heteroaryl having 3 to 30 carbon atoms;
L is selected from a single bond, substituted or unsubstituted arylene having 6 to 30 carbon atoms, substituted or unsubstituted heteroarylene having 3 to 30 carbon atoms or a combination thereof;
wherein in Formula 6-1,
Z is selected from O or S;
Z₄₁ to Z₄₈ are, at each occurrence identically or differently, selected from CR₄, CR₄′ or N, at least one of Z₄₁ to Z₄₈ is selected from N, and at least one of Z₄₁ to Z₄₈ is selected from CR₄′;
R₄′ is, at each occurrence identically or differently, selected from substituted or unsubstituted aryl having 6 to 30 carbon atoms, substituted or unsubstituted heteroaryl having 3 to 30 carbon atoms or a combination thereof;
R_{L} and R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₄ can be optionally joined to form a ring;
more preferably, the first host compound is selected from the group consisting of Compound N-1-1 to Compound N-1-60, Compound N-2-1 to Compound N-2-35, and Compound N-3-1 to Compound N-3-9: 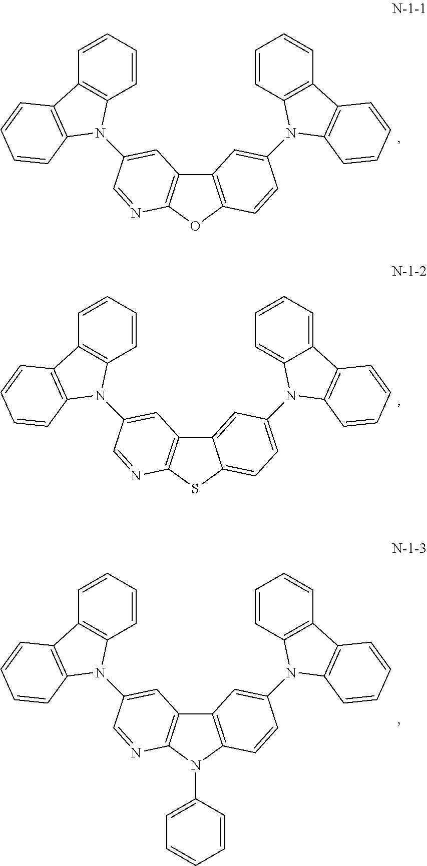 [SMILES: c1ccc2c(c1)c1ccccc1n2-c1ccc2oc3ncc(-n4c5ccccc5c5ccccc54)cc3c2c1 ; c1ccc2c(c1)c1ccccc1n2-c1ccc2sc3ncc(-n4c5ccccc5c5ccccc54)cc3c2c1 ; c1ccc(-n2c3ccc(-n4c5ccccc5c5ccccc54)cc3c3cc(-n4c5ccccc5c5ccccc54)cnc32)cc1] 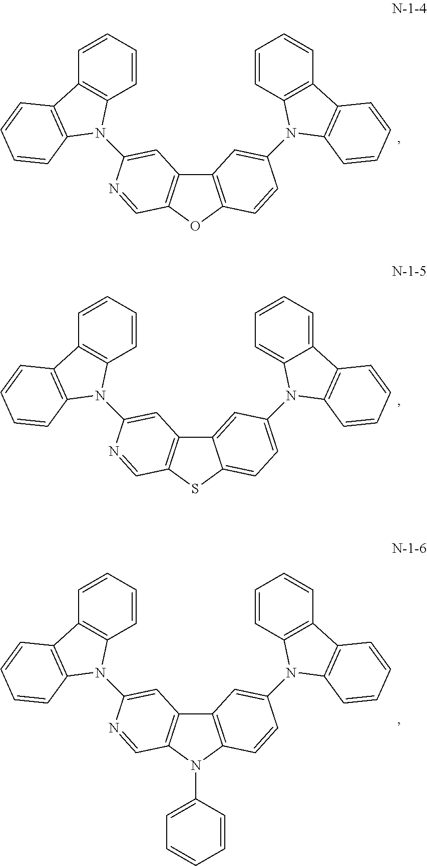 [SMILES: c1ccc2c(c1)c1ccccc1n2-c1ccc2oc3cnc(-n4c5ccccc5c5ccccc54)cc3c2c1 ; c1ccc2c(c1)c1ccccc1n2-c1ccc2sc3cnc(-n4c5ccccc5c5ccccc54)cc3c2c1 ; c1ccc(-n2c3ccc(-n4c5ccccc5c5ccccc54)cc3c3cc(-n4c5ccccc5c5ccccc54)ncc32)cc1] 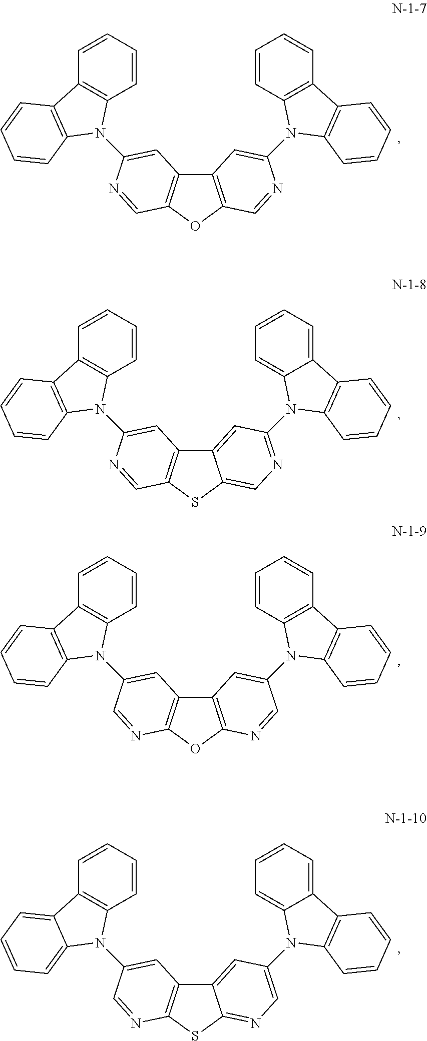 [SMILES: c1ccc2c(c1)c1ccccc1n2-c1cc2c(cn1)oc1cnc(-n3c4ccccc4c4ccccc43)cc12 ; c1ccc2c(c1)c1ccccc1n2-c1cc2c(cn1)sc1cnc(-n3c4ccccc4c4ccccc43)cc12 ; c1ccc2c(c1)c1ccccc1n2-c1cnc2oc3ncc(-n4c5ccccc5c5ccccc54)cc3c2c1 ; c1ccc2c(c1)c1ccccc1n2-c1cnc2sc3ncc(-n4c5ccccc5c5ccccc54)cc3c2c1] 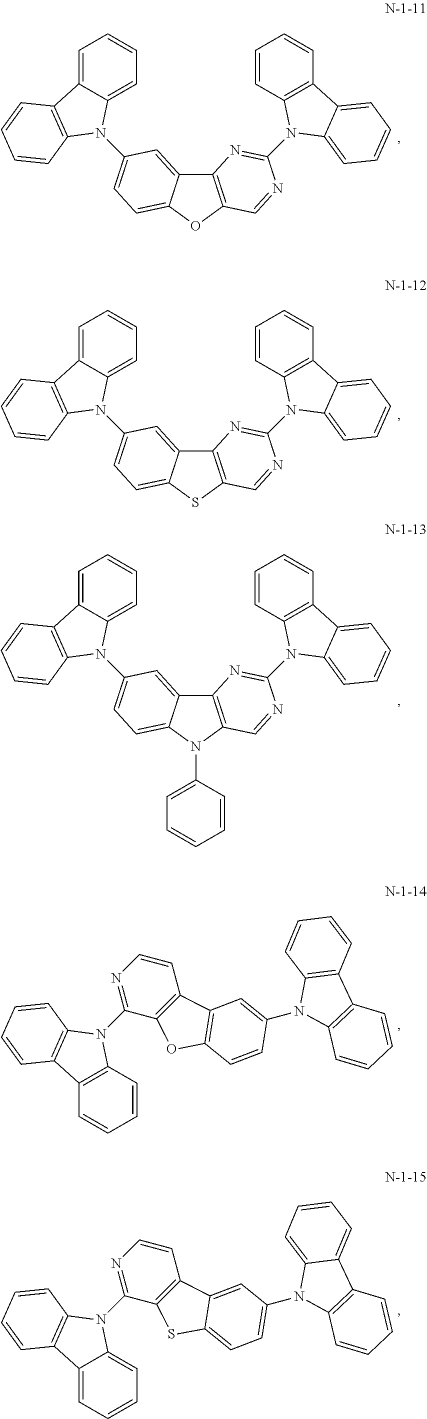 [SMILES: c1ccc2c(c1)c1ccccc1n2-c1ccc2oc3cnc(-n4c5ccccc5c5ccccc54)nc3c2c1 ; c1ccc2c(c1)c1ccccc1n2-c1ccc2sc3cnc(-n4c5ccccc5c5ccccc54)nc3c2c1 ; c1ccc(-n2c3ccc(-n4c5ccccc5c5ccccc54)cc3c3nc(-n4c5ccccc5c5ccccc54)ncc32)cc1 ; c1ccc2c(c1)c1ccccc1n2-c1ccc2oc3c(-n4c5ccccc5c5ccccc54)nccc3c2c1 ; c1ccc2c(c1)c1ccccc1n2-c1ccc2sc3c(-n4c5ccccc5c5ccccc54)nccc3c2c1] 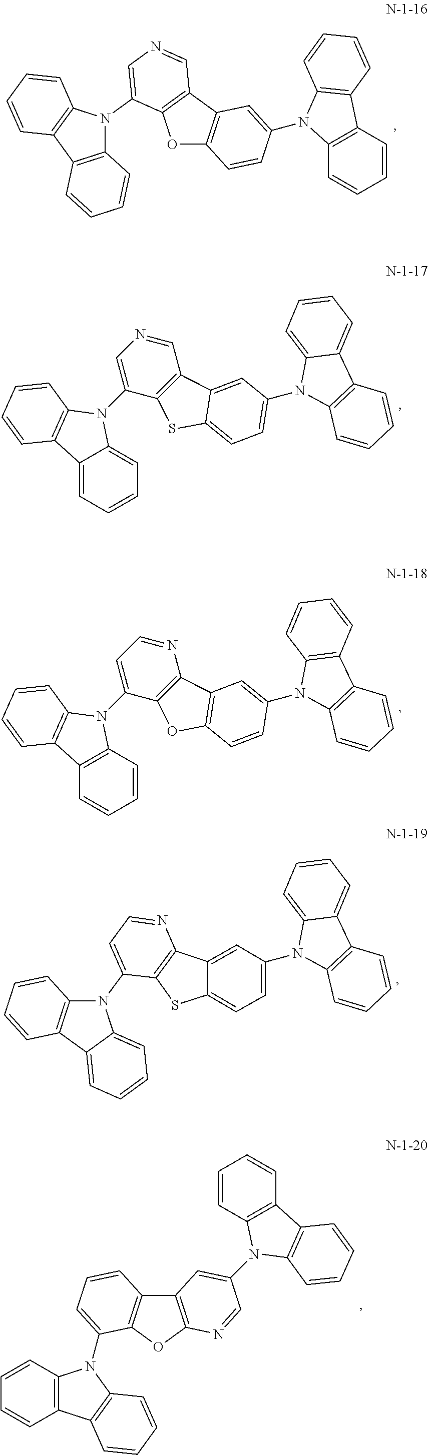 [SMILES: c1ccc2c(c1)c1ccccc1n2-c1ccc2oc3c(-n4c5ccccc5c5ccccc54)cncc3c2c1 ; c1ccc2c(c1)c1ccccc1n2-c1ccc2sc3c(-n4c5ccccc5c5ccccc54)cncc3c2c1 ; c1ccc2c(c1)c1ccccc1n2-c1ccc2oc3c(-n4c5ccccc5c5ccccc54)ccnc3c2c1 ; c1ccc2c(c1)c1ccccc1n2-c1ccc2sc3c(-n4c5ccccc5c5ccccc54)ccnc3c2c1 ; c1cc(-n2c3ccccc3c3ccccc32)c2oc3ncc(-n4c5ccccc5c5ccccc54)cc3c2c1] 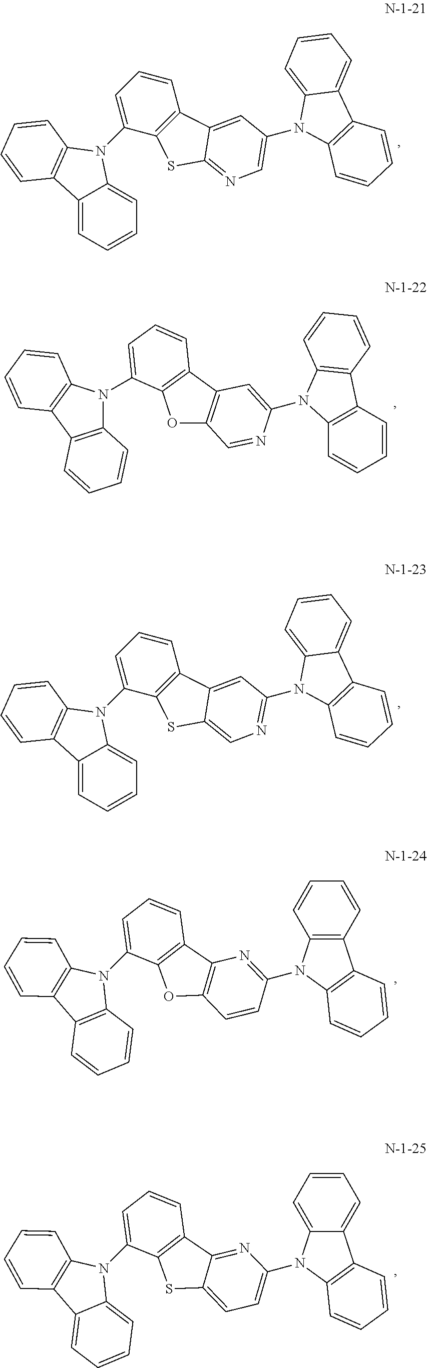 [SMILES: c1cc(-n2c3ccccc3c3ccccc32)c2sc3ncc(-n4c5ccccc5c5ccccc54)cc3c2c1 ; c1cc(-n2c3ccccc3c3ccccc32)c2oc3cnc(-n4c5ccccc5c5ccccc54)cc3c2c1 ; c1cc(-n2c3ccccc3c3ccccc32)c2sc3cnc(-n4c5ccccc5c5ccccc54)cc3c2c1 ; c1cc(-n2c3ccccc3c3ccccc32)c2oc3ccc(-n4c5ccccc5c5ccccc54)nc3c2c1 ; c1cc(-n2c3ccccc3c3ccccc32)c2sc3ccc(-n4c5ccccc5c5ccccc54)nc3c2c1] 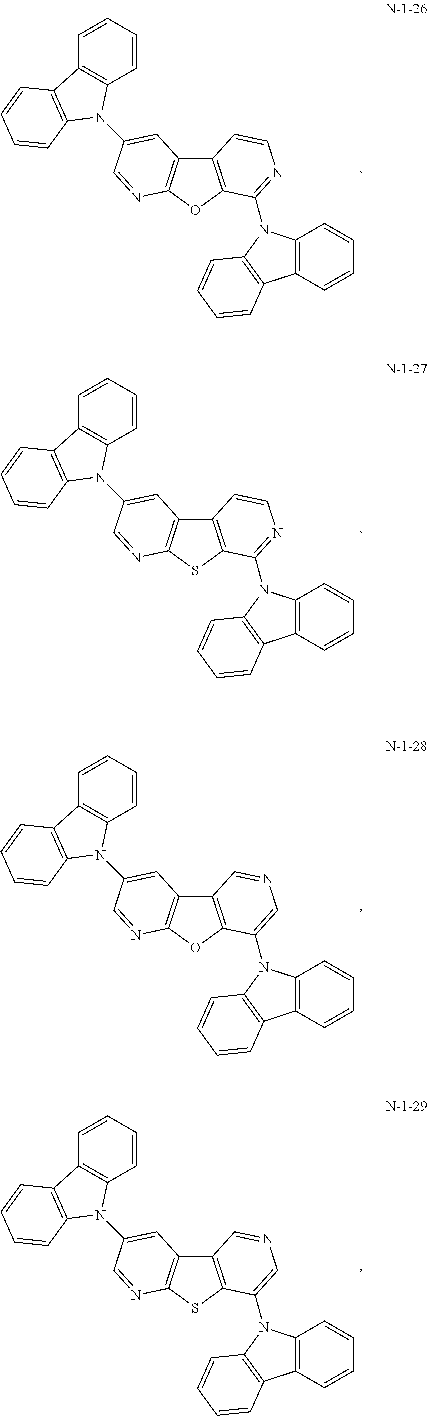 [SMILES: c1ccc2c(c1)c1ccccc1n2-c1cnc2oc3c(-n4c5ccccc5c5ccccc54)nccc3c2c1 ; c1ccc2c(c1)c1ccccc1n2-c1cnc2sc3c(-n4c5ccccc5c5ccccc54)nccc3c2c1 ; c1ccc2c(c1)c1ccccc1n2-c1cnc2oc3c(-n4c5ccccc5c5ccccc54)cncc3c2c1 ; c1ccc2c(c1)c1ccccc1n2-c1cnc2sc3c(-n4c5ccccc5c5ccccc54)cncc3c2c1] 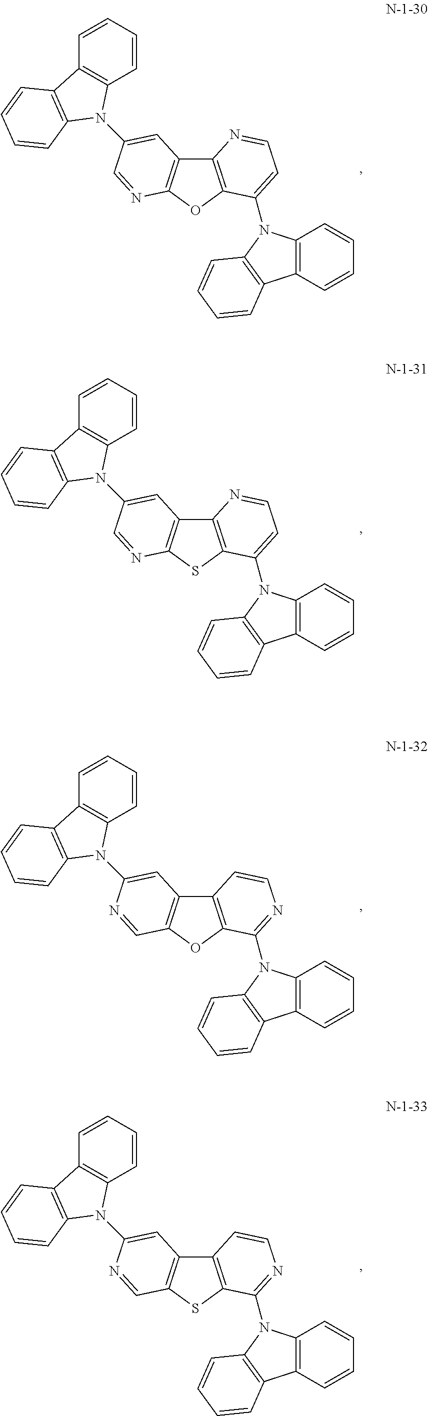 [SMILES: c1ccc2c(c1)c1ccccc1n2-c1cnc2oc3c(-n4c5ccccc5c5ccccc54)ccnc3c2c1 ; c1ccc2c(c1)c1ccccc1n2-c1cnc2sc3c(-n4c5ccccc5c5ccccc54)ccnc3c2c1 ; c1ccc2c(c1)c1ccccc1n2-c1cc2c(cn1)oc1c(-n3c4ccccc4c4ccccc43)nccc12 ; c1ccc2c(c1)c1ccccc1n2-c1cc2c(cn1)sc1c(-n3c4ccccc4c4ccccc43)nccc12] 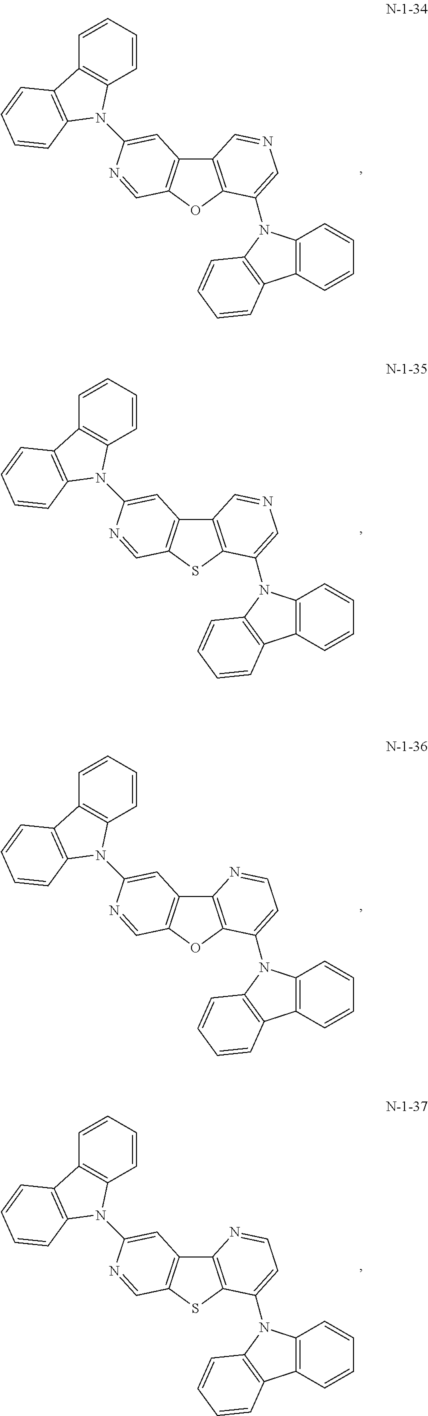 [SMILES: c1ccc2c(c1)c1ccccc1n2-c1cc2c(cn1)oc1c(-n3c4ccccc4c4ccccc43)cncc12 ; c1ccc2c(c1)c1ccccc1n2-c1cc2c(cn1)sc1c(-n3c4ccccc4c4ccccc43)cncc12 ; c1ccc2c(c1)c1ccccc1n2-c1cc2c(cn1)oc1c(-n3c4ccccc4c4ccccc43)ccnc12 ; c1ccc2c(c1)c1ccccc1n2-c1cc2c(cn1)sc1c(-n3c4ccccc4c4ccccc43)ccnc12] 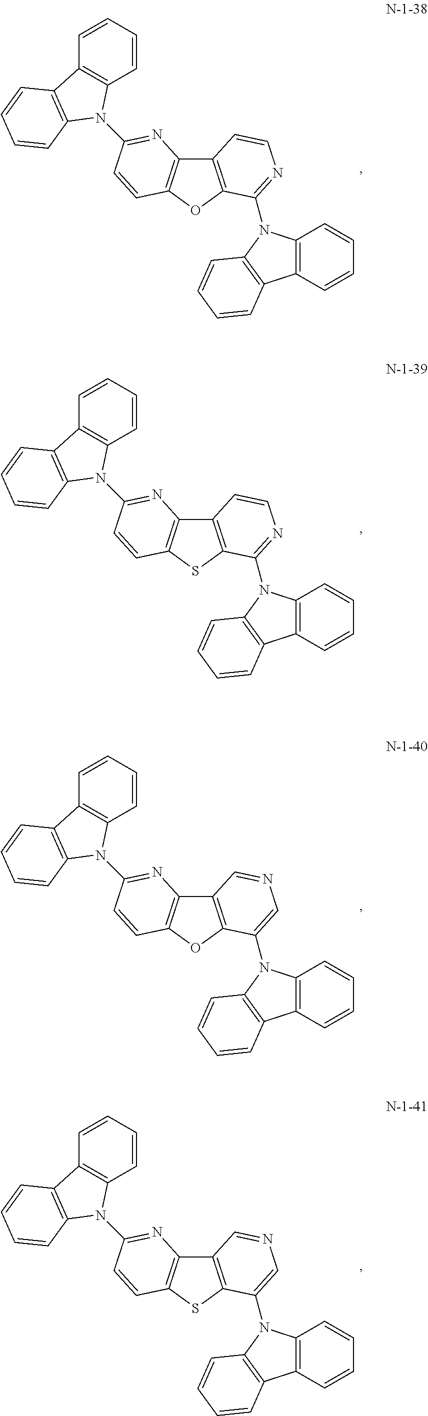 [SMILES: c1ccc2c(c1)c1ccccc1n2-c1ccc2oc3c(-n4c5ccccc5c5ccccc54)nccc3c2n1 ; c1ccc2c(c1)c1ccccc1n2-c1ccc2sc3c(-n4c5ccccc5c5ccccc54)nccc3c2n1 ; c1ccc2c(c1)c1ccccc1n2-c1ccc2oc3c(-n4c5ccccc5c5ccccc54)cncc3c2n1 ; c1ccc2c(c1)c1ccccc1n2-c1ccc2sc3c(-n4c5ccccc5c5ccccc54)cncc3c2n1] 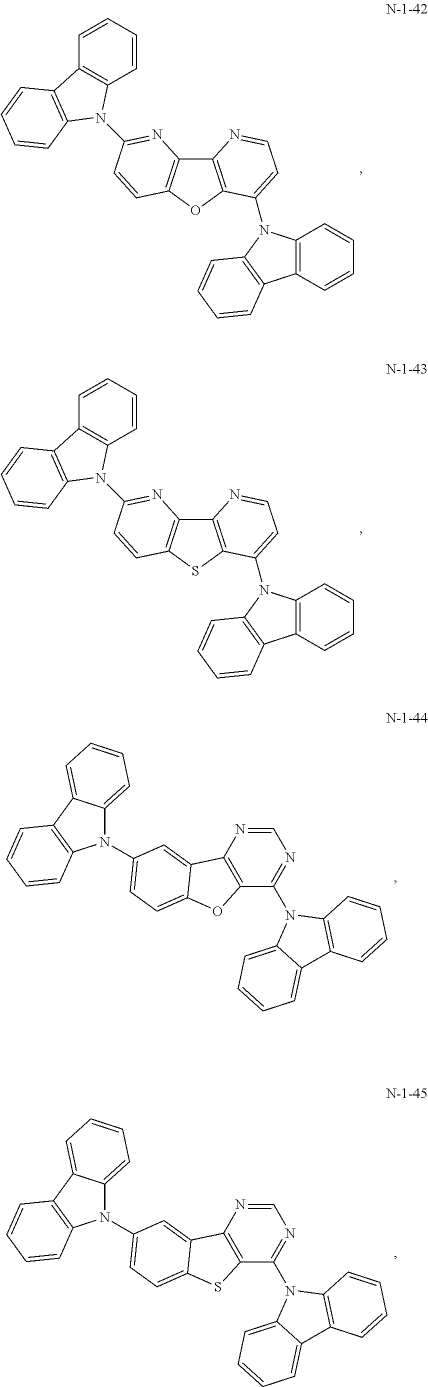 [SMILES: c1ccc2c(c1)c1ccccc1n2-c1ccc2oc3c(-n4c5ccccc5c5ccccc54)ccnc3c2n1 ; c1ccc2c(c1)c1ccccc1n2-c1ccc2sc3c(-n4c5ccccc5c5ccccc54)ccnc3c2n1 ; c1ccc2c(c1)c1ccccc1n2-c1ccc2oc3c(-n4c5ccccc5c5ccccc54)ncnc3c2c1 ; c1ccc2c(c1)c1ccccc1n2-c1ccc2sc3c(-n4c5ccccc5c5ccccc54)ncnc3c2c1] 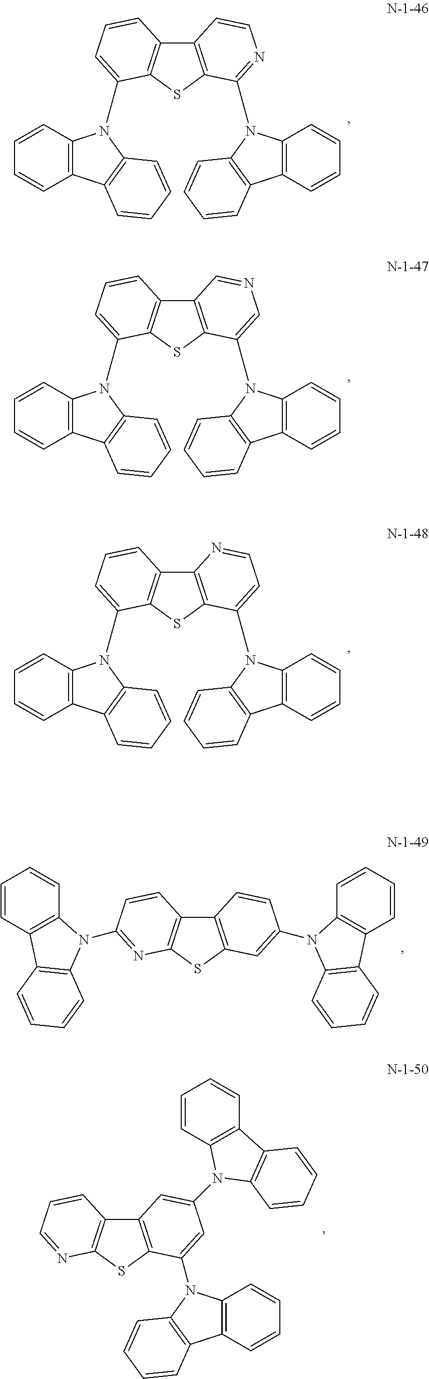 [SMILES: c1cc(-n2c3ccccc3c3ccccc32)c2sc3c(-n4c5ccccc5c5ccccc54)nccc3c2c1 ; c1cc(-n2c3ccccc3c3ccccc32)c2sc3c(-n4c5ccccc5c5ccccc54)cncc3c2c1 ; c1cc(-n2c3ccccc3c3ccccc32)c2sc3c(-n4c5ccccc5c5ccccc54)ccnc3c2c1 ; c1ccc2c(c1)c1ccccc1n2-c1ccc2c(c1)sc1nc(-n3c4ccccc4c4ccccc43)ccc12 ; c1cnc2sc3c(-n4c5ccccc5c5ccccc54)cc(-n4c5ccccc5c5ccccc54)cc3c2c1] 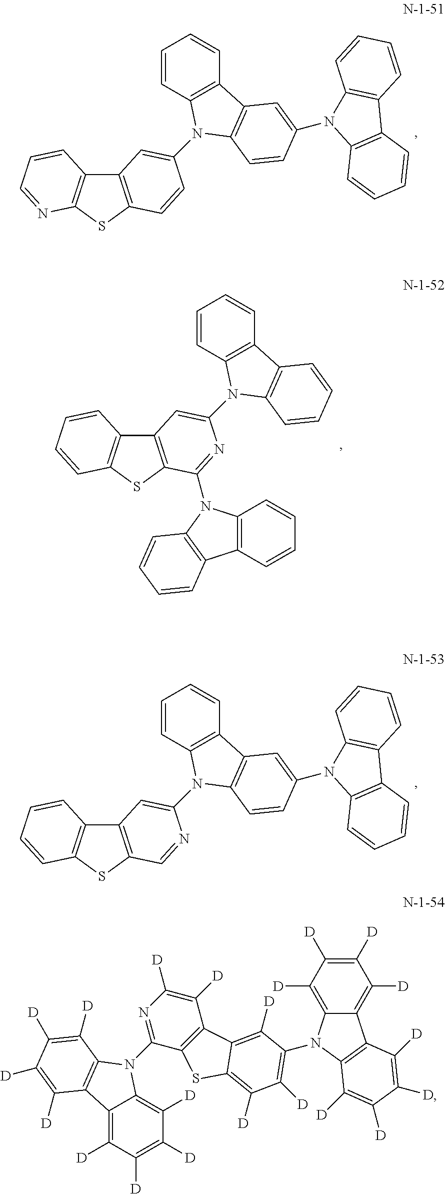 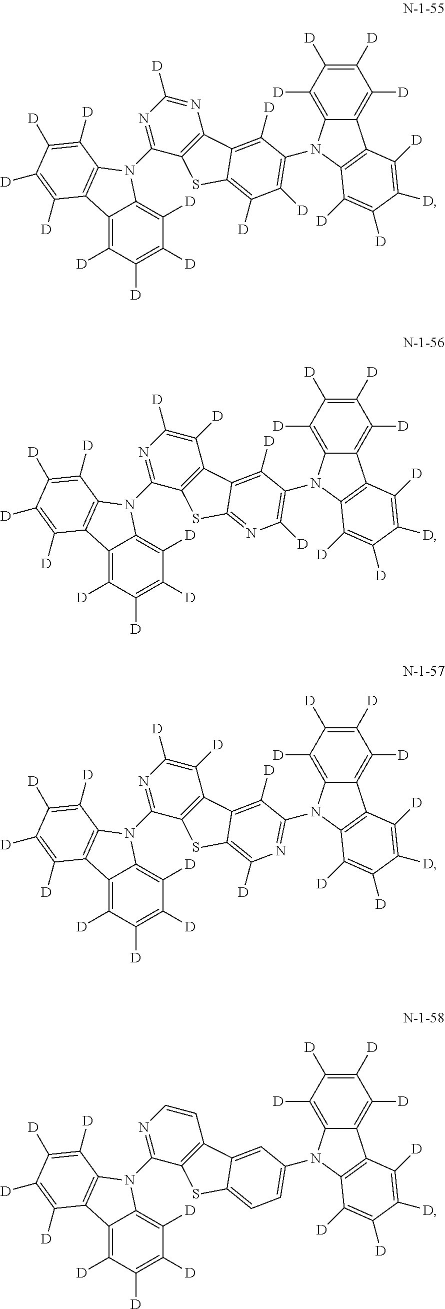 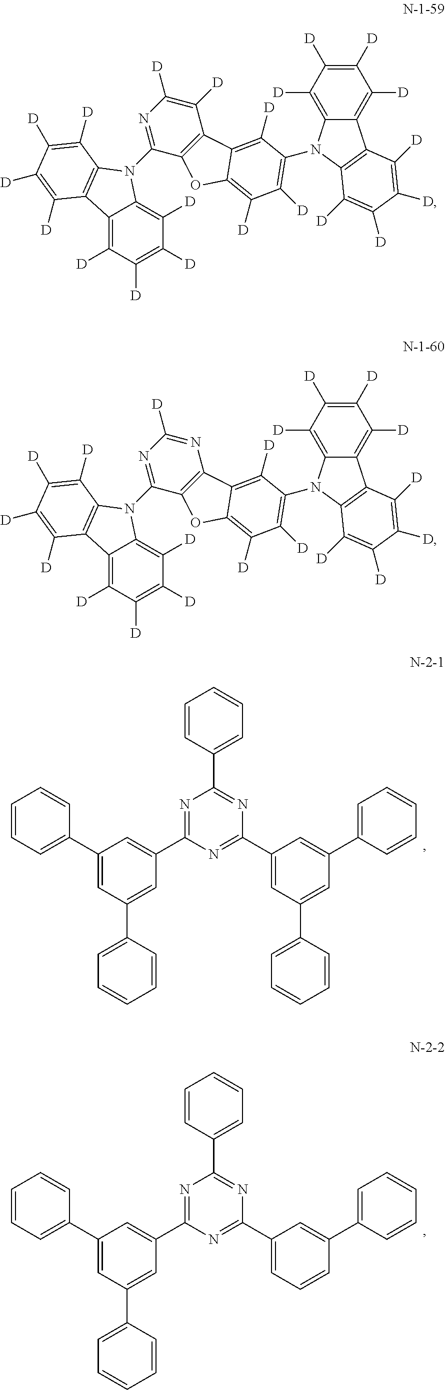 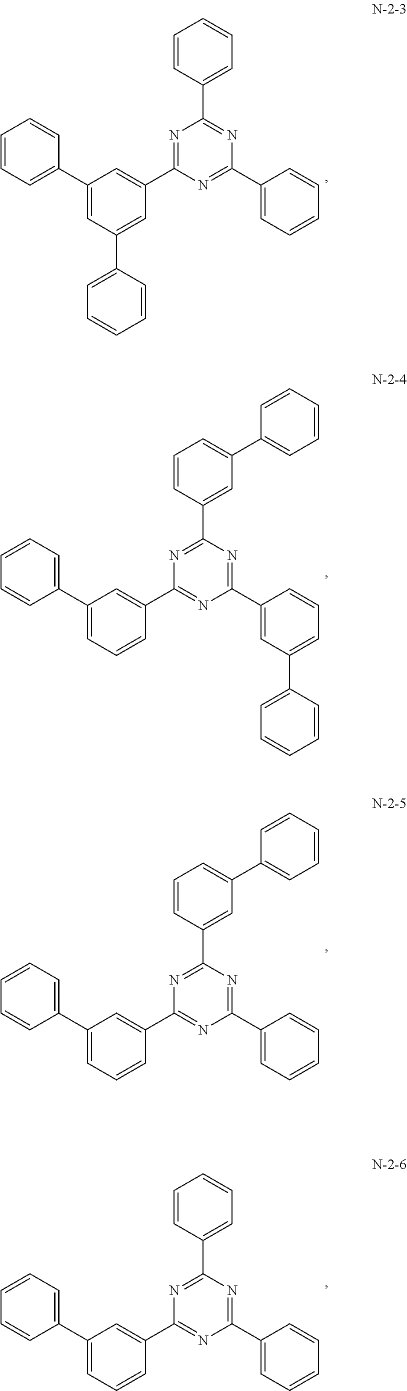 [SMILES: c1ccc(-c2cc(-c3ccccc3)cc(-c3nc(-c4ccccc4)nc(-c4ccccc4)n3)c2)cc1 ; c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4ccccc4)nc(-c4cccc(-c5ccccc5)c4)n3)c2)cc1 ; c1ccc(-c2cccc(-c3nc(-c4ccccc4)nc(-c4ccccc4)n3)c2)cc1] 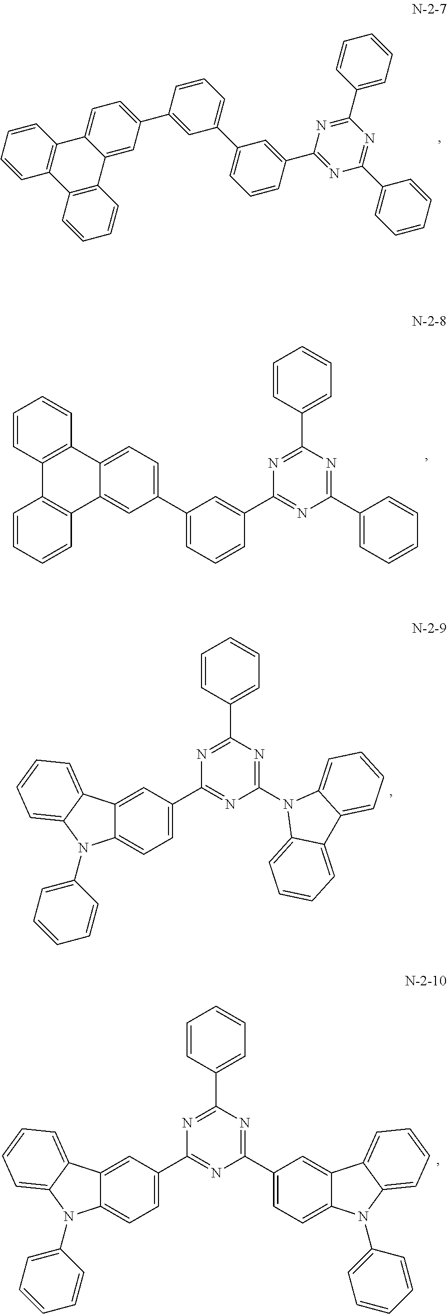 [SMILES: c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3cccc(-c4ccc5c6ccccc6c6ccccc6c5c4)c3)n2)cc1 ; c1ccc(-c2nc(-c3ccc4c(c3)c3ccccc3n4-c3ccccc3)nc(-n3c4ccccc4c4ccccc43)n2)cc1 ; c1ccc(-c2nc(-c3ccc4c(c3)c3ccccc3n4-c3ccccc3)nc(-c3ccc4c(c3)c3ccccc3n4-c3ccccc3)n2)cc1] 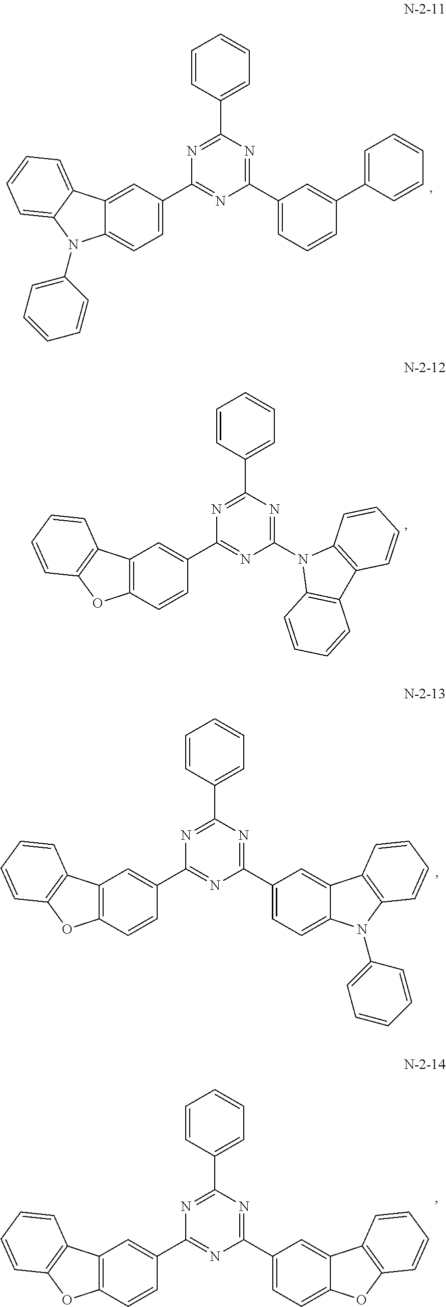 [SMILES: c1ccc(-c2cccc(-c3nc(-c4ccccc4)nc(-c4ccc5c(c4)c4ccccc4n5-c4ccccc4)n3)c2)cc1 ; c1ccc(-c2nc(-c3ccc4oc5ccccc5c4c3)nc(-n3c4ccccc4c4ccccc43)n2)cc1 ; c1ccc(-c2nc(-c3ccc4oc5ccccc5c4c3)nc(-c3ccc4c(c3)c3ccccc3n4-c3ccccc3)n2)cc1 ; c1ccc(-c2nc(-c3ccc4oc5ccccc5c4c3)nc(-c3ccc4oc5ccccc5c4c3)n2)cc1] 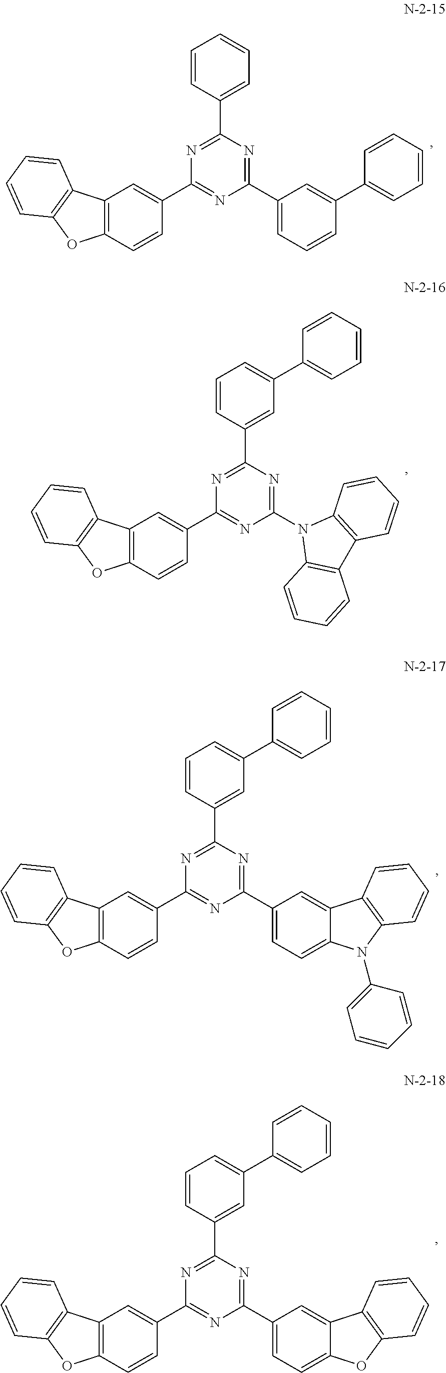 [SMILES: c1ccc(-c2cccc(-c3nc(-c4ccccc4)nc(-c4ccc5oc6ccccc6c5c4)n3)c2)cc1 ; c1ccc(-c2cccc(-c3nc(-c4ccc5oc6ccccc6c5c4)nc(-n4c5ccccc5c5ccccc54)n3)c2)cc1 ; c1ccc(-c2cccc(-c3nc(-c4ccc5oc6ccccc6c5c4)nc(-c4ccc5c(c4)c4ccccc4n5-c4ccccc4)n3)c2)cc1 ; c1ccc(-c2cccc(-c3nc(-c4ccc5oc6ccccc6c5c4)nc(-c4ccc5oc6ccccc6c5c4)n3)c2)cc1] 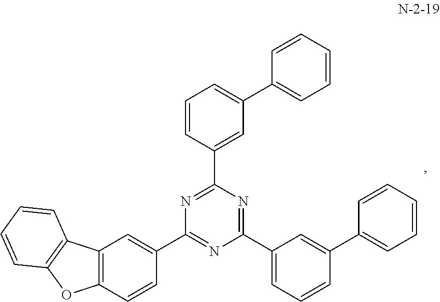 [SMILES: c1ccc(-c2cccc(-c3nc(-c4cccc(-c5ccccc5)c4)nc(-c4ccc5oc6ccccc6c5c4)n3)c2)cc1] 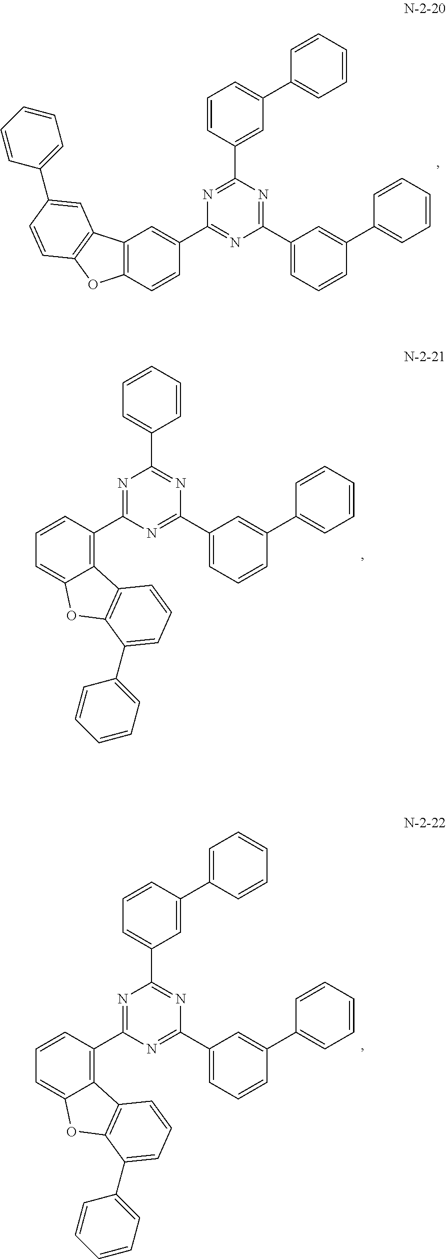 [SMILES: c1ccc(-c2cccc(-c3nc(-c4cccc(-c5ccccc5)c4)nc(-c4ccc5oc6ccc(-c7ccccc7)cc6c5c4)n3)c2)cc1 ; c1ccc(-c2cccc(-c3nc(-c4ccccc4)nc(-c4cccc5oc6c(-c7ccccc7)cccc6c45)n3)c2)cc1 ; c1ccc(-c2cccc(-c3nc(-c4cccc(-c5ccccc5)c4)nc(-c4cccc5oc6c(-c7ccccc7)cccc6c45)n3)c2)cc1] 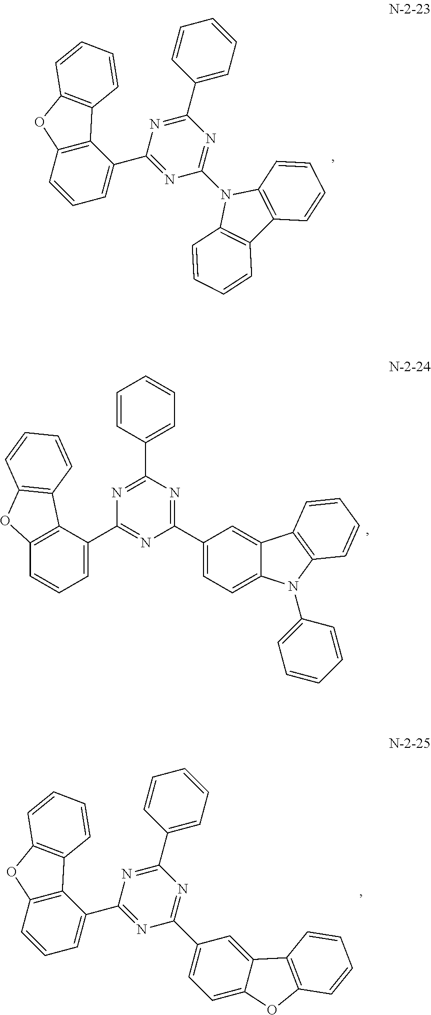 [SMILES: c1ccc(-c2nc(-c3cccc4oc5ccccc5c34)nc(-n3c4ccccc4c4ccccc43)n2)cc1 ; c1ccc(-c2nc(-c3ccc4c(c3)c3ccccc3n4-c3ccccc3)nc(-c3cccc4oc5ccccc5c34)n2)cc1 ; c1ccc(-c2nc(-c3ccc4oc5ccccc5c4c3)nc(-c3cccc4oc5ccccc5c34)n2)cc1] 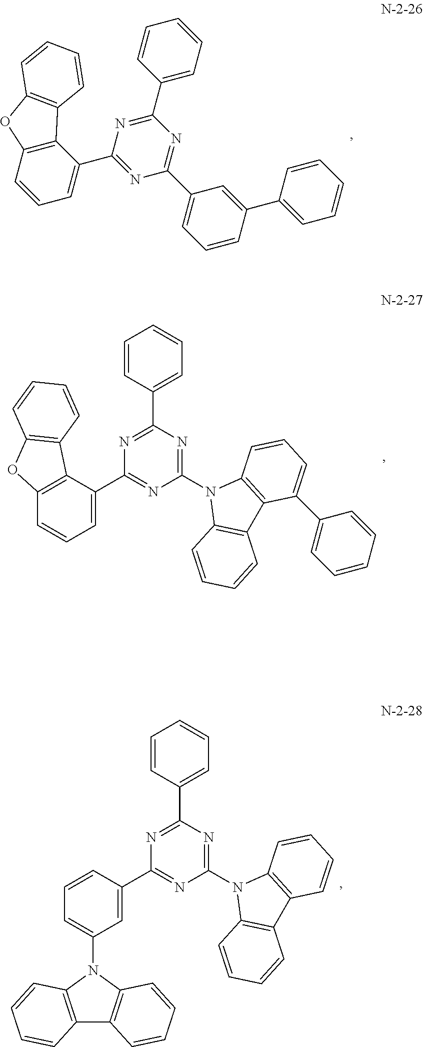 [SMILES: c1ccc(-c2cccc(-c3nc(-c4ccccc4)nc(-c4cccc5oc6ccccc6c45)n3)c2)cc1 ; c1ccc(-c2nc(-c3cccc4oc5ccccc5c34)nc(-n3c4ccccc4c4c(-c5ccccc5)cccc43)n2)cc1 ; c1ccc(-c2nc(-c3cccc(-n4c5ccccc5c5ccccc54)c3)nc(-n3c4ccccc4c4ccccc43)n2)cc1] 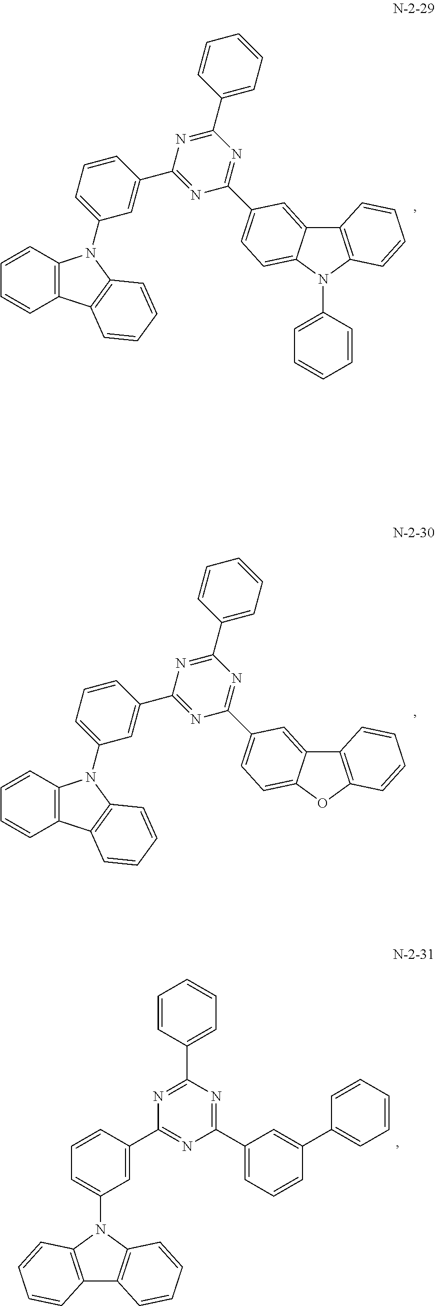 [SMILES: c1ccc(-c2nc(-c3cccc(-n4c5ccccc5c5ccccc54)c3)nc(-c3ccc4c(c3)c3ccccc3n4-c3ccccc3)n2)cc1 ; c1ccc(-c2nc(-c3cccc(-n4c5ccccc5c5ccccc54)c3)nc(-c3ccc4oc5ccccc5c4c3)n2)cc1 ; c1ccc(-c2cccc(-c3nc(-c4ccccc4)nc(-c4cccc(-n5c6ccccc6c6ccccc65)c4)n3)c2)cc1] 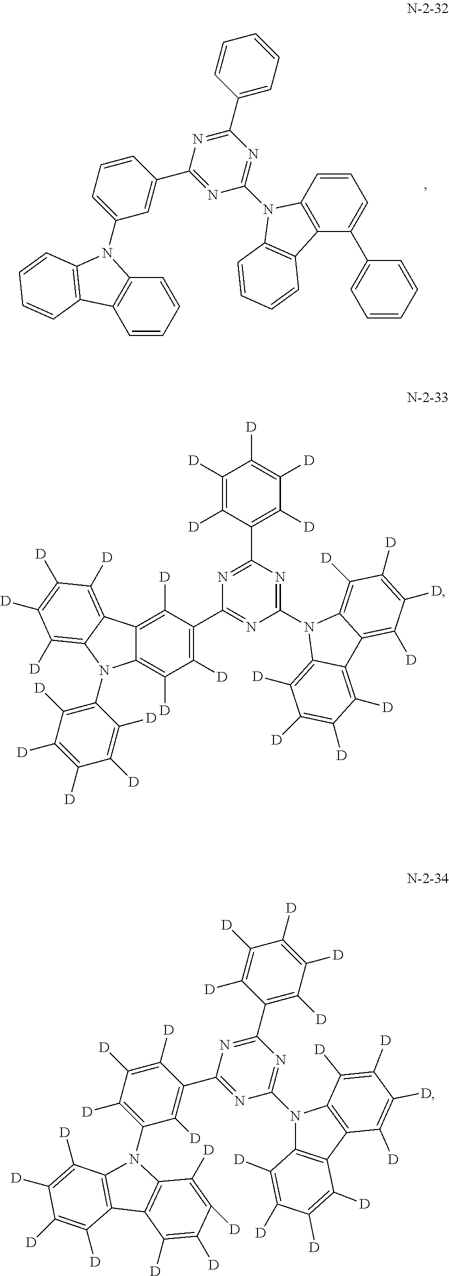 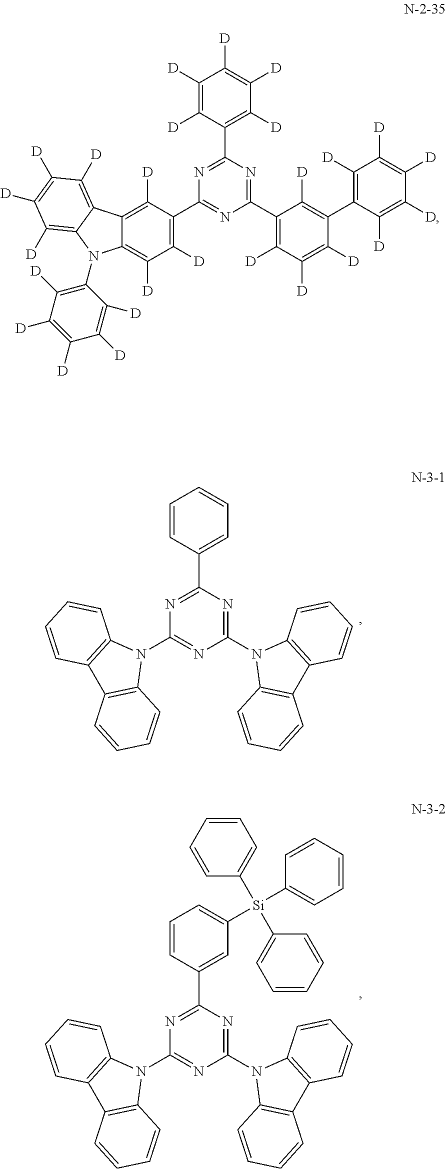 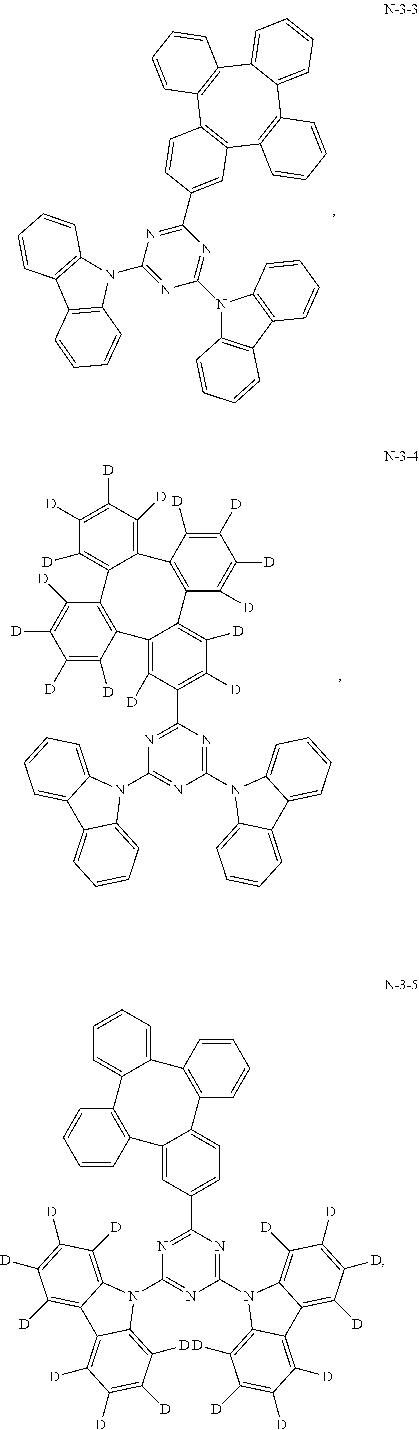 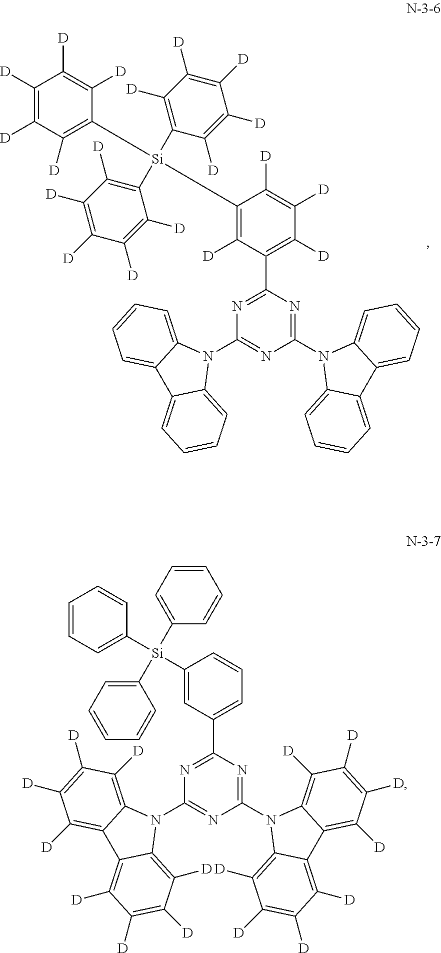 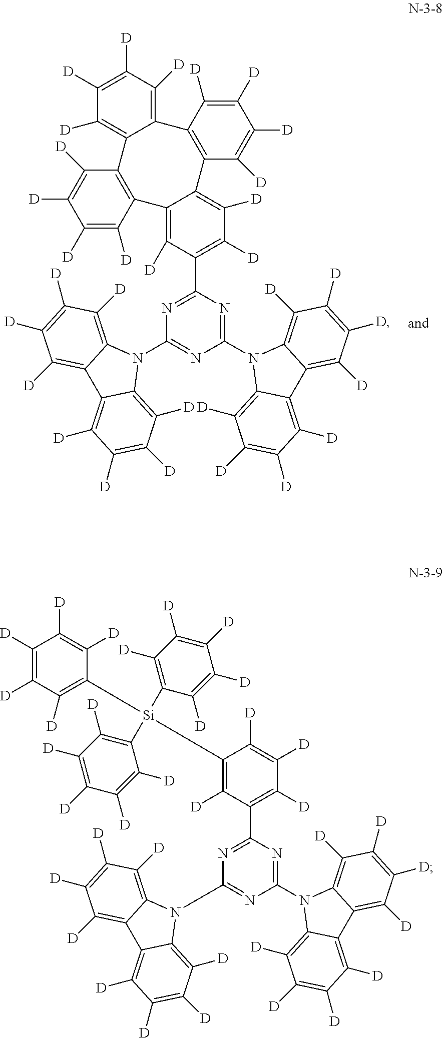
wherein optionally, hydrogens in the structures of Compound N-1-1 to Compound N-1-53, Compound N-1-58, Compound N-2-1 to Compound N-2-32, and Compound N-3-1 to Compound N-3-7 can be partially or fully substituted with deuterium.

20. The organic electroluminescent device according to claim 1, wherein the second host compound has a structure represented by Formula 8: 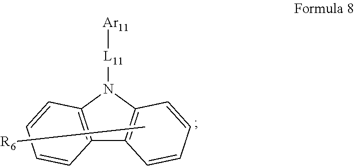
wherein in Formula 8,
L₁₁ is selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₆ can be optionally joined to form a ring;
preferably, the second host compound has a structure represented by Formula 8-1 or Formula 8-2: 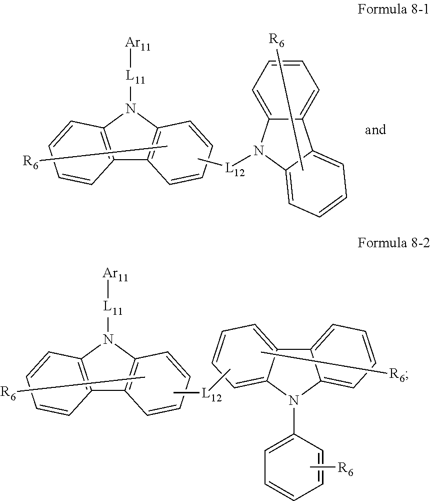
wherein L₁₁ and L₁₂ are selected from a single bond, substituted or unsubstituted arylene having 6 to 30 carbon atoms, substituted or unsubstituted heteroarylene having 3 to 30 carbon atoms or a combination thereof;
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms or a combination thereof;
R₆ represents, at each occurrence identically or differently, mono-substitution, multiple substitutions or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
adjacent substituents R₆ can be optionally joined to form a ring;
more preferably, the second host compound is selected from the group consisting of Compound P-1 to Compound P-38: 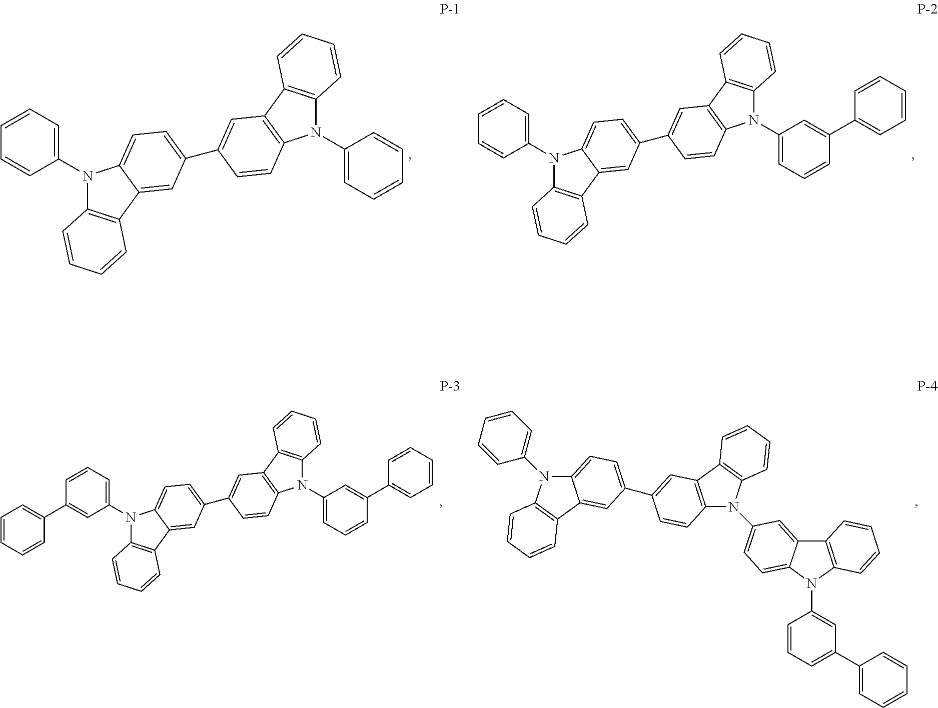 [SMILES: c1ccc(-n2c3ccccc3c3cc(-c4ccc5c(c4)c4ccccc4n5-c4ccccc4)ccc32)cc1 ; c1ccc(-c2cccc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-n5c6ccccc6c6cc(-c7ccc8c(c7)c7ccccc7n8-c7ccccc7)ccc65)ccc43)c2)cc1] 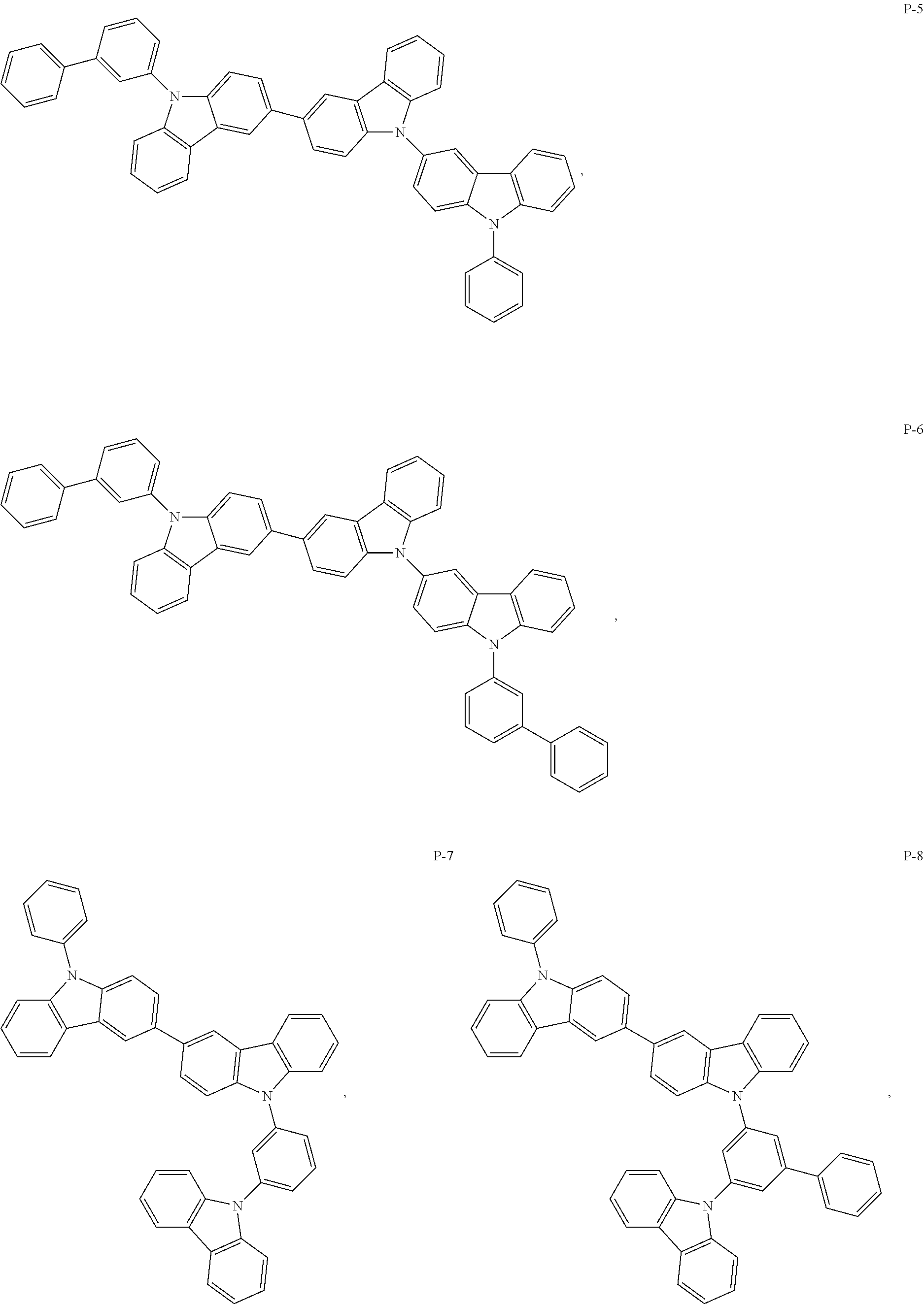 [SMILES: c1ccc(-c2cccc(-n3c4ccccc4c4cc(-c5ccc6c(c5)c5ccccc5n6-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5ccc6c(c5)c5ccccc5n6-c5cccc(-c6ccccc6)c5)ccc43)c2)cc1 ; c1ccc(-n2c3ccccc3c3cc(-c4ccc5c(c4)c4ccccc4n5-c4cccc(-n5c6ccccc6c6ccccc65)c4)ccc32)cc1 ; c1ccc(-c2cc(-n3c4ccccc4c4ccccc43)cc(-n3c4ccccc4c4cc(-c5ccc6c(c5)c5ccccc5n6-c5ccccc5)ccc43)c2)cc1] 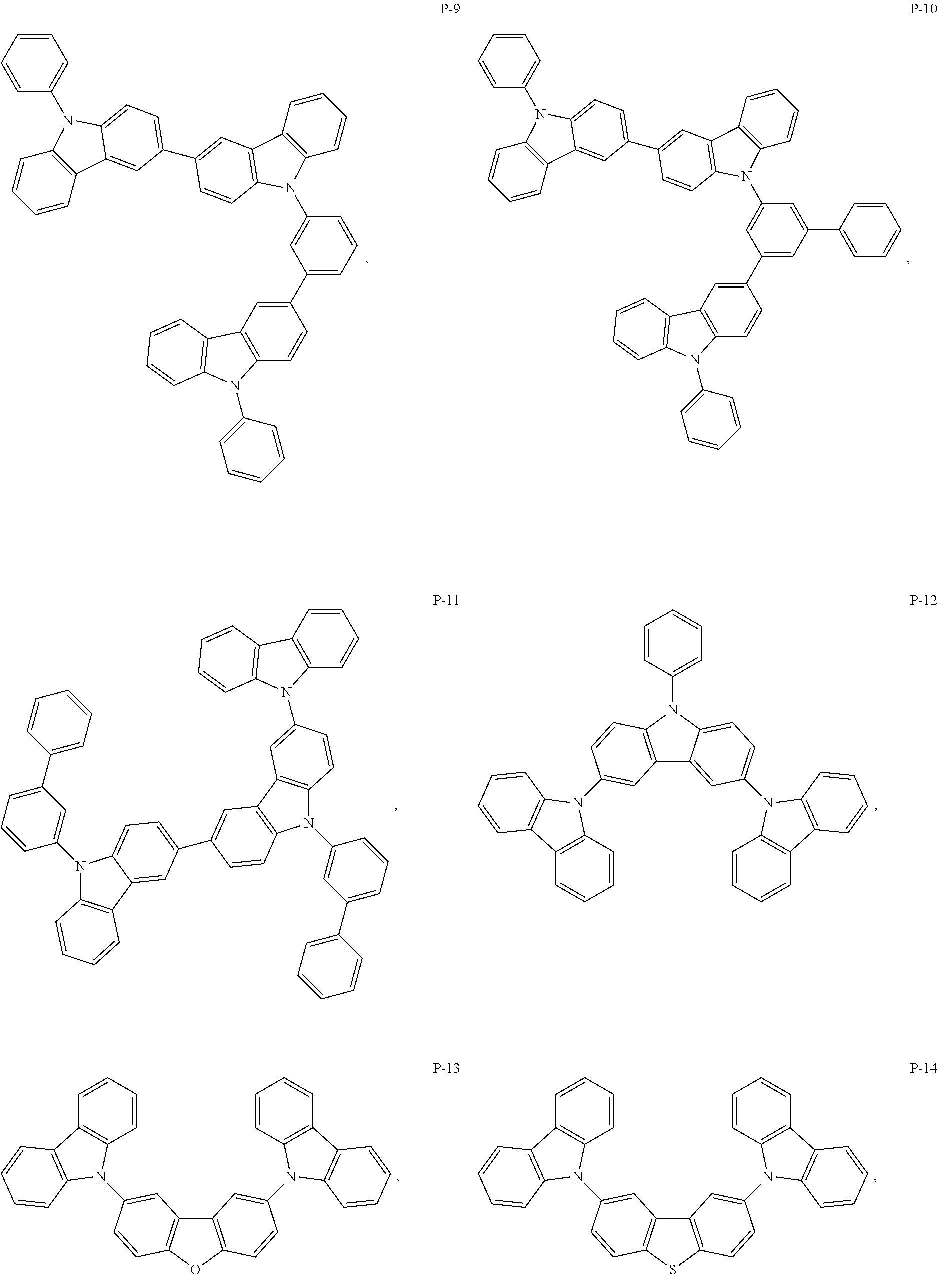 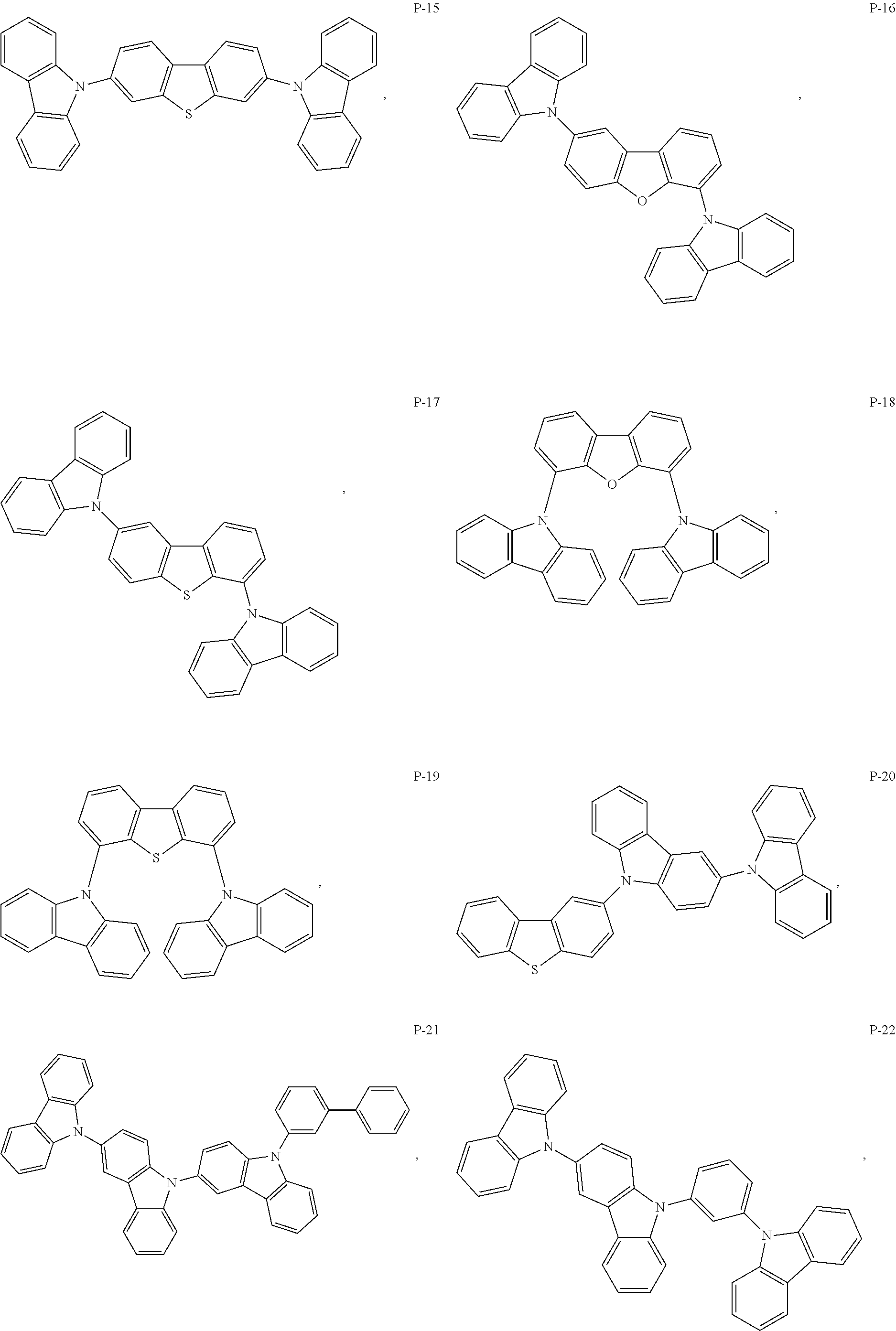 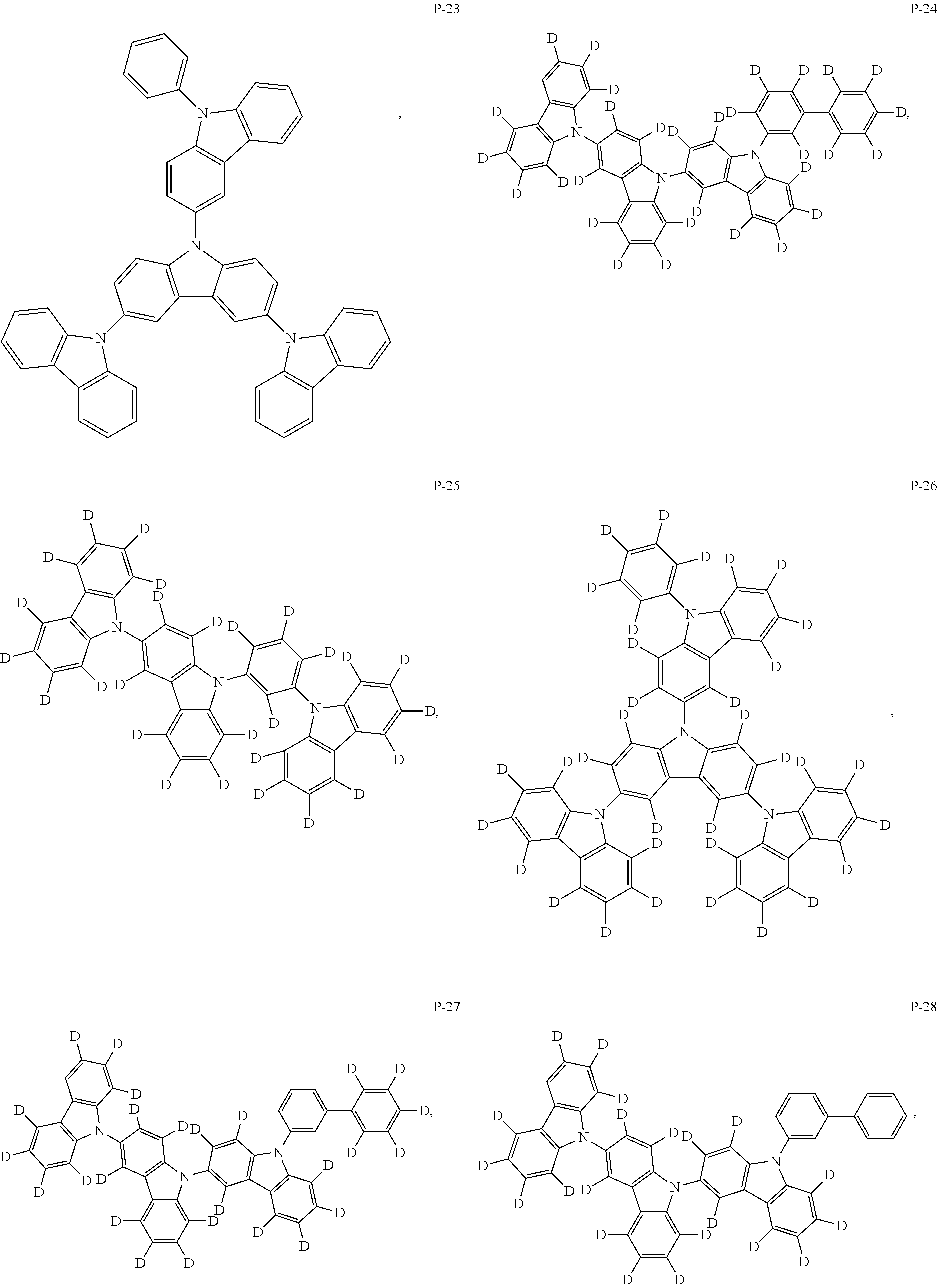 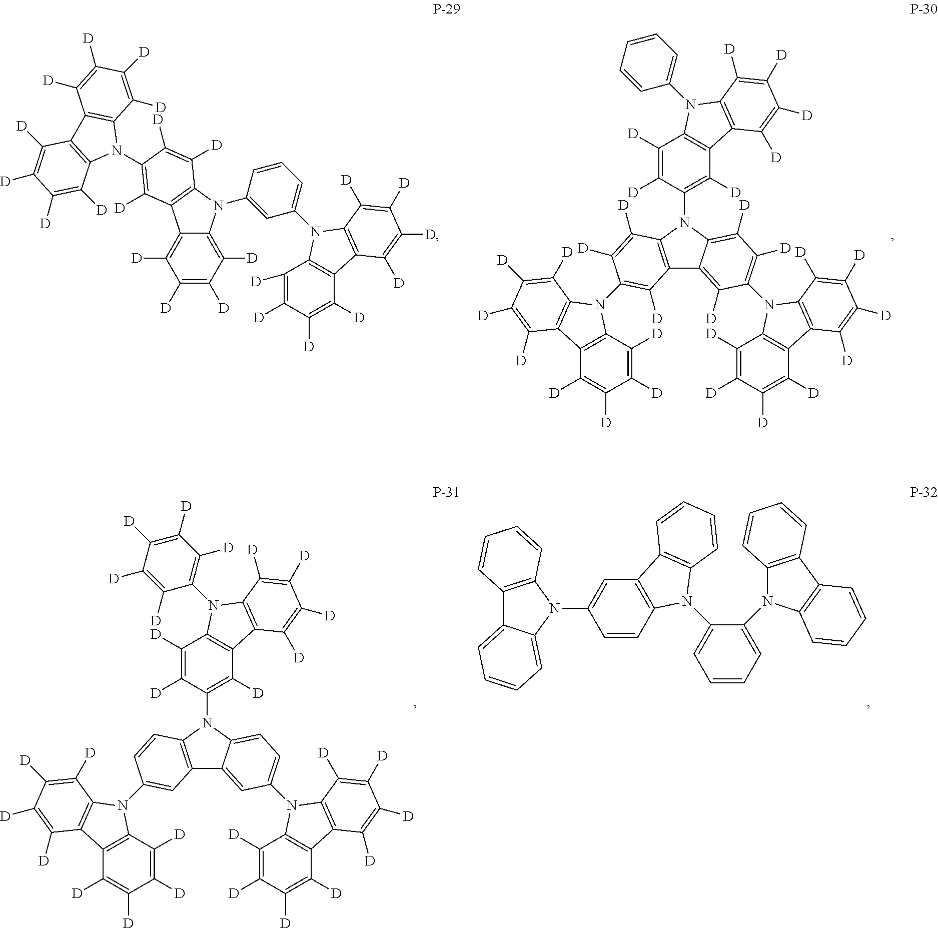 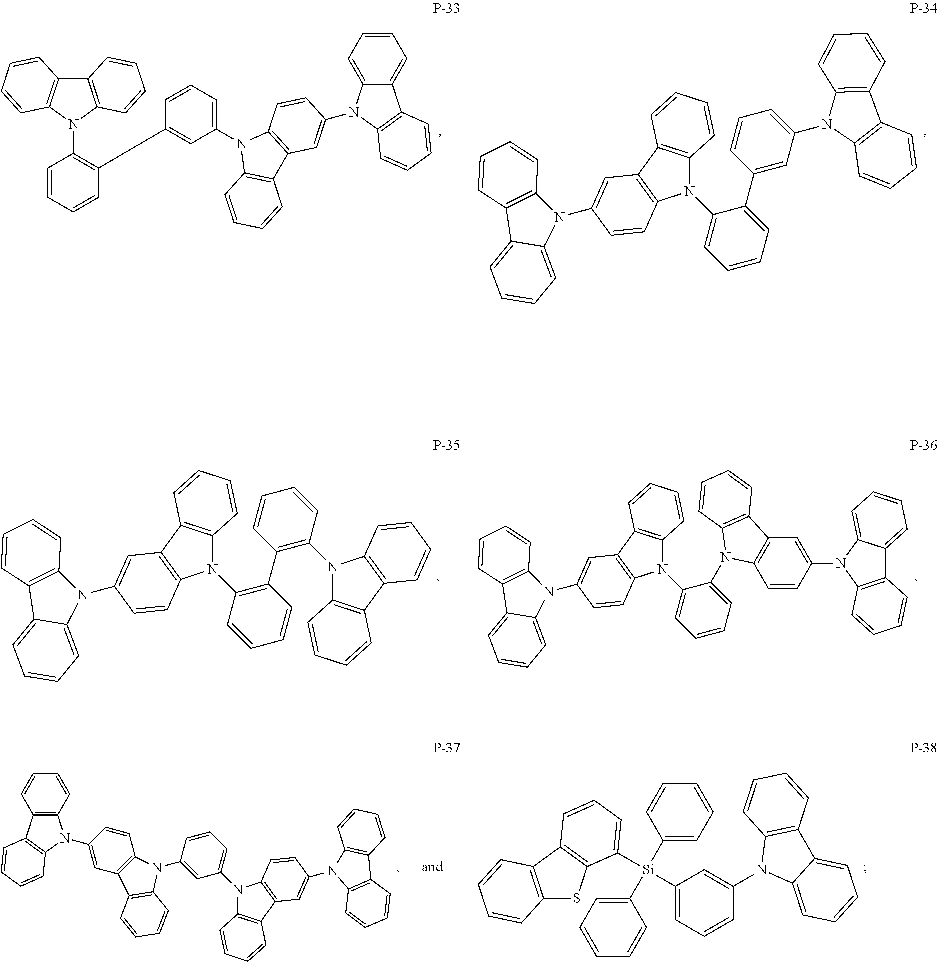
wherein optionally, hydrogens in the structures of Compound P-1 to Compound P-23 and Compound P-27 to Compound P-38 can be partially or fully substituted with deuterium.

21. The organic electroluminescent device according to claim 1, wherein a weight of the first host compound and the second host compound accounts for 65% to 98.9% of a total weight of materials in the emissive layer, a weight of the metal complex accounts for 1% to 30% of the total weight of materials in the emissive layer, and a weight of the fluorescent emissive material accounts for 0.1% to 5% of the total weight of materials in the emissive layer;
preferably, the weight of the first host compound and the second host compound accounts for 82% to 94.5% of the total weight of materials in the emissive layer, the weight of the metal complex accounts for 5% to 15% of the total weight of materials in the emissive layer, and the weight of the fluorescent emissive material accounts for 0.5% to 3% of the total weight of materials in the emissive layer;
more preferably, the weight of the first host compound and the second host compound accounts for 86.5% to 91.5% of the total weight of materials in the emissive layer, the weight of the metal complex accounts for 8% to 12% of the total weight of materials in the emissive layer, and the weight of the fluorescent emissive material accounts for 0.5% to 1.5% of the total weight of materials in the emissive layer.

22. The organic electroluminescent device according to claim 1, wherein the device emits deep blue light; preferably, the maximum emission wavelength of the device is 460 nm to 470 nm.

23. A display apparatus, comprising the organic electroluminescent device according to claim 1.

24. A composition, comprising a fluorescent emissive material, a metal complex, a first host compound, and a second host compound;
wherein the fluorescent light-emitting material has a structure represented by Formula 1: 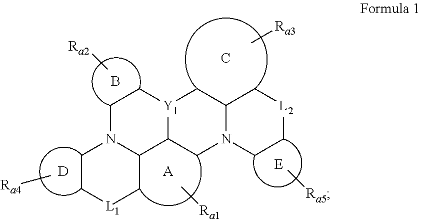
wherein in Formula 1,
the ring A is selected from an unsaturated carbocyclic ring having 5 to 30 carbon atoms or an unsaturated heterocyclic ring having 4 to 30 carbon atoms;
the ring B, the ring C, the ring D, and the ring E are each independently selected from an unsaturated carbocyclic ring having 5 to 30 carbon atoms or an unsaturated heterocyclic ring having 3 to 30 carbon atoms;
Y₁ is selected from B, P═O, P═S, As, As═O, As═S, SiR′ or GeR′;
Rₐ₁, Rₐ₂, Rₐ₃, Rₐ₄, and Rₐ₅ represent, at each occurrence identically or differently, mono-substitution, multiple substitutions or non-substitution;
R′, Rₐ₁, Rₐ₂, Rₐ₃, Rₐ₄, and Rₐ₅ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ and L₂ are each independently selected from the group consisting of: a single bond, O, S, Se, SiR_{L1}R_{L1}, PR_{L1}, R_{L1}C═CR_{L1}, substituted or unsubstituted arylene having 6 to 30 carbon atoms, substituted or unsubstituted heteroarylene having 3 to 30 carbon atoms, and combinations thereof;
R_{L1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof;
adjacent substituents Rₐ₁ can be optionally joined to form a ring;
adjacent substituents Rₐ₂ can be optionally joined to form a ring;
adjacent substituents Rₐ₃ can be optionally joined to form a ring;
adjacent substituents Rₐ₄ can be optionally joined to form a ring;
adjacent substituents Rₐ₅ can be optionally joined to form a ring; and
adjacent substituents R_{L1} can be optionally joined to form a ring.
